(19) United States
(12) Patent Application Publication
(10) Pub. No.: US 2023/0045441 A1
(43) Pub. Date: Feb. 9, 2023

(54) PATTERN FORMING METHOD, METHOD FOR MANUFACTURING ELECTRONIC DEVICE, ACTINIC RAY-SENSITIVE OR RADIATION-SENSITIVE RESIN COMPOSITION, AND RESIST FILM

(71) Applicant: FUJIFILM Corporation, Tokyo (JP)

(72) Inventor: Michihiro SHIRAKAWA, Haibara-gun (JP)

(73) Assignee: FUJIFILM Corporation, Tokyo (JP)

(21) Appl. No.: 17/901,433

(22) Filed: Sep. 1, 2022

Related U.S. Application Data
(63) Continuation of application No. PCT/JP2021/007927, filed on Mar. 2, 2021.

(30) Foreign Application Priority Data
Mar. 6, 2020 (JP) 2020-039096

(51) Int. Cl. G03F 7/039; G03F 7/004; G03F 7/32

(52) U.S. Cl. CPC G03F 7/039; G03F 7/0048; G03F 7/325

(57) ABSTRACT

An object of the present invention is to provide a pattern forming method with which a pattern having excellent resolution performance and LER performance can be formed. In addition, another object of the present invention is to provide a method for manufacturing an electronic device, an actinic ray-sensitive or radiation-sensitive resin composition, and a resist film.

A pattern forming method of the present invention includes a resist film forming step of forming a resist film on a substrate using an actinic ray-sensitive or radiation-sensitive resin composition, an exposing step of exposing the resist film, and a developing step of positively developing the exposed resist film using an organic solvent-based developer, in which the actinic ray-sensitive or radiation-sensitive resin composition includes a resin having a polar group, a compound including two or more ion pairs which are decomposed by an irradiation with an actinic ray or a radiation and having a molecular weight of 5,000 or less, and a solvent.

### CROSS-REFERENCE TO RELATED APPLICATIONS

This application is a Continuation of PCT International Application No. PCT/JP2021/007927 filed on Mar. 2, 2021, which claims priority under 35 U.S.C. § 119(a) to Japanese Patent Application No. 2020-039096 filed on Mar. 6, 2020. The above application is hereby expressly incorporated by reference, in its entirety, into the present application.

### BACKGROUND OF THE INVENTION

### 1. Field of the Invention

The present invention relates to a pattern forming method, a method for manufacturing an electronic device, an actinic ray-sensitive or radiation-sensitive resin composition, and a resist film.

### 2. Description of the Related Art

In recent years, a pattern has been rapidly miniaturized due to a shortening of a wavelength (higher energy) of an exposure light source. In the related art, ultraviolet rays typified by g-rays and i-rays have been used, but nowadays, mass production of semiconductor elements using KrF excimer lasers and ArF excimer lasers has started. In addition, studies have been conducted on the use of electron beam (EB), extreme ultraviolet rays (EUV), X-rays, and the like, which have a shorter wavelength (higher energy) than the above-described excimer laser.

By the way, with the progress of lithography technology in recent years, in processes for manufacturing semiconductor devices such as an integrated circuit (IC) and a large scale integrated circuit (LSI), microfabrication by lithography using a chemically amplified resist composition has been used in many cases. On the other hand, in recent years, a non-chemically amplified resist composition which is not affected by acid diffusion has been attracting attention again.

As the non-chemically amplified resist composition, for example, JP2013-127526A discloses “a resist pattern forming method including a step (1) of forming, on a support, a resist film having an association structure of an acidic group and a light-absorbing cation, a step (2) of exposing the resist film to break the association structure and expose the acidic group, and a step (3) of developing the resist film with a developer containing an organic solvent”.

### SUMMARY OF THE INVENTION

The present inventors have conducted studies on the pattern forming method disclosed in JP2013-127526A, and have thus found that there is room for improvement in resolution performance and line edge roughness (LER) performance of a pattern to be formed.

Therefore, an object of the present invention is to provide a pattern forming method with which a pattern having excellent resolution performance and LER performance can be formed.

In addition, another object of the present invention is to provide a method for manufacturing an electronic device using the pattern forming method.

In addition, another object of the present invention is to provide an actinic ray-sensitive or radiation-sensitive resin composition with which a pattern having excellent resolution performance and LER performance can be formed.

In addition, another object of the present invention is to provide a resist film formed of the actinic ray-sensitive or radiation-sensitive resin composition.

The present inventors have conducted intensive studies to achieve the above-described objects, and as a result, they have found that the above-described objects can be achieved by the following configurations.

[1] A pattern forming method comprising:

a resist film forming step of forming a resist film on a substrate using an actinic ray-sensitive or radiation-sensitive resin composition;

an exposing step of exposing the resist film; and

a developing step of positively developing the exposed resist film using an organic solvent-based developer,

in which the actinic ray-sensitive or radiation-sensitive resin composition includes a resin having a polar group, a compound including two or more ion pairs which are decomposed by an irradiation with an actinic ray or a radiation and having a molecular weight of 5,000 or less, and a solvent.

[2] The pattern forming method according to [1],

in which the resin includes a repeating unit X1 having a polar group.

[3] The pattern forming method according to [2],

in which the repeating unit X1 includes a repeating unit including a phenolic hydroxyl group.

[4] The pattern forming method according to any one of [1] to [3],

in which the resin does not include a repeating unit X2 which decreases a solubility in the organic solvent-based developer by an action of acid, or

in a case where the resin includes the repeating unit X2, a content of the repeating unit X2 is 20 mol % or less with respect to all repeating units of the resin.

[5] The pattern forming method according to any one of [1] to [4],

in which the resin does not include a repeating unit X2 which decreases a solubility in the organic solvent-based developer by an action of acid, or

in a case where the resin includes the repeating unit X2, a content of the repeating unit X2 is 10 mol % or less with respect to all repeating units of the resin.

[6] A method for manufacturing an electronic device, comprising:

the pattern forming method according to any one of [1] to [5].

[7] An actinic ray-sensitive or radiation-sensitive resin composition comprising:

a resin having a polar group;

a compound including two or more ion pairs which are decomposed by an irradiation with an actinic ray or a radiation and having a molecular weight of 5,000 or less; and

a solvent,

in which, in a case where a resist film formed of the actinic ray-sensitive or radiation-sensitive resin composition is irradiated with an actinic ray or a radiation, a solubility in an organic solvent-based developer is increased.

[8] The actinic ray-sensitive or radiation-sensitive resin composition according to [7],

in which the resin includes a repeating unit X1 having a polar group.

[9] The actinic ray-sensitive or radiation-sensitive resin composition according to [8],

in which the repeating unit X1 includes a repeating unit including a phenolic hydroxyl group.

[10] The actinic ray-sensitive or radiation-sensitive resin composition according to any one of [7] to [9],

in which the resin does not include a repeating unit X2 which decreases a solubility in the organic solvent-based developer by an action of acid, or

in a case where the resin includes the repeating unit X2, a content of the repeating unit X2 is 20 mol % or less with respect to all repeating units of the resin.

[11] The actinic ray-sensitive or radiation-sensitive resin composition according to any one of [7] to [10],

in which the resin does not include a repeating unit X2 which decreases a solubility in the organic solvent-based developer by an action of acid, or

in a case where the resin includes the repeating unit X2, a content of the repeating unit X2 is 10 mol % or less with respect to all repeating units of the resin.

[12] A resist film formed of the actinic ray-sensitive or radiation-sensitive resin composition according to any one of [7] to [11].

According to the present invention, it is possible to provide a pattern forming method with which a pattern having excellent resolution performance and LER performance can be formed.

In addition, according to the present invention, it is possible to provide a method for manufacturing an electronic device using the pattern forming method.

In addition, according to the present invention, it is possible to provide an actinic ray-sensitive or radiation-sensitive resin composition with which a pattern having excellent resolution performance and LER performance can be formed.

In addition, according to the present invention, it is possible to provide a resist film formed of the actinic ray-sensitive or radiation-sensitive resin composition.

### BRIEF DESCRIPTION OF THE DRAWINGS

FIG. 1 is a schematic view for explaining a step X1.

FIG. 2 is a schematic view for explaining a step X2.

FIG. 3 is a schematic view for explaining the step X2, and is a view showing a state after exposure.

FIG. 4 is a schematic view for explaining a positive tone resist pattern obtained through a step X3.

### DESCRIPTION OF THE PREFERRED EMBODIMENTS

Hereinafter, a pattern forming method, a method for manufacturing an electronic device, an actinic ray-sensitive or radiation-sensitive resin composition, and a resist film according to an embodiment of the present invention will be described in detail.

Description of configuration requirements described below may be made on the basis of representative embodiments of the present invention in some cases, but the present invention is not limited to such embodiments.

In notations for a group (atomic group) in the present specification, in a case where the group is cited without specifying that it is substituted or unsubstituted, the group includes both a group having no substituent and a group having a substituent as long as it does not impair the spirit of the present invention. For example, an “alkyl group” includes not only an alkyl group having no substituent (unsubstituted alkyl group), but also an alkyl group having a substituent (substituted alkyl group). In addition, an “organic group” in the present specification refers to a group including at least one carbon atom.

A substituent is preferably a monovalent substituent unless otherwise specified.

“Actinic ray” or “radiation” in the present specification means, for example, a bright line spectrum of a mercury lamp, far ultraviolet rays typified by an excimer laser, extreme ultraviolet rays (EUV light), X-rays, electron beams (EB), or the like. “Light” in the present specification means actinic ray or radiation.

Unless otherwise specified, “exposure” in the present specification encompasses not only exposure by a bright line spectrum of a mercury lamp, far ultraviolet rays typified by an excimer laser, extreme ultraviolet rays, X-rays, or the like, but also drawing by particle beams such as electron beams and ion beams.

In the present specification, a numerical range expressed using “to” is used in a meaning of a range that includes the preceding and succeeding numerical values of “to” as the lower limit value and the upper limit value, respectively.

A bonding direction of a divalent group cited in the present specification is not limited unless otherwise specified. For example, in a case where Y in a compound represented by General Formula “X—Y—Z” is —COO—, Y may be —CO—O— or —O—CO—. In addition, the above-described compound may be “X—CO—O—Z” or “X—O—CO—Z”.

In the present specification, (meth)acrylic acid represents acrylic acid and methacrylic acid.

In the present specification, a weight-average molecular weight (Mw), a number-average molecular weight (Mn), and a dispersity (also referred to as a molecular weight distribution) (Mw/Mn) of a resin are defined as values expressed in terms of polystyrene by means of gel permeation chromatography (GPC) measurement (solvent: tetrahydrofuran, flow amount (amount of a sample injected): 10 μL, columns: TSK gel Multipore HXL-M manufactured by Tosoh Corporation, column temperature: 40° C., flow rate: 1.0 mL/min, and detector: differential refractive index detector) using a GPC apparatus (HLC-8120GPC manufactured by Tosoh Corporation).

In the present specification, an acid dissociation constant (pKa) represents a pKa in an aqueous solution, and is specifically a value determined by computation from a value based on a Hammett's substituent constant and database of publicly known literature values, using the following software package 1. Any of the pKa values described in the present specification indicates values determined by computation using the software package.

Software Package 1: Advanced Chemistry Development (ACD/Labs) Software V 8.14 for Solaris (1994-2007 ACD/Labs).

On the other hand, the pKa can also be determined by a molecular orbital computation method. Examples of a specific method thereof include a method for performing calculation by computing H⁺ dissociation free energy in a solvent based on a thermodynamic cycle (in the present specification, water is usually used as the solvent, and in a case where a pKa is not determined with water, dimethyl sulfoxide (DMSO) is used).

With regard to a computation method for H⁺ dissociation free energy, the H⁺ dissociation free energy can be computed by, for example, density functional theory (DFT), but various other methods have been reported in literature and the like, and are not limited thereto. There are a plurality of software applications capable of performing DFT, and examples thereof include Gaussian 16.

As described above, the pKa in the present specification refers to a value determined by computation from a value based on a Hammett's substituent constant and database of publicly known literature values, using the software package 1, but in a case where the pKa cannot be calculated by the method, a value obtained by Gaussian 16 based on density functional theory (DFT) shall be adopted.

In the present specification, examples of the halogen atom include a fluorine atom, a chlorine atom, a bromine atom, and an iodine atom.

[Pattern Forming Method and Resist Film]

The pattern forming method according to the embodiment of the present invention includes the following steps X1 to X3.

Step X1: resist film forming step of forming a resist film on a substrate using an actinic ray-sensitive or radiation-sensitive resin composition (hereinafter, also referred to as a “specific resist composition”) described later

Step X2: exposing step of exposing the resist film

Step X3: developing step of positively developing the exposed resist film using an organic solvent-based developer

<<Specific Resist Composition>>

The specific resist composition includes a resin having a polar group (hereinafter, also referred to as a “specific resin”), a compound including two or more ion pairs which are decomposed by an irradiation with an actinic ray or a radiation and having a molecular weight of 5,000 or less (hereinafter, also referred to as a “specific photodegradable ion compound”), and a solvent.

A pattern formed by the above-described pattern forming method has excellent resolution performance and LER performance. The mechanism of action is not always clear, but the present inventors have presumed as follows.

In the step X1 of the above-described pattern forming method, the specific resin and the specific photodegradable ion compound form an association structure by an electrostatic interaction between the polar group in the specific resin and the ion pairs in the specific photodegradable ion compound, and as a result, a resist film with low solubility or insolubility in the organic solvent-based developer is formed. Next, in a case where the step X2 (exposure treatment) is performed on the obtained resist film, in the exposed portion, the association structure is released by decomposing the specific photodegradable ion compound. As a result, in the exposed portion, the solubility in the organic solvent-based developer is improved. On the other hand, in the non-exposed portion, the solubility in the organic solvent-based developer is almost unchanged. That is, by going through the above-described step X2, a difference in solubility (dissolution contrast) in the organic solvent-based developer occurs between the exposed portion and the non-exposed portion of the resist film, and in the subsequent step X3, the exposed portion of the resist film is dissolved and removed in the organic solvent-based developer to form a positive tone pattern.

The present inventors have considered that the point that the specific photodegradable ion compound includes two or more ion pairs which are decomposed by an irradiation with an actinic ray or a radiation and the point that the molecular weight is 5,000 or less is the main feature point improving the resolution performance and LER performance. That is, since the specific photodegradable ion compound includes two or more ion pairs which are decomposed by an irradiation with an actinic ray or a radiation, the specific photodegradable ion compound functions as a crosslinking component which crosslinks between the polar groups in the specific resin, and as a result, an associate of the specific resin and the specific photodegradable ion compound becomes a higher polymeric substance, and the solubility of the resist film formed in the step X1 in the organic solvent-based developer can be further reduced. That is, in the step X2, the dissolution contrast between the exposed portion and the non-exposed portion can be further improved. In addition, in a case where the molecular weight of the specific photodegradable ion compound is 5,000 or less, the association structure of the specific resin and the specific photodegradable ion compound tends to be more uniform in the film, and as a result, the LER of the formed pattern tends to be smaller.

The above-described effects are also clear from results shown in the examples column of the present specification. That is, compared to a case of using a compound including only one ion pair which is decomposed by an irradiation with an actinic ray or a radiation (refer to Comparative Examples 1 and 2) and a case where a polymer compound including two or more ion pairs which are decomposed by an irradiation with an actinic ray or a radiation and having a molecular weight of more than 5,000 (refer to Comparative Example 3), the pattern formed by the above-described pattern forming method has more excellent resolution performance and LER performance.

The above-described pattern forming method can be suitably used, for example, in a case of forming a fine pattern having a line-and-space of 16 nm or less.

Hereinafter, the pattern forming method and resist film according to the embodiment of the present invention will be described in detail for each step with reference to the drawings. The description of the configuration requirements described below is made on the basis of representative embodiments of the present invention, but it should not be construed that the present invention is limited to those embodiments.

### First Embodiment

A first embodiment of the pattern forming method includes the following step X1, step X2, and step X3 in this order.

Step X1: resist film forming step of forming a resist film on a substrate using the specific resist composition

Step X2: exposing step of exposing the resist film Step X3: developing step of positively developing the exposed resist film using an organic solvent-based developer

[Step X1: Resist Film Forming Step]

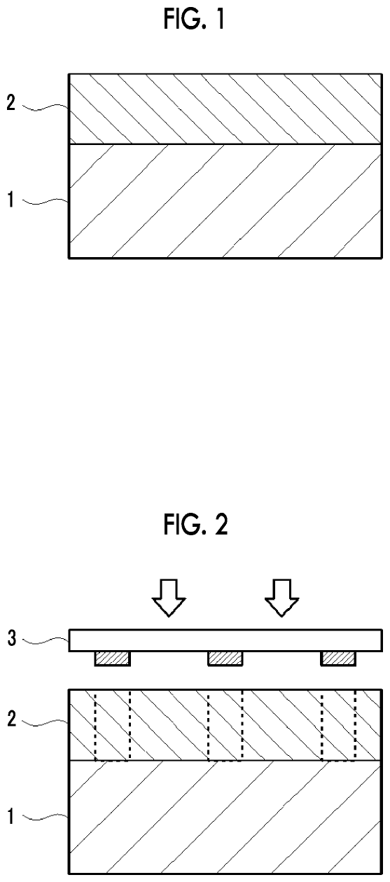

As shown in FIG. 1, the step X1 is a step of forming a resist film 2 on a substrate 1 using the specific resist composition.

Examples of a method for forming a resist film on a substrate using the specific resist composition include a method in which the specific resist composition is applied to a substrate.

The specific resist composition can be applied to a substrate (for example, silicon and silicon dioxide coating) as used in the manufacture of integrated circuit elements by a suitable application method such as an application using a spinner or a coater. The application method is preferably a spin application using a spinner. A rotation speed upon the spin application using a spinner is preferably 1000 to 3000 rpm.

In a case where the specific resist composition is applied to a substrate and dried, an electrostatic interaction acts between the polar group in the specific resin and the specific photodegradable ion compound, and the specific resin and the specific photodegradable ion compound form an association structure to form the resist film 2. This association structure exhibits low solubility or insolubility in the organic solvent-based developer. Composition of the specific resist composition will be described later.

After the application of the specific resist composition, the substrate may be heated to form a resist film. In addition, various underlying films (an inorganic film, an organic film, or an antireflection film) may be formed on an underlayer of the resist film.

The heating can be carried out using a unit included in an ordinary exposure machine and/or development machine, and may also be carried out using a hot plate or the like.

A heating temperature is preferably 80° C. to 150° C., more preferably 80° C. to 140° C., and still more preferably 80° C. to 130° C. A heating time is preferably 30 to 1000 seconds, more preferably 30 to 800 seconds, and still more preferably 40 to 600 seconds. The heating may be carried out in a plurality of times.

A film thickness of the resist film is not particularly limited, but from the viewpoint that a more accurate fine pattern can be formed, the film thickness is preferably 10 to 90 nm, more preferably 10 to 65 nm, and still more preferably 15 to 50 nm.

A topcoat may be formed on the upper layer of the resist film using a topcoat composition.

It is preferable that the topcoat composition is not mixed with the resist film and can be uniformly applied to the upper layer of the resist film.

The topcoat composition includes, for example, a resin, an additive, and a solvent.

The topcoat is not particularly limited, a topcoat known in the related art can be formed by the methods known in the related art, and for example, the topcoat can be formed based on the description in paragraphs [0072] to [0082] of JP2014-059543A.

For example, it is preferable that a topcoat including a basic compound as described in JP2013-061648A is formed on the resist film. As the basic compound which can be included in the topcoat, for example, basic compounds described in the pamphlet of WO2017/002737A can also be used.

In addition, it is also preferable that the topcoat includes a compound which includes at least one group or bond selected from the group consisting of an ether bond, a thioether bond, a hydroxyl group, a thiol group, a carbonyl bond, and an ester bond.

[Step X2: Exposing Step]

As shown in FIG. 2, the step X2 is a step of exposing the resist film 2 obtained through the step X1 in a patterned manner through a predetermined mask 3.

In a case where the step X2 is performed, by decomposing the specific photodegradable ion compound in the resist film 2 in the exposed portion (which is an opening region of the mask, and corresponds to a region indicated by an arrow in FIG. 2), the association structure of the specific resin and the specific photodegradable ion compound is released. As a result, in the exposed portion, the solubility in the organic solvent-based developer is improved. On the other hand, in the non-exposed portion (which is a non-opened region of the mask, and corresponds to a region without the arrow in FIG. 2), the above-described association structure is still maintained, and the solubility in the organic solvent-based developer remains almost unchanged. That is, by going through the above-described step X2, a difference in solubility (dissolution contrast) in the organic solvent-based developer may occur between the exposed portion and the non-exposed portion of the resist film.

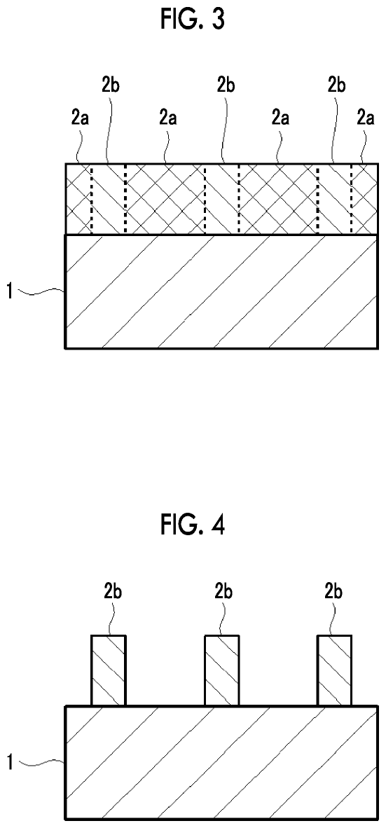

Accordingly, as shown in FIG. 3, by going through the step X2, a region 2a (exposed portion) with high solubility in the organic solvent-based developer and a region 2b (non-exposed portion) with low solubility or insolubility in the organic solvent-based developer are formed.

A light source wavelength used in the exposing step is not limited, and examples thereof include infrared rays, visible light, ultraviolet rays, far ultraviolet rays, extreme ultraviolet rays (EUV), X-rays, and electron beams. Among these, far ultraviolet rays are preferable, and a wavelength thereof is preferably 250 nm or less, more preferably 220 nm or less, and still more preferably 1 to 200 nm. Specifically, a KrF excimer laser (248 nm), an ArF excimer laser (193 nm), an F₂ excimer laser (157 nm), X-rays, EUV (13 nm), or electron beam is preferable, a KrF excimer laser, an ArF excimer laser, EUV, or electron beam is more preferable, and EUV or electron beam is still more preferable.

The exposure method in the exposing step of the above-described step X2 may be a liquid immersion exposure. In addition, the exposing step may be divided into a plurality of times to perform the exposure.

An exposure amount may be set such that the specific photodegradable ion compound present in the exposed portion 2a can be further decomposed by light absorption.

A heating (post exposure bake (also referred to as a “bake after exposure”); PEB) step may be performed after exposure and before development.

A heating temperature is preferably 80° C. to 150° C., more preferably 80° C. to 140° C., and still more preferably 80° C. to 130° C.

A heating time is preferably 10 to 1000 seconds, more preferably 10 to 180 seconds, and still more preferably 30 to 120 seconds.

The heating can be carried out using a unit included in an ordinary exposure machine and/or development machine, and may also be performed using a hot plate or the like. In addition, the heating may be carried out in a plurality of times.

[Step X3: Developing Step]

The step X3 is a step of developing the exposed resist film using an organic solvent-based developer to form a pattern. As shown in FIG. 4, by going through the step X3, the exposed portion 2a is dissolved and removed in the organic solvent-based developer, and the non-exposed portion 2b remains as a film to form a positive tone resist pattern. That is, the step X3 corresponds to a positive developing step.

<Organic Solvent-Based Developer>

The organic solvent-based developer represents a developer including an organic solvent.

A vapor pressure of the organic solvent included in the organic solvent-based developer (in a case of a mixed solvent, a vapor pressure as a whole) is preferably 5 kPa or less, more preferably 3 kPa or less, and still more preferably 2 kPa or less at 20° C. By setting the vapor pressure of the organic solvent to 5 kPa or less, evaporation of the developer on the substrate or in a development cup is suppressed, temperature uniformity in a wafer plane is improved, and as a result, dimensional uniformity in the wafer plane is improved.

The organic solvent-based developer is preferably a developer containing at least one organic solvent selected from the group consisting of a ketone-based solvent, an ester-based solvent, an alcohol-based solvent, an amide-based solvent, an ether-based solvent, and a hydrocarbon-based solvent.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, and propylene carbonate.

Examples of the ester-based solvent include butyl acetate, isobutyl acetate, methyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, and butyl propionate.

As the alcohol-based solvent, the amide-based solvent, the ether-based solvent, and the hydrocarbon-based solvent, the solvents described in paragraphs [0715] to [0718] of the specification of US2016/0070167A1 can be used.

Among these, in a case where EUV or electron beam is used in the above-described exposing step, as the organic solvent included in the organic solvent-based developer, from the viewpoint that it is possible to further suppress swelling of the resist film, it is preferable to use an ester-based solvent having 6 or more (preferably 7 or more, and preferably 14 or less, more preferably 12 or less, and still more preferably 10 or less) carbon atoms and 2 or less heteroatoms.

The heteroatom of the ester-based solvent is an atom other than a carbon atom and a hydrogen atom, and examples thereof include an oxygen atom, a nitrogen atom, and a sulfur atom. The number of the heteroatoms is preferably 2 or less.

As the ester-based solvent having 6 or more carbon atoms and 2 or less heteroatoms, butyl acetate, isobutyl acetate, amyl acetate, isoamyl acetate, 2-methylbutyl acetate, 1-methylbutyl acetate, hexyl acetate, pentyl propionate, hexyl propionate, butyl propionate, isobutyl isobutyrate, heptyl propionate, or butyl butanoate is preferable.

In addition, in a case where EUV or electron beam is used in the above-described exposing step, as the organic solvent included in the organic solvent-based developer, from the viewpoint that it is possible to further suppress swelling of the resist film, it is also preferable to use a mixed solvent of an ester-based solvent and a hydrocarbon-based solvent or a mixed solvent of a ketone-based solvent and a hydrocarbon-based solvent.

In a case where a mixed solvent of an ester-based solvent and a hydrocarbon-based solvent is used as the organic solvent included in the organic solvent-based developer, examples of the ester-based solvent include the above-described ester-based solvent having 6 or more carbon atoms and 2 or less heteroatoms, and isoamyl acetate is preferable. In addition, from the viewpoint of adjusting the solubility of the resist film, as the hydrocarbon-based solvent, a saturated hydrocarbon solvent (for example, octane, nonane, decane, dodecane, undecane, and hexadecane) is preferable.

In a case where a mixed solvent of a ketone-based solvent and a hydrocarbon-based solvent is used as the organic solvent included in the organic solvent-based developer, examples of the ketone-based solvent include the above-described ketone-based solvent, and 2-heptanone is preferable. In addition, from the viewpoint of adjusting the solubility of the resist film, as the hydrocarbon-based solvent, a saturated hydrocarbon solvent (for example, octane, nonane, decane, dodecane, undecane, and hexadecane) is preferable.

In a case of using the above-described mixed solvent, since a content of the hydrocarbon-based solvent depends on the solubility of the resist film in a solvent, the content is not particularly limited, and the content may be appropriately adjusted to determine a necessary amount of the hydrocarbon-based solvent.

In the organic solvent-based developer, a plurality of organic solvents may be mixed, or may be mixed with an organic solvent other than the above or water and used. However, in order to fully exert the effects of the present invention, a moisture content of the organic solvent-based developer as a whole is preferably less than 10% by mass, and the organic solvent-based developer is more preferably substantially free of the moisture. A concentration of the organic solvent (in a case of mixing a plurality of organic solvents, a total thereof) in the organic solvent-based developer is preferably 50% by mass or more, more preferably 60% by mass or more, still more preferably 85% by mass or more, particularly preferably 90% by mass or more, and most preferably 95% by mass or more. The upper limit value thereof is, for example, 100% by mass or less.

The organic solvent-based developer may include an appropriate amount of a known surfactant as necessary.

A content of the surfactant is usually 0.001% to 5% by mass, preferably 0.005% to 2% by mass, and still more preferably 0.01% to 0.5% by mass with respect to the total amount of the organic solvent-based developer.

Examples of a developing method include a method in which the substrate is immersed in a tank filled with the organic solvent-based developer for a certain period of time (a dipping method), a method in which a development is performed by heaping the organic solvent-based developer up onto the surface of the substrate by surface tension, and then leaving it to stand for a certain period of time (a paddling method), a method in which the organic solvent-based developer is sprayed on the surface of the substrate (a spraying method), and a method in which the organic solvent-based developer is continuously jetted onto the substrate rotating at a constant rate while scanning a developer jetting nozzle at a constant rate (a dynamic dispensing method).

In addition, after the step of performing the development, a step of stopping the development may be carried out while replacing the solvent with another solvent.

A developing time is not particularly limited as long as it is a period of time where the non-exposed portion of the resin is sufficiently dissolved, and is preferably 10 to 300 seconds and more preferably 20 to 120 seconds.

A temperature of the developer is preferably 0° C. to 50° C. and more preferably 15° C. to 35° C.

### Other Embodiments

The pattern forming method according to the embodiment of the present invention is not limited to the above-described first embodiment, and for example, may be an embodiment having other steps in addition to the above-described steps X1 to X3. Hereinafter, other steps which may be included in the pattern forming method according to the embodiment of the present invention will be described.

[Other Steps]

<Rinsing Step>

It is preferable that the pattern forming method includes a step of performing washing using a rinsing liquid after the step X3.

The rinsing liquid is not particularly limited as long as the pattern is not dissolved, and a solution including a general organic solvent can be used. As the rinsing liquid, a rinsing liquid including at least one organic solvent selected from the group consisting of a hydrocarbon-based solvent, a ketone-based solvent, an ester-based solvent, an alcohol-based solvent, an amide-based solvent, and an ether-based solvent is preferable.

A method for the rinsing step is not particularly limited, and examples thereof include a method in which the rinsing liquid is continuously jetted onto the substrate rotated at a constant rate (a spin coating method), a method in which the substrate is immersed in a tank filled with the rinsing liquid for a certain period of time (a dipping method), and a method in which the rinsing liquid is sprayed on the surface of the substrate (a spraying method).

In addition, the above-described pattern forming method may include a heating step (post baking) after the rinsing step. By this step, the organic solvent-based developer and the rinsing liquid remaining between and inside the patterns are removed. In addition, this step also has an effect that a resist pattern is annealed and the surface roughness of the pattern is improved.

A heating temperature in the heating step after the rinsing step is preferably 40° C. to 250° C. and more preferably 80° C. to 200° C. In addition, a heating time is preferably 10 seconds to 3 minutes and more preferably 30 to 120 seconds.

<Etching Step>

In addition, an etching treatment on the substrate may be carried out using the formed pattern as a mask.

For etching, any of known methods can be used, and various conditions and the like are appropriately determined according to the type of the substrate, usage, and the like. The etching can be carried out, for example, in accordance with Journal of The International Society for Optical Engineering (Proc. of SPIE), Vol. 6924, 692420 (2008), JP2009-267112A, and the like. In addition, the etching can also be carried out in accordance with “Chapter 4 Etching” in “Semiconductor Process Text Book, 4^{th} Ed., published in 2007, publisher: SEMI Japan”.

<Purifying Step>

The above-described pattern forming method may include a step of purifying the specific resist composition used in the pattern forming method and various materials other than the specific resist composition (for example, a developer, a rinsing liquid, a composition for forming an antireflection film, a composition for forming a topcoat, and the like).

A content of impurities included in the specific resist composition and various materials other than the specific resist composition is preferably 1 ppm by mass or less, more preferably 10 ppb by mass or less, still more preferably 100 ppt by mass or less, particularly preferably 10 ppt by mass or less, and most preferably 1 ppt by mass or less. Here, examples of the metal impurities include Na, K, Ca, Fe, Cu, Mg, Al, Li, Cr, Ni, Sn, Ag, As, Au, Ba, Cd, Co, Pb, Ti, V, W, and Zn.

Examples of a method for removing the impurities such as metals from the various materials include filtration using a filter. As for a filter pore diameter, the pore size is preferably less than 100 nm, more preferably 10 nm or less, and still more preferably 5 nm or less. As a filter, a polytetrafluoroethylene-made filter, a polyethylene-made filter, or a nylon-made filter is preferable. The filter may be composed of a composite material in which the above-described filter material is combined with an ion exchange medium. As the filter, a filter which has been washed with an organic solvent in advance may be used. In the step of filter filtration, plural kinds of filters connected in series or in parallel may be used. In a case of using the plural kinds of filters, a combination of filters having different pore diameters and/or materials may be used. In addition, various materials may be filtered plural times, and the step of filtering plural times may be a circulatory filtration step.

In the production of the specific resist composition, for example, it is preferable to dissolve the respective components such as the specific resin and the specific photodegradable ion compound in the solvent, and then perform a circulatory filtration using a plurality of filters having different materials. For example, it is preferable to connect a polyethylene-made filter having a pore diameter of 50 nm, a nylon-made filter having a pore diameter of 10 nm, and a polyethylene-made filter having a pore diameter of 3 mu in permuted connection, and then perform the circulatory filtration ten times or more. A smaller pressure difference between the filters is more preferable, and the pressure difference is generally 0.1 MPa or less, preferably 0.05 MPa or less, and more preferably 0.01 MPa or less. A smaller pressure difference between the filter and the charging nozzle is more preferable, and the pressure difference is generally 0.5 MPa or less, preferably 0.2 MPa or less, and more preferably 0.1 MPa or less.

It is preferable to subject the inside of a production device of the specific resist composition to a gas replacement with an inert gas such as nitrogen. As a result, it is possible to suppress the dissolution of an active gas such as oxygen in the specific resist composition.

After being filtered by a filter, the specific resist composition is charged into a clean container. It is preferable that the specific resist composition charged in the container is stored in a refrigerator. As a result, performance deterioration over time is suppressed. A shorter time from the completion of charging the composition into the container to the start of the storage in a refrigerator is more preferable, and the time is generally 24 hours or less, preferably 16 hours or less, more preferably 12 hours or less, and still more preferably 10 hours or less. A storage temperature is preferably 0° C. to 15° C., more preferably 0° C. to 10° C., and still more preferably 0° C. to 5° C.

In addition, examples of a method for reducing the impurities such as metals included in the various materials include a method of selecting raw materials having a low content of metals as raw materials constituting the various materials, a method of subjecting raw materials constituting the various materials to filter filtration, and a method of performing distillation under the condition for suppressing the contamination as much as possible by, for example, lining the inside of a device with TEFLON (registered trademark).

In addition to the filter filtration, removal of the impurities by an adsorbing material may be performed, or a combination of filter filtration and an adsorbing material may be used. As the adsorbing material, known adsorbing materials can be used, and for example, inorganic adsorbing materials such as silica gel and zeolite and organic adsorbing materials such as activated carbon can be used. It is necessary to prevent the incorporation of impurities such as metals in the production process in order to reduce the metal impurities included in the above-described various materials. Whether or not the metal impurities are sufficiently removed from the production device can be confirmed by measuring the content of metal components included in a washing solution used to wash the production device. A content of the metal components included in the washing solution after the use is preferably 100 parts per trillion (ppt) by mass or less, more preferably 10 ppt by mass or less, and still more preferably 1 ppt by mass or less.

A conductive compound may be added to an organic treatment liquid such as the organic solvent-based developer and the rinsing liquid in order to prevent breakdown of chemical liquid pipes and various parts (a filter, an O-ring, a tube, or the like) due to electrostatic charging, and subsequently generated electrostatic discharging. The conductive compound is not particularly limited, and examples thereof include methanol. An addition amount is not particularly limited, but from the viewpoint that preferred development characteristics or rinsing characteristics are maintained, the addition amount is preferably 10% by mass or less and more preferably 5% by mass or less.

For members of the chemical liquid pipe, for example, various pipes coated with stainless steel (SUS), or a polyethylene, polypropylene, or a fluororesin (a polytetrafluoroethylene resin, a perfluoroalkoxy resin, or the like) that has been subjected to an antistatic treatment can be used. In the same manner, for the filter or the O-ring, polyethylene, polypropylene, or a fluororesin (polytetrafluoroethylene, a perfluoroalkoxy resin, or the like) that has been subjected to an antistatic treatment can be used.

[Actinic Ray-Sensitive or Radiation-Sensitive Resin Composition]

Hereinafter, the actinic ray-sensitive or radiation-sensitive resin composition (specific resist composition) used in the step X1 will be described.

<Specific Photodegradable Ion Compound>

The specific resist composition includes a compound (specific photodegradable ion compound) including two or more ion pairs which are decomposed by an irradiation with an actinic ray or a radiation and having a molecular weight of 5,000 or less.

The above-described ion pair is composed of a cationic moiety, which is a positively charged atomic group having a total valence of W, and an anionic moiety, which is a negatively charged atomic group having a total valence of W. That is, the above-described ion pair is composed of a cationic moiety and an anionic moiety having the same absolute value of valence. The above-described ion pair may have a salt structure, or a structure in which the cationic moiety and the anionic moiety are linked by a covalent bond (so-called betaine structure).

In the specific photodegradable ion compound, it is preferable that the cationic moiety represents a positively charged atomic group having a valence of 1, and the anionic moiety represents a negatively charged atomic group having a valence of 1.

As the specific photodegradable ion compound, for example, a compound having an ion pair consisting of a cationic moiety which has absorption to actinic ray or radiation and an anionic moiety which can form a protonated structure upon irradiation with actinic ray or radiation is preferable, and for example, a compound having an ion pair consisting of a sulfonium cationic moiety or an iodonium cationic moiety and a non-nucleophilic anionic moiety is preferable.

The number of ion pairs described above, included in the specific photodegradable ion compound, is not particularly limited as long as it is 2 or more. From the viewpoint that the resolution and/or LER performance of the formed pattern is more excellent, the upper limit value thereof is preferably 20 or less, more preferably 10 or less, still more preferably 6 or less, particularly preferably 5 or less, and most preferably 4 or less.

A molecular weight (in a case where the specific photodegradable ion compound is a polymer compound and a molecular weight thereof has a distribution, the molecular weight is intended to be a weight-average molecular weight) of the specific photodegradable ion compound is not particularly limited as long as it is 5,000 or less. From the viewpoint that the resolution and/or LER performance of the formed pattern is more excellent, the lower limit value thereof is preferably 250 or more, more preferably 500 or more, and still more preferably 600 or more. In addition, the upper limit value thereof is preferably 3,000 or less and more preferably 2,000 or less.

Examples of the specific photodegradable ion compound include compounds represented by General Formulae (EX1) to (EX3).

Hereinafter, the compound represented by General Formula (EX1) will be described.

(Compound Represented by General Formula (EX1))

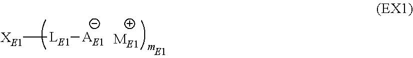

In General Formula (EX1), X_{E1} represents a single bond or an m_{E1}-valent linking group. L_{E1} represents a single bond or a divalent linking group. m_{E1} represents an integer of 2 to 4. A_{E1}⁻ represents an anionic moiety. M_{E1}⁺ represents a cationic moiety. A plurality of L_{E1}'s, A_{E1}⁻'s, and M_{E1}⁺'s may be the same or different from each other.

In General Formula (EX1), A_{E1}⁻ and M_{E1}⁺ form an ion pair (salt structure). In addition, in a case where X_{E1} represents a single bond, m_{E1} represents 2. That is, in a case where X_{E1} represents a single bond, General Formula (EX1) is represented by the following formula.

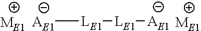

In General Formula (EX1), the m_{E1}-valent linking group represented by X_{E1} is not particularly limited, and examples thereof include linking groups represented by General Examples (EX1-a1) to (EX1-a3). In General Examples (EX1-a1) to (EX1-a3), * represents a bonding position with L_{E1} specified in General Formula (EX1).

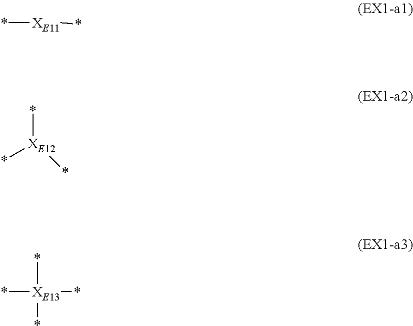

In General Examples (EX1-a1) to (EX1-a3), X_{E11}, X_{E12}, and X_{E13} each independently represent an organic group. The organic group represented by X_{E11} constitutes a divalent linking group. In other words, the organic group represented by X_{E11} has two bonding positions (*) with L_{E1} in General Formula (EX1). Similarly, the organic group represented by X_{E12} constitutes a trivalent linking group, and the organic group represented by X_{E13} constitutes a tetravalent linking group.

Specific examples of the organic groups represented by X_{E11}, X_{E12}, and X_{E13} include hydrocarbon groups formed from hydrocarbons, which may include a heteroatom (examples of the heteroatom include a nitrogen atom, an oxygen atom, and a sulfur atom; in addition, the heteroatom may be included, for example, in a form of —O—, —S—, —SO₂—, —NR¹—, —CO—, or a linking group in which two or more of these groups are combined), and a linear or branched aliphatic hydrocarbon group, an alicyclic group, an aromatic hydrocarbon group, a heterocyclic group, or a linking group in which a plurality of these groups is combined is preferable.

The hydrocarbon group which may include a heteroatom, as the organic group represented by X_{E11}, means a divalent group formed by removing two hydrogen atoms from the above-described hydrocarbons which may include a heteroatom, the hydrocarbon group which may include a heteroatom, as the organic group represented by X_{E12}, means a trivalent group formed by removing three hydrogen atoms from the above-described hydrocarbons which may include a heteroatom, and the hydrocarbon group which may include a heteroatom, as the organic group represented by X_{E13}, means a tetravalent group formed by removing four hydrogen atoms from the above-described hydrocarbons which may include a heteroatom.

R¹ represents a hydrogen atom or a substituent. The above-described substituent is not particularly limited, but for example, an alkyl group (preferably having 1 to 6 carbon atoms; which may be linear or branched) is preferable.

The number of carbon atoms in the above-described linear or branched aliphatic hydrocarbon group is not particularly limited, but is preferably 1 to 10, more preferably 1 to 6, still more preferably 1 to 4, and particularly preferably 1 to 3.

The number of carbon atoms in the above-described alicyclic group is not particularly limited, but is preferably 3 to 30, more preferably 6 to 20, still more preferably 6 to 15, and particularly preferably 6 to 12. The alicyclic group may be monocyclic or polycyclic, and may be a spiro ring. Examples of an alicyclic ring constituting the monocyclic alicyclic group include monocyclic cycloalkanes such as cyclopentane, cyclohexane, and cyclooctane. Examples of an alicyclic ring constituting the polycyclic alicyclic group include polycyclic cycloalkanes such as norbornane, tricyclodecane, tetracyclodecane, tetracyclododecane, and adamantane.

The number of carbon atoms in an aromatic hydrocarbon ring constituting the above-described aromatic hydrocarbon group is not particularly limited, but is preferably 6 to 30, more preferably 6 to 20, still more preferably 6 to 15, and particularly preferably 6 to 12. The aromatic hydrocarbon group may be monocyclic or polycyclic. Examples of the above-described aromatic hydrocarbon ring include a benzene ring and a naphthalene ring.

The number of carbon atoms in a heterocyclic ring constituting the above-described heterocyclic group is not particularly limited, but is preferably 3 to 25, more preferably 3 to 20, still more preferably 6 to 20, particularly preferably 6 to 15, and most preferably 6 to 10. In addition, the above-described heterocyclic ring may be monocyclic or polycyclic, and may be an aromatic heterocyclic ring or an aliphatic heterocyclic ring. Further, the above-described heterocyclic ring may be a Spiro ring. Examples of the aromatic heterocyclic ring include a furan ring, a thiophene ring, a benzofuran ring, a benzothiophene ring, a dibenzofuran ring, a dibenzothiophene ring, and a pyridine ring. Examples of the aliphatic heterocyclic ring include a tetrahydropyran ring, a lactone ring, a sultone ring, and a decahydroisoquinoline ring.

The above-described linear or branched aliphatic hydrocarbon group, alicyclic group, aromatic hydrocarbon group, and heterocyclic group may further have a substituent. Examples of this substituent include an alkyl group, a cycloalkyl group, an aryl group, a hydroxyl group, an alkoxy group, an ester group, an amide group, a urethane group, a ureido group, a thioether group, a sulfonamide group, and a sulfonic acid ester group.

Among these, as X_{E11}, a linear or branched aliphatic hydrocarbon group which may have a substituent, an alicyclic group which may have a substituent, or an aliphatic heterocyclic group which may have a substituent is preferable.

Among these, as X_{E12} and X_{E13}, a linear or branched aliphatic hydrocarbon group which may have a substituent, an alicyclic group which may have a substituent, or an aliphatic heterocyclic group which may have a substituent is preferable.

In General Formula (EX1), the divalent linking group represented by LEI is not particularly limited, but is preferably a divalent linking group in which one or two or more selected from the group consisting of an alkylene group, an arylene group, —CO—, —CONR^{N}—, —O—, and —S— are combined, more preferably a divalent linking group in which one or two or more selected from the group consisting of an alkylene group, an arylene group, —CO—, —O—, and —S— are combined, and still more preferably a divalent linking group in which one or two or more selected from the group consisting of an alkylene group, an arylene group, and —COO— are combined.

The above-described alkylene group may be linear, branched, or cyclic. The number of carbon atoms in the alkylene group is preferably 1 to 10 and more preferably 1 to 4.

The number of carbon atoms in the above-described arylene group is preferably 6 to 10, and a benzene ring group is more preferable.

The above-described alkylene group and the above-described arylene group may have a substituent. The substituent is not particularly limited, and examples thereof include a fluorine atom. In a case where the above-described alkylene group includes a fluorine atom as the substituent, the divalent linking group may be a perfluoroalkylene group. The R^{N} represents a hydrogen atom or a substituent. The above-described substituent is not particularly limited, but for example, an alkyl group (preferably having 1 to 6 carbon atoms; which may be linear or branched) is preferable.

In General Formula (EX1), A_{E1}⁻ represents an anionic moiety.

The anionic moiety represented by A_{E1}⁻ is not particularly limited, and examples thereof include anionic functional groups represented by General Formulae (EX1-b1) to (EX1-b10).

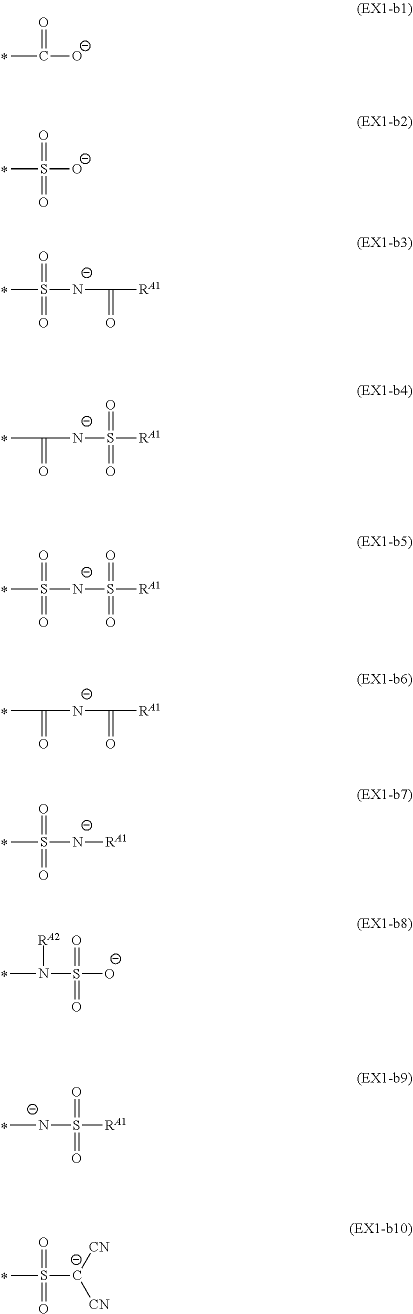

In General Formulae (EX1-b1) to (EX1-b10), * represents a bonding position.

It is also preferable that * in General Formula (EX1-b9) is a bonding position to a group which is neither —CO— nor —SO₂—.

In General Formulae (EX1-b3) to (EX1-b7) and (EX1-b9), R^{A1} represents an organic group.

As RAI, an alkyl group (may be linear or branched; the number of carbon atoms is preferably 1 to 15), a cycloalkyl group (may be monocyclic or polycyclic; the number of carbon atoms is preferably 3 to 20), or an aryl group (may be monocyclic or polycyclic; the number of carbon atoms is preferably 6 to 20) is preferable. The above-described alkyl group, cycloalkyl group, and aryl group, which are represented by R^{A1}, may further have a substituent.

In General Formula (EX1-b7), an atom directly bonded to N⁻ in R^{A1} is preferably neither a carbon atom in —CO— nor a sulfur atom in —SO₂—.

Examples of the above-described cycloalkyl group include a norbornyl group and an adamantyl group.

As a substituent which may be included in the above-described cycloalkyl group, an alkyl group (may be linear or branched; preferably having 1 to 5 carbon atoms) is preferable. In addition, one or more of the carbon atoms which are ring member atoms of the above-described cycloalkyl group may be substituted with a carbonyl carbon atom.

In the above-described alkyl group, the number of carbon atoms in the alkyl group is preferably 1 to 10 and more preferably 1 to 5.

As a substituent which may be included in the above-described alkyl group, a cycloalkyl group, a fluorine atom, or a cyano group is preferable. Examples of the cycloalkyl group as the substituent include those of the cycloalkyl group described in a case where R^{A1} is the cycloalkyl group.

In a case where the above-described alkyl group has a fluorine atom as a substituent, the above-described alkyl group may be a perfluoroalkyl group.

In addition, one or more of —CH₂-'s in the above-described alkyl group may be substituted with a carbonyl group.

As the above-described aryl group, a benzene ring group is preferable.

As a substituent which may be included in the above-described aryl group, an alkyl group, a fluorine atom, or a cyano group is preferable. Examples of the alkyl group as the above-described substituent include those of the alkyl group described in a case where R^{A1} is the cycloalkyl group, and a perfluoroalkyl group is preferable and a perfluoromethyl group is more preferable.

R^{A1} in General Formula (EX1-b5) preferably represents a perfluoroalkyl group. The number of carbon atoms in the above-described perfluoroalkyl group is preferably 1 to 15, more preferably 1 to 10, and still more preferably 1 to 6.

R^{A2} in General Formula (EX1-b8) represents a hydrogen atom or a substituent. The above-described substituent is not particularly limited, but for example, an alkyl group (preferably having 1 to 6 carbon atoms; which may be linear or branched) is preferable.

Among these, as A_{E1}⁻, (EX1-b1) or (EX1-b2) is preferable.

In General Formula (EX1), M_{E1}⁺ represents a cationic moiety.

As the cationic moiety represented by M_{E1}⁺, from the viewpoint that a sensitivity, a resolution of the formed pattern, and/or LER is more excellent, an organic cation (cation (ZaI)) represented by General Formula (ZaI) or an organic cation (cation (ZaII)) represented by General Formula (ZaII) is preferable.

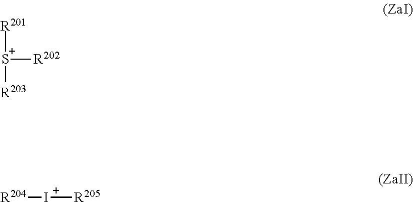

In General Formula (ZaI), R²⁰¹, R²⁰², and R²⁰³ each independently represent an organic group.

The number of carbon atoms in the organic group of R²⁰¹, R²⁰², and R²⁰³ is usually 1 to 30, and preferably 1 to 20. In addition, two of R²⁰¹ to R²⁰³ may be bonded to each other to form a ring structure, and the ring structure may include an oxygen atom, a sulfur atom, an ester group, an amide group, or a carbonyl group in the ring. Examples of the group formed by the bonding of two of R²⁰¹ to R²⁰³ include an alkylene group (for example, a butylene group and a pentylene group) and —CH₂—CH₂—O—CH₂—CH₂—.

Examples of suitable aspects of the organic cation in General Formula (ZaI) include a cation (ZaI-1), a cation (ZaI-2), an organic cation (cation (ZaI-3b)) represented by General Formula (ZaI-3b), and an organic cation (cation (ZaI-4b)) represented by General Formula (ZaI-4b), each of which will be described later.

First, the cation (ZaI-1) will be described.

The cation (ZaI-1) is an arylsulfonium cation in which at least one of R²⁰¹, R²⁰², or R²⁰³ of General Formula (ZaI) is an aryl group.

In the arylsulfonium cation, all of R²⁰¹ to R²⁰³ may be aryl groups, or some of R²⁰¹ to R²⁰³ may be an aryl group and the remaining may be an alkyl group or a cycloalkyl group.

In addition, one of R²⁰1 to R²⁰³ may be an aryl group, the remaining two of R²⁰¹ to R²⁰³ may be bonded to each other to form a ring structure, and an oxygen atom, a sulfur atom, an ester group, an amide group, or a carbonyl group may be included in the ring. Examples of the group formed by the bonding of two of R²⁰¹ to R²⁰³ include an alkylene group (for example, a butylene group, a pentylene group, or —CH₂—CH₂—O—CH₂—CH₂—) in which one or more methylene groups may be substituted with an oxygen atom, a sulfur atom, an ester group, an amide group, and/or a carbonyl group.

Examples of the arylsulfonium cation include a triarylsulfonium cation, a diarylalkylsulfonium cation, an aryldialkylsulfonium cation, a diarylcycloalkylsulfonium cation, and an aryldicycloalkylsulfonium cation.

The aryl group included in the arylsulfonium cation is preferably a phenyl group or a naphthyl group, and more preferably a phenyl group. The aryl group may be an aryl group which has a heterocyclic structure having an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. In a case where the arylsulfonium cation has two or more aryl groups, the two or more aryl groups may be the same or different from each other.

The alkyl group or the cycloalkyl group included in the arylsulfonium cation as necessary is preferably a linear alkyl group having 1 to 15 carbon atoms, a branched alkyl group having 3 to 15 carbon atoms, or a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group, and a cyclohexyl group.

Examples of substituents which may be included in the aryl group, the alkyl group, and the cycloalkyl group of R²⁰¹ to R²⁰³ each independently include an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a cycloalkylalkoxy group (for example, having 1 to 15 carbon atoms), a halogen atom, a hydroxyl group, and a phenylthio group.

The substituent may further have a substituent if possible, and may be in a form of an alkyl halide group such as a trifluoromethyl group, for example, in which an alkyl group has a halogen atom as a substituent.

Next, the cation (ZaI-2) will be described.

The cation (ZaI-2) is a cation in which R²⁰¹ to R²⁰³ in Formula (ZaI) are each independently a cation representing an organic group having no aromatic ring. Here, the aromatic ring also encompasses an aromatic ring including a heteroatom.

The number of carbon atoms in the organic group as R²⁰¹ to R²⁰³, which has no aromatic ring, is generally 1 to 30, and preferably 1 to 20.

R²⁰¹ to R²⁰³ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and still more preferably a linear or branched 2-oxoalkyl group.

Examples of the alkyl group and cycloalkyl group of R²⁰¹ to R²⁰³ include a linear alkyl group having 1 to 10 carbon atoms or a branched alkyl group having 3 to 10 carbon atoms (for example, a methyl group, an ethyl group, a propyl group, a butyl group, and a pentyl group), and a cycloalkyl group having 3 to 10 carbon atoms (for example, a cyclopentyl group, a cyclohexyl group, and a norbornyl group).

R²⁰¹ to R²⁰³ may further be substituted with a halogen atom, an alkoxy group (for example, having 1 to 5 carbon atoms), a hydroxyl group, a cyano group, or a nitro group.

Next, the cation (ZaI-3b) will be described.

The cation (ZaI-3b) is a cation represented by General Formula (ZaI-3b).

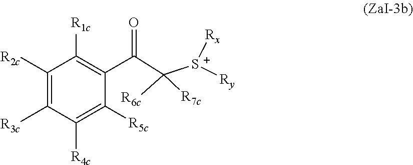

In General Formula (ZaI-3b),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} each independently represent a hydrogen atom, an alkyl group (a t-butyl group and the like), a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

Any two or more of R_{1c}, . . . , or R_{5c}, R_{5c} and R_{6c}, R_{6c} and R_{7c}, R_{5c} and Rₓ, and Rₓ and R_{y} may each be bonded to each other to form a ring, and the rings may each independently include an oxygen atom, a sulfur atom, a ketone group, an ester bond, or an amide bond.

Examples of the above-described ring include an aromatic or non-aromatic hydrocarbon ring, an aromatic or non-aromatic heterocyclic ring, and a polycyclic fused ring formed by a combination of two or more of these rings. Examples of the ring include a 3- to 10-membered ring, and the ring is preferably a 4- to 8-membered ring and more preferably a 5- or 6-membered ring.

Examples of the group formed by the bonding of any two or more of R_{1c}, . . . , or R_{5c}, R_{6c} and R_{7c}, and Rₓ and R_{y} include an alkylene group such as a butylene group and a pentylene group. A methylene group in this alkylene group may be substituted with a heteroatom such as an oxygen atom.

As the group formed by the bonding of R_{5c} and R_{6c}, and R_{5c}, and Rₓ, a single bond or an alkylene group is preferable. Examples of the alkylene group include a methylene group and an ethylene group.

Next, the cation (ZaI-4b) will be described.

The cation (ZaI-4b) is a cation represented by General Formula (ZaI-4b).

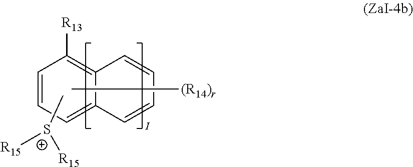

In General Formula (ZaI-4b),

l represents an integer of 0 to 2.

r represents an integer of 0 to 8.

R₁₃ represents a hydrogen atom, a fluorine atom, a hydroxyl group, an alkyl group, an alkoxy group, an alkoxycarbonyl group, or a group having a cycloalkyl group (which may be the cycloalkyl group itself or a group including the cycloalkyl group in a part thereof). These groups may have a substituent.

R₁₄ represents a hydroxyl group, an alkyl group, an alkoxy group, an alkoxycarbonyl group, an alkylcarbonyl group, an alkylsulfonyl group, a cycloalkylsulfonyl group, or a group having a cycloalkyl group (which may be the cycloalkyl group itself or a group including the cycloalkyl group in a part thereof). These groups may have a substituent. In a case where R₁₄'s are present in a plural number, R₁₄'s each independently represent the above-described group such as a hydroxyl group.

R₁₅'s each independently represent an alkyl group, a cycloalkyl group, or a naphthyl group. These groups may have a substituent. Two R₁₅'s may be bonded to each other to form a ring. In a case where two R₁₅'s are bonded to each other to form a ring, the ring skeleton may include a heteroatom such as an oxygen atom and a nitrogen atom. In one aspect, it is preferable that two R₁₅'s are alkylene groups and are bonded to each other to form a ring structure.

In General Formula (ZaI-4b), the alkyl group of R₁₃, R₁₄, and R₁₅ is linear or branched. The number of carbon atoms in the alkyl group is preferably 1 to 10. The alkyl group is more preferably a methyl group, an ethyl group, an n-butyl group, a t-butyl group, or the like.

Next, General Formula (ZaII) will be described.

In General Formula (ZaII), R²⁰⁴ and R²⁰⁵ each independently represent an aryl group, an alkyl group, or a cycloalkyl group.

The aryl group of R²⁰⁴ and R²⁰⁵ is preferably a phenyl group or a naphthyl group, and more preferably a phenyl group. The aryl group of R²⁰⁴ and R²⁰⁵ may be an aryl group which has a heterocyclic ring having an oxygen atom, a nitrogen atom, a sulfur atom, or the like. Examples of a skeleton of the aryl group having a heterocyclic ring include pyrrole, furan, thiophene, indole, benzofuran, and benzothiophene.

The alkyl group and cycloalkyl group of R²⁰⁴ and R²⁰⁵ are preferably a linear alkyl group having 1 to 10 carbon atoms or a branched alkyl group having 3 to 10 carbon atoms (for example, a methyl group, an ethyl group, a propyl group, a butyl group, and a pentyl group), or a cycloalkyl group having 3 to 10 carbon atoms (for example, a cyclopentyl group, a cyclohexyl group, and a norbornyl group).

The aryl group, the alkyl group, and the cycloalkyl group of R²⁰⁴ and R²⁰⁵ may each independently have a substituent. Examples of the substituent which may be included in each of the aryl group, the alkyl group, and the cycloalkyl group of R²⁰⁴ and R²⁰⁵ include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group.

Specific examples of the cationic moiety represented by M_{E1}⁺ in General Formula (EX1) include those described in paragraphs [0177] to [0188], [0193], [0197], and the like of JP2013-127526A.

(Compound Represented by General Formula (EX2))

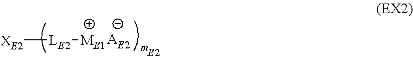

In General Formula (EX2), X_{E2} represents a single bond or an m_{E2}-valent linking group. L_{E2} represents a single bond or a divalent linking group. m_{E2} represents an integer of 2 to 4. M_{E2}⁺ represents a cationic moiety. A_{E2}⁻ represents an anionic moiety. A plurality of L_{E2}'s, M_{E2}⁺'s, and A_{E2}⁻'s may be the same or different from each other.

In General Formula (EX2), M_{E2}⁺ and A_{E2}⁻ form an ion pair (salt structure). In addition, same as X_{E1} in General Formula (EX1) described above, in a case where X_{E2} represents a single bond, m_{E2} represents 2.

Examples of the m_{E2}-valent linking group represented by X_{E2} and the divalent linking group represented by L_{E2} in General Formula (EX2) include the same linking groups as the m_{E1}-valent linking group represented by X_{E1} and the divalent linking group represented by L_{E1} in General Formula (EX1), and the suitable aspects thereof are also the same.

Examples of the anionic moiety represented by A_{E2}⁻ in General Formula (EX2) include an organic anion represented by General Formula (EX2-a1), an organic anion represented by General Formula (EX2-a2), an organic anion represented by General Formula (EX2-a3), and an organic anion represented by General Formula (EX2-a4).

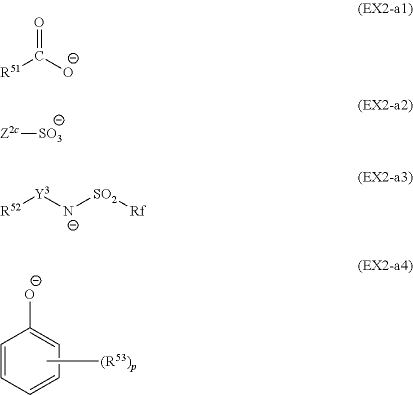

In General Formula (EX2-a1), R⁵¹ represents a monovalent organic group.

Specific examples of the monovalent organic group represented by R⁵¹ include hydrocarbon groups formed by removing one hydrogen atom from hydrocarbons, which may include a heteroatom (examples of the heteroatom include a nitrogen atom, an oxygen atom, and a sulfur atom; in addition, the heteroatom may be included, for example, in a form of —O—, —S—, —SO₂—, —NR^{A}—, —CO—, or a linking group in which two or more of these groups are combined), and a linear or branched aliphatic hydrocarbon group, an alicyclic group, an aromatic hydrocarbon group, or a heterocyclic group is preferable.

The R^{A} represents a hydrogen atom or a substituent. The substituent is not particularly limited, but for example, an alkyl group (preferably having 1 to 6 carbon atoms; which may be linear or branched) is preferable.

In addition, the above-described linear or branched aliphatic hydrocarbon group, alicyclic group, aromatic hydrocarbon group, and heterocyclic group may further have a substituent.

Specific examples of the above-described linear or branched aliphatic hydrocarbon group, alicyclic group, aromatic hydrocarbon group, and heterocyclic group and the substituent which may be included therein are each the same as the linear or branched aliphatic hydrocarbon group, alicyclic group, aromatic hydrocarbon group, and heterocyclic group, which are described as one example of the hydrocarbon group which may include a heteroatom, represented by X_{E11}, X_{E12}, and X_{E13} of General Formulae (EX1-a1) to (EX1-a3) described above, and the substituent which may be included therein.

The linear or branched aliphatic hydrocarbon group represented by R⁵¹ may be an alkyl group, an alkenyl group, or an alkynyl group, but an alkyl group is preferable. The number of carbon atoms in the above-described alkyl group is preferably 1 to 10, more preferably 1 to 6, and still more preferably 1 to 4. As the aromatic hydrocarbon group represented by R⁵¹, a phenyl group or a naphthyl group is preferable.

In General Formula (EX2-a2), Z^{2c} represents a monovalent hydrocarbon group having 1 to 30 carbon atoms, which may include a heteroatom (however, a fluorine atom is not substituted for a carbon atom adjacent to S).

Examples of the heteroatom include a nitrogen atom, an oxygen atom, and a sulfur atom. In addition, the heteroatom may be included, for example, in a form of —O—, —S—, —SO₂—, —NR^{A}—, —CO—, or a linking group in which two or more of these groups are combined. The R^{A} represents a hydrogen atom or a substituent. The substituent is not particularly limited, but for example, an alkyl group (preferably having 1 to 6 carbon atoms; which may be linear or branched) is preferable.

As the above-described hydrocarbon group, a linear or branched aliphatic hydrocarbon group, an alicyclic group, an aromatic hydrocarbon group, or a heterocyclic group is preferable. The above-described linear or branched aliphatic hydrocarbon group, alicyclic group, aromatic hydrocarbon group, and heterocyclic group may further have a substituent.

Specific examples of the above-described linear or branched aliphatic hydrocarbon group, alicyclic group, aromatic hydrocarbon group, and heterocyclic group and the substituent which may be included therein are each the same as the linear or branched aliphatic hydrocarbon group, alicyclic group, aromatic hydrocarbon group, and heterocyclic group, which are described as one example of the hydrocarbon group which may include a heteroatom, represented by X_{E11}, X_{E12}, and X_{E13} of General Formulae (EX1-a1) to (EX1-a3) described above, and the substituent which may be included therein.

As the monovalent hydrocarbon group having 1 to 30 carbon atoms, which may include a heteroatom, represented by Z^{2c}, for example, a group having a norbornyl group which may have a substituent is preferable. Carbon atoms forming the above-described norbornyl group may be a carbonyl carbon.

In General Formula (EX2-a3), R⁵² represents a monovalent organic group.

Examples of the monovalent organic group represented by R⁵² include the same as the monovalent organic group represented by R⁵¹ described above.

Y³ represents a linear or branched alkylene group, a cycloalkylene group, an arylene group, or a carbonyl group.

The number of carbon atoms in the linear or branched alkylene group represented by Y³ is preferably 1 to 10, more preferably 1 to 6, still more preferably 1 to 4, and particularly preferably 1 to 3.

The number of carbon atoms in the above-described cycloalkylene group represented by Y³ is preferably 6 to 20 and more preferably 6 to 12.

The number of carbon atoms in the above-described arylene group represented by Y³ is preferably 6 to 20 and more preferably 6 to 10.

The linear or branched alkylene group, cycloalkylene group, and arylene group represented Y³ may further have a substituent. Examples of the substituent include a fluorine atom and a fluorinated alkyl group having 1 to 5 carbon atoms, which is substituted with a fluorine atom.

Rf represents a hydrocarbon group including a fluorine atom.

As the hydrocarbon group including a fluorine atom, represented by Rf, a fluorinated alkyl group is preferable.

In General Formula (EX2-a4), R⁵³ represents a monovalent substituent. The substituent is not particularly limited, and examples thereof include an alkyl group, an alkoxy group, and a fluorine atom.

p represents an integer of 0 to 5. p is preferably 0 to 3 and more preferably 0.

Specific examples of the anionic moiety represented by A_{E2}⁻ in General Formula (EX2) include those described in paragraphs [0215], [0216], [0220], [0229], [0230], and the like of JP2013-127526A.

In General Formula (EX2), M_{E2}⁺ represents a cationic moiety.

As the cationic moiety represented by M_{E2}⁺, from the viewpoint that a sensitivity, a resolution of the formed pattern, and/or LER is more excellent, a cationic moiety represented by General Formula (EX2-b1) or a cationic moiety represented by General Formula (EX2-b2) is preferable.

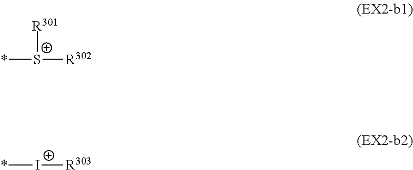

In General Formula (EX2-b1), R³⁰¹ and R³⁰² each independently represent an organic group.

The number of carbon atoms in the organic group of R³⁰¹ and R³⁰² is usually 1 to 30, and preferably 1 to 20. In addition, R³⁰¹ and R³⁰² may be bonded to each other to form a ring structure, and the ring structure may include an oxygen atom, a sulfur atom, an ester group, an amide group, or a carbonyl group in the ring. Examples of the group formed by the bonding of R³⁰¹ and R³⁰² include an alkylene group (for example, a butylene group and a pentylene group) and —CH₂—CH₂—O—CH₂—CH₂—.

In a case where L_{E2} specified in General Formula (EX2) represents a divalent linking group, R³⁰¹ and R³⁰² may be each independently bonded to L_{E2} to form a cyclic structure. Examples of a suitable aspect of the combination of the divalent linking group represented by L_{E2} and the cationic moiety represented by M_{E2}⁺ in General Formula (EX2-b1) include an aspect in which a linking portion (hereinafter, also referred to as a “specific linking portion”) of the divalent linking group represented by L_{E2} with the cationic moiety represented by General Formula (EX2-b1) is an arylene group and R³⁰¹ and R³⁰² are also aryl groups, and an aspect in which the specific linking portion is an arylene group and R³⁰¹ and R³⁰² are bonded to each other to form the above-described ring structure.

Among these, as R³⁰¹ and R³⁰², an aryl group is preferable, a phenyl group or a naphthyl group is more preferable, and a phenyl group is still more preferable.

The aryl group represented by R³⁰¹ and R³⁰² may further have a substituent. Examples of the above-described substituent each independently include an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a cycloalkylalkoxy group (for example, having 1 to 15 carbon atoms), a halogen atom, a hydroxyl group, and a phenylthio group. The substituent may further have a substituent if possible, and may be in a form of an alkyl halide group such as a trifluoromethyl group, for example, in which an alkyl group has a halogen atom as a substituent.

In General Formula (EX2-b2), R³⁰³ represents an aryl group, an alkyl group, or a cycloalkyl group.

The aryl group of R³⁰³ is preferably a phenyl group or a naphthyl group, and more preferably a phenyl group. The aryl group of R³⁰³ may be an aryl group which has a heterocyclic ring having an oxygen atom, a nitrogen atom, a sulfur atom, or the like. Examples of a skeleton of the aryl group having a heterocyclic ring include pyrrole, furan, thiophene, indole, benzofuran, and benzothiophene.

The alkyl group and cycloalkyl group represented by R³⁰³ are preferably a linear alkyl group having 1 to 10 carbon atoms or a branched alkyl group having 3 to 10 carbon atoms (for example, a methyl group, an ethyl group, a propyl group, a butyl group, and a pentyl group), or a cycloalkyl group having 3 to 10 carbon atoms (for example, a cyclopentyl group, a cyclohexyl group, and a norbornyl group).

The aryl group, alkyl group, and cycloalkyl group represented by R³⁰³ may have a substituent. Examples of the substituent which may be included in the aryl group, the alkyl group, and the cycloalkyl group of R³⁰³ include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group.

As the compound represented by General Formula (EX2), among these, a compound represented by General Formula (EX2-A) is preferable.

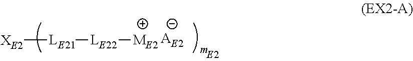

X_{E2}, L_{E21}, A_{E2}⁻, and m_{E2} in General Formula (EX2-A) are the same as X_{E2}, L_{E2}, A_{E2}⁻, and m_{E2} in General Formula (EX2).

M_{E2}⁺ represents the cationic moiety represented by General Formula (EX2-b1) described above.

L_{E22} in General Formula (EX2-A) represents an arylene group which may have a substituent.

As the arylene group represented by L_{E22}, a phenylene group or a naphthylene group is preferable, and a phenylene group is more preferable.

Examples of the substituent which may be included in the arylene group represented by L_{E22} each independently include an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a cycloalkylalkoxy group (for example, having 1 to 15 carbon atoms), a halogen atom, a hydroxyl group, and a phenylthio group. The substituent may further have a substituent if possible, and may be in a form of an alkyl halide group such as a trifluoromethyl group, for example, in which an alkyl group has a halogen atom as a substituent.

(Compound Represented by General Formula (EX3))

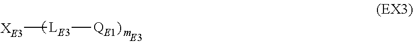

In General Formula (EX3), X_{E3} represents a single bond or an m_{E3}-valent linking group. L_{E3} represents a single bond or a divalent linking group. m_{E3} represents an integer of 2 to 4. Q_{E1} represents an organic group which includes an anionic moiety and a cationic moiety, in which the anionic moiety and the cationic moiety form an ion pair having a non-salt structure. In other words, Q_{E1} represents an organic group formed by linking the cationic moiety and the anionic moiety by a covalent bond. A plurality of L_{E3}'s and Q_{E1}'s may be the same or different from each other. In addition, same as X_{E1} in General Formula (EX1) described above, in a case where X_{E3} represents a single bond, m_{E3} represents 2.

Examples of the m_{E3}-valent linking group represented by X_{E3} and the divalent linking group represented by L_{E3} in General Formula (EX3) include the same linking groups as the m_{E1}-valent linking group represented by X_{E1} and the divalent linking group represented by L_{E1} in General Formula (EX1), and the suitable aspects thereof are also the same.

Examples of the above-described organic group represented by Q_{E1} in General Formula (EX3) include General Formula (EX3-1) and General Formula (EX3-2).

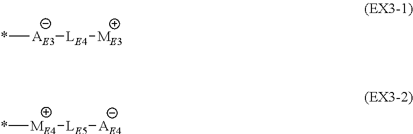

In General Formula (EX3-1), L_{E4} represents a single bond or a divalent linking group. A_{E3}⁻ represents an anionic moiety. M_{E3}⁺ represents a cationic moiety. * represents a bonding position with L_{E3} specified in General Formula (EX3).

In General Formula (EX3-2), L_{E5} represents a single bond or a divalent linking group. A_{E4}⁻ represents an anionic moiety. M_{E4}⁺ represents a cationic moiety. * represents a bonding position with L_{E3} specified in General Formula (EX3).

Examples of L_{E4} and L_{E5} in General Formula (EX3-1) and General Formula (EX3-2) include the same as L_{E1} in General Formula (EX1), and the suitable aspects thereof are also the same.

Examples of M_{E3}⁺ in General Formula (EX3-1) include the same as M_{E2}⁺ in General Formula (EX2), and the suitable aspect thereof is also the same. In a case where L_{E4} specified in General Formula (EX3-1) represents a divalent linking group and ME_{E3}⁺ represents a cationic moiety represented by General Formula (EX2-b1), R³⁰¹ and R³⁰² in the cationic moiety represented by General Formula (EX2-b1) as M_{E3}⁺ may be each independently bonded to the L_{E2} to form a cyclic structure. A suitable aspect of the combination of the divalent linking group represented by L_{E4} and R³⁰¹ and R³⁰² in the cationic moiety represented by General Formula (EX2-b1) as M_{E3}⁺ is also the same as the suitable aspect of the combination of the divalent linking group represented by L_{E2} and R³⁰¹ and R³⁰² in the cationic moiety represented by General Formula (EX2-b1) as M_{E2}⁺ in General Formula (EX2) described above.

Examples of A_{E4}⁻ in General Formula (EX3-2) include the same as A_{E1}⁻ in General Formula (EX1), and the suitable aspect thereof is also the same.

In General Formula (EX3-1), A_{E3}⁻ represents an anionic moiety.

The anionic moiety represented by A_{E3}⁻ is not particularly limited, and examples thereof include anionic functional groups represented by General Formulae (EX3-a1) to (EX3-a19).

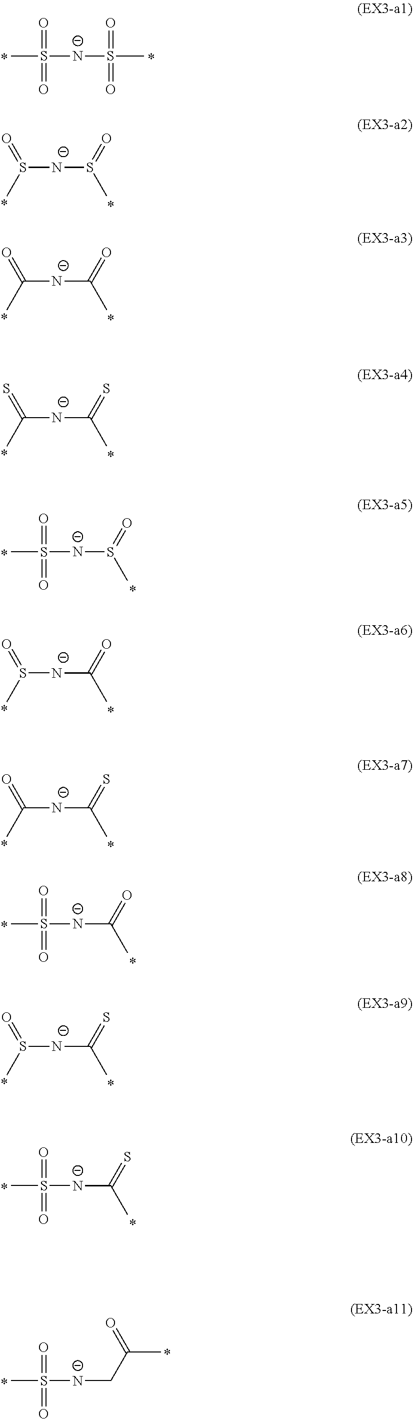

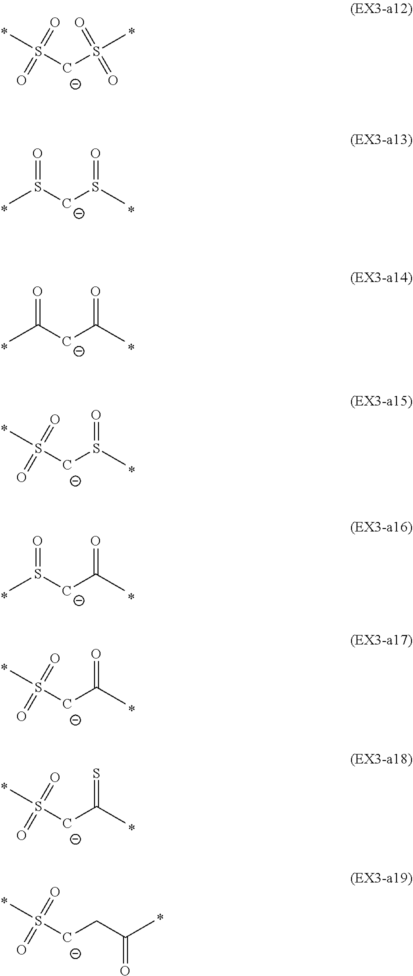

In General Formula (EX3-2), M_{E4}⁺ represents a cationic moiety.

As the cationic moiety represented by M_{E4}⁺, from the viewpoint that a sensitivity, a resolution of the formed pattern, and/or LER is more excellent, a cationic moiety represented by General Formula (EX3-b1) or a cationic moiety represented by General Formula (EX3-b2) is preferable.

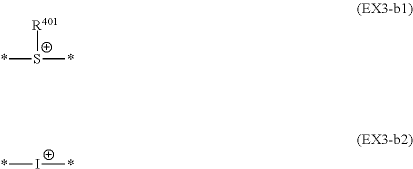

In General Formula (EX2-b1), R⁴⁰¹ represents an organic group.

The number of carbon atoms in the organic group as R⁴⁰¹ is usually 1 to 30, and preferably 1 to 20.

Examples of R⁴⁰¹ include an alkyl group, a cycloalkyl group, and an aryl group, and an aryl group is preferable, a phenyl group or a naphthyl group is more preferable, and a phenyl group is still more preferable. The aryl group represented by R⁴⁰¹ may further have a substituent. Examples of the above-described substituent each independently include an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a cycloalkylalkoxy group (for example, having 1 to 15 carbon atoms), a halogen atom, a hydroxyl group, and a phenylthio group. The substituent may further have a substituent if possible, and may be in a form of an alkyl halide group such as a trifluoromethyl group, for example, in which an alkyl group has a halogen atom as a substituent.

In a case where Q_{E1} specified in General Formula (EX3) represents General Formula (EX3-2), L_{E3} specified in General Formula (EX3) and L_{E5} specified in General Formula (EX3-2) represent divalent linking groups, and M_{E4}⁺ specified in General Formula (EX3-2) represents General Formula (EX3-b1), examples of a suitable aspect of the combination of the divalent linking group represented by L_{E3}, the divalent linking group represented by L_{E5}, and the cationic moiety represented by M_{E4}⁺ in General Formula (EX3-b1) include an aspect in which a linking position in the divalent linking group represented by L_{E3} with the cationic moiety represented by General Formula (EX3-b1) and a linking position in the divalent linking group represented by L_{E5} with the cationic moiety represented by General Formula (EX3-b1) are arylene groups and R³⁰¹ is an aryl group.

As the compound represented by General Formula (EX3), among these, a compound represented by General Formula (EX3-A) is preferable.

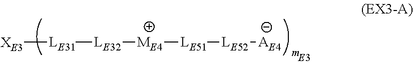

X_{E3}, L_{E31}, and m_{E3} in General Formula (EX3-A) are the same as X_{E3}, L_{E3}, and m_{E3} in General Formula (EX3).

L_{E52} and A_{E4}⁻ are the same as L_{E5} and A_{E4}⁻ in General Formula (EX3-2).

M_{E4}⁺ represents the cationic moiety represented by General Formula (EX3-b1) described above.

L_{E32} and L_{E51} in General Formula (EX3-A) represent arylene groups which may have a substituent.

The arylene group represented by L_{E32} and L_{E51} in General Formula (EX3-A) and the substituent which may be included in the arylene group are the same as the arylene group represented by L_{E22} in General Formula (EX2-A) and the substituent which may be included in the arylene group, and the suitable aspects thereof are also the same.

Hereinafter, specific examples of the specific photodegradable ion compound represented by General Formulae (EX1) to (EX3) are shown below, but the present invention is not limited thereto.

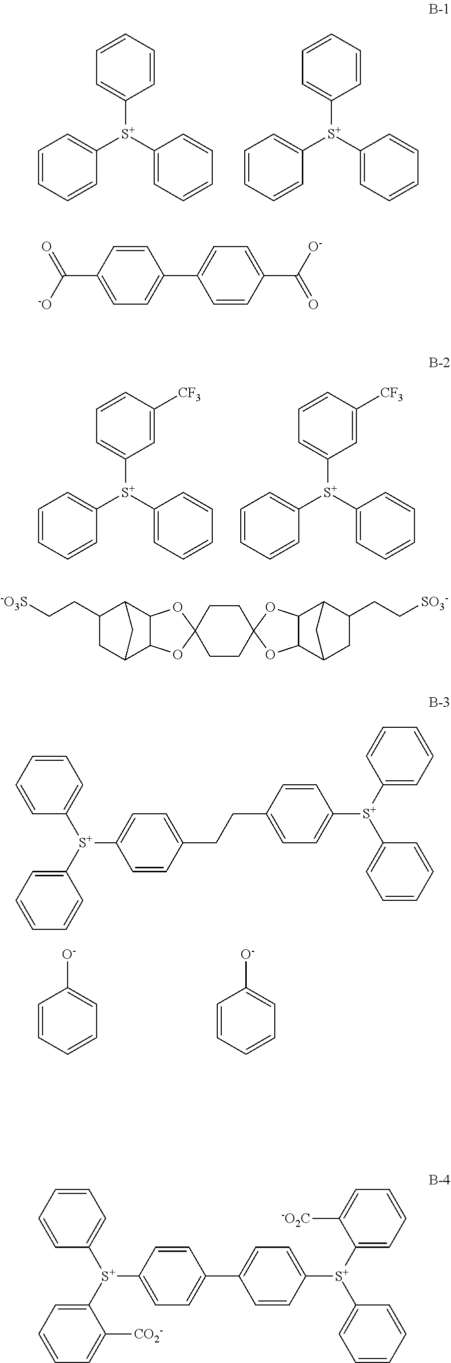

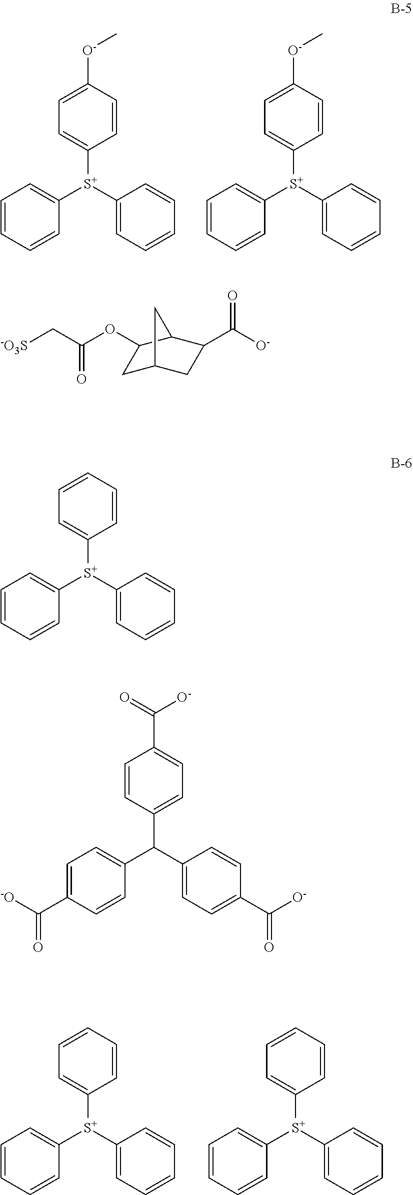

The specific photodegradable ion compound may be a polymer compound as long as the weight-average molecular weight is 5,000 or less.

Examples of the polymer-type specific photodegradable ion compound include a resin which includes a repeating unit including an ion pair decomposed by irradiation with actinic ray or radiation in the side chain. The definition of the ion pair decomposed by irradiation with actinic ray or radiation is as described above.

Among these, as the polymer-type specific photodegradable ion compound, from the viewpoint that the resolution and/or LER performance of the formed pattern is more excellent, a resin which includes a repeating unit X1 which can be included in a resin having a polar group described later and a repeating unit including an ion pair decomposed by irradiation with actinic ray or radiation in the side chain is preferable.

In the polymer-type specific photodegradable ion compound, a content of the repeating unit including an ion pair decomposed by irradiation with actinic ray or radiation in the side chain is preferably 1 to 30 mol % and more preferably 1 to 20 mol % with respect to all repeating units. In addition, a dispersity (molecular weight distribution) thereof is usually 1 to 5, preferably 1 to 3, more preferably 1.2 to 3.0, and still more preferably 1.2 to 2.0.

Among these, as the specific photodegradable ion compound, from the viewpoint that the resolution and/or LER performance of the formed pattern is more excellent, a non-polymer-type specific photodegradable ion compound is preferable, and the above-described compounds represented by General Formulae (EX1) to (EX3) are more preferable.

A content of the specific photodegradable ion compound in the specific resist composition (in a case of including a plurality thereof, the total content thereof) is preferably 0.1% to 40.0% by mass, more preferably 0.1% to 30.0% by mass, still more preferably 2.0% to 30.0% by mass, and particularly preferably 5.0% to 30.0% by mass with respect to the total solid content of the composition.

The solid content is intended to be components excluding the solvent in the composition, and any of components other than the solvent are regarded as a solid content even in a case where they are liquid components.

In addition, the specific photodegradable ion compound may be used alone or in combination of two or more kinds thereof.

<Specific Resin>

The specific resist composition includes a resin having a polar group (specific resin).

(Polar Group)

The polar group is preferably an acid group having a pKa of 13 or less.

As the polar group, for example, a phenolic hydroxyl group, a carboxyl group, a fluorinated alcohol group (preferably, a hexafluoroisopropanol group), a sulfonic acid group, a sulfonamide group, or an isopropanol group is preferable.

In addition, in the above-described hexafluoroisopropanol group, one or more (preferably one or two) fluorine atoms may be substituted with a group (an alkoxycarbonyl group and the like) other than a fluorine atom. —C(CF₃)(OH)—CF₂— formed as above is also preferable as the acid group. In addition, one or more fluorine atoms may be substituted with a group other than a fluorine atom to form a ring including —C(CF₃)(OH)—CF₂—.

(Repeating Unit X1 Having Polar Group)

From the viewpoint that the resolution and/or LER performance of the formed pattern is more excellent, the specific resin preferably includes a repeating unit X1 having a polar group (hereinafter, also referred to as a “repeating unit X1”). The polar group included in the repeating unit X1 is as described above. The repeating unit X1 may have a fluorine atom or an iodine atom.

As the repeating unit X1, a repeating unit represented by Formula (B) is preferable.

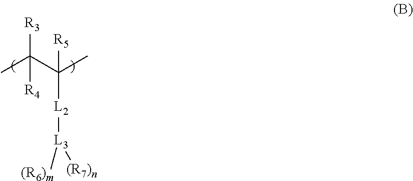

R₃ represents a hydrogen atom or a monovalent organic group which may have a fluorine atom or an iodine atom.

As the monovalent organic group which may have a fluorine atom or an iodine atom, a group represented by -L₄-R₈ is preferable. L₄ represents a single bond or an ester group. R₈ is an alkyl group which may have a fluorine atom or an iodine atom, a cycloalkyl group which may have a fluorine atom or an iodine atom, an aryl group which may have a fluorine atom or an iodine atom, or a group formed by a combination thereof.

R₄ and R₅ each independently represent a hydrogen atom, a fluorine atom, an iodine atom, or an alkyl group which may have a fluorine atom or an iodine atom.

L₂ represents a single bond or an ester group.

L₃ represents an (n+m+1)-valent aromatic hydrocarbon ring group or an (n+m+1)-valent alicyclic hydrocarbon ring group. Examples of the aromatic hydrocarbon ring group include a benzene ring group and a naphthalene ring group. The alicyclic hydrocarbon ring group may be monocyclic or polycyclic, and examples thereof include a cycloalkyl ring group.

R₆ represents a hydroxyl group, a carboxyl group, or a fluorinated alcohol group (preferably, a hexafluoroisopropanol group). In a case where R₆ is a hydroxyl group, L₃ is preferably the (n+m+1)-valent aromatic hydrocarbon ring group.

R₆ is preferably a hydroxyl group or a carboxyl group and more preferably a hydroxyl group, it is still more preferable that R₆ is a hydroxyl group and L3 is the (n+m+1)-valent aromatic hydrocarbon ring group.

R₇ represents a halogen atom. Examples of the halogen atom include a fluorine atom, a chlorine atom, a bromine atom, and an iodine atom.

m represents an integer of 1 or more. m is preferably an integer of 1 to 3 and more preferably an integer of 1 or 2.

n represents 0 or an integer of 1 or more. n is preferably an integer of 1 to 4.

(n+m+1) is preferably an integer of 1 to 5.

As the repeating unit X1, a repeating unit represented by General Formula (I) is also preferable.

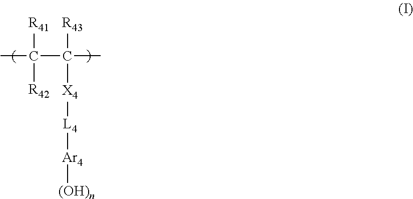

In General Formula (I),

R₄₁, R₄₂, and R₄₃ each independently represent a hydrogen atom, an alkyl group, a cycloalkyl group, a halogen atom, a cyano group, or an alkoxycarbonyl group. However, R₄₂ may be bonded to Ar₄ to form a ring, and in this case, R₄₂ represents a single bond or an alkylene group.

X₄ represents a single bond, —COO—, or —CONR₆₄—, and R₆₄ represents a hydrogen atom or an alkyl group.

L₄ represents a single bond or an alkylene group.

Ar₄ represents an (n+1)-valent aromatic ring group, and in a case where Ar₄ is bonded to R₄₂ to form a ring, Ar₄ represents an (n+2)-valent aromatic ring group.

n represents an integer of 1 to 5.

As the alkyl group represented by each of R₄₁, R₄₂, and R₄₃ in General Formula (I), an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group is preferable, an alkyl group having 8 or less carbon atoms is more preferable, and an alkyl group having 3 or less carbon atoms is still more preferable.

The cycloalkyl group of R₄₁, R₄₂, and R₄₃ in General Formula (I) may be monocyclic or polycyclic. Among these, a monocyclic cycloalkyl group having 3 to 8 carbon atoms, such as a cyclopropyl group, a cyclopentyl group, and a cyclohexyl group, is preferable.

Examples of the halogen atom of R₄₁, R₄₂, and R₄₃ in General Formula (I) include a fluorine atom, a chlorine atom, a bromine atom, and an iodine atom, and a fluorine atom is preferable.

As the alkyl group included in the alkoxycarbonyl group of R₄₁, R₄₂, and R₄₃ in General Formula (I), the same as the alkyl group in R⁴¹, R⁴², and R⁴³ described above is preferable.

Preferred examples of the substituent in each of the groups include an alkyl group, a cycloalkyl group, an aryl group, an amino group, an amide group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. The number of carbon atoms in the substituent is preferably 8 or less.

Ar₄ represents an (n+1)-valent aromatic ring group. The divalent aromatic ring group in a case where n is 1 is preferably, for example, an arylene group having 6 to 18 carbon atoms, such as a phenylene group, a tolylene group, a naphthylene group, and an anthracenylene group, or a divalent aromatic ring group including a heterocycle such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. The above-described aromatic ring group may have a substituent.

Specific examples of the (n+1)-valent aromatic ring group in a case where n is an integer of 2 or more include groups formed by removing any (n−1) hydrogen atoms from the above-described specific examples of the divalent aromatic ring group.

The (n+1)-valent aromatic ring group may further have a substituent. Examples of the substituent which may be included in the above-described alkyl group, cycloalkyl group, alkoxycarbonyl group, alkylene group, and (n+1)-valent aromatic ring group include alkyl groups mentioned as R₄₁, R₄₂, and R₄₃ in General Formula (I); alkoxy groups such as a methoxy group, an ethoxy group, a hydroxyethoxy group, a propoxy group, a hydroxypropoxy group, and a butoxy group; and aryl groups such as a phenyl group.

Examples of the alkyl group of R₆₄ in —CONR₆₄— represented by X₄ (R₆₄ represents a hydrogen atom or an alkyl group) include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, and an alkyl group having 8 or less carbon atoms, is preferable.

X₄ is preferably a single bond, —COO—, or —CONH—, and more preferably a single bond or —COO—.

As the alkylene group in L₄, an alkylene group having 1 to 8 carbon atoms, such as a methylene group, an ethylene group, a propylene group, a butylene group, a hexylene group, and an octylene group, is preferable.

As Ar₄, an aromatic ring group having 6 to 18 carbon atoms is preferable, and a benzene ring group, a naphthalene ring group, and a biphenylene ring group are more preferable.

The repeating unit represented by General Formula (I) preferably includes a hydroxystyrene structure. That is, Ar₄ is preferably a benzene ring group.

The repeating unit represented by General Formula (I) is preferably a repeating unit represented by General Formula (1).

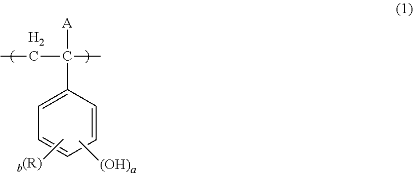

In General Formula (1),

A represents a hydrogen atom, an alkyl group, a cycloalkyl group, a halogen atom, or a cyano group.

R represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group, and in a case of a plurality of R's, the plurality of R's may be the same or different from each other. In a case where a plurality of R's are included, the plurality of R's may be combined with each other to form a ring. R is preferably a hydrogen atom.

a represents an integer of 1 to 3.

b represents an integer of 0 to (5-a).

Hereinafter, the repeating unit X1 will be illustrated. In the formulae, R represents a hydrogen atom or a substituent (as the substituent, an alkyl group which may be substituted with a halogen atom, a halogen atom, or a cyano group is preferable), and a represents 1 or 2.

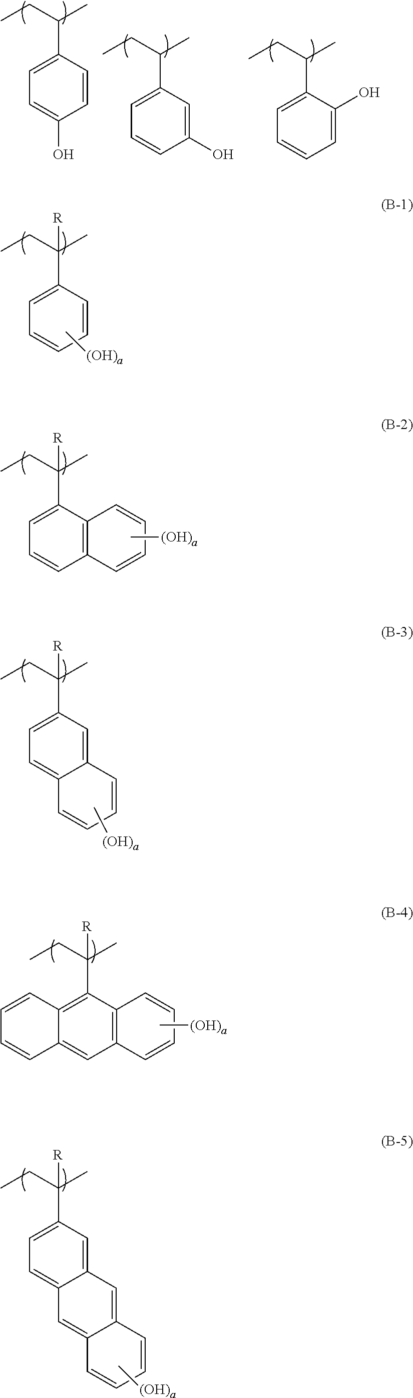

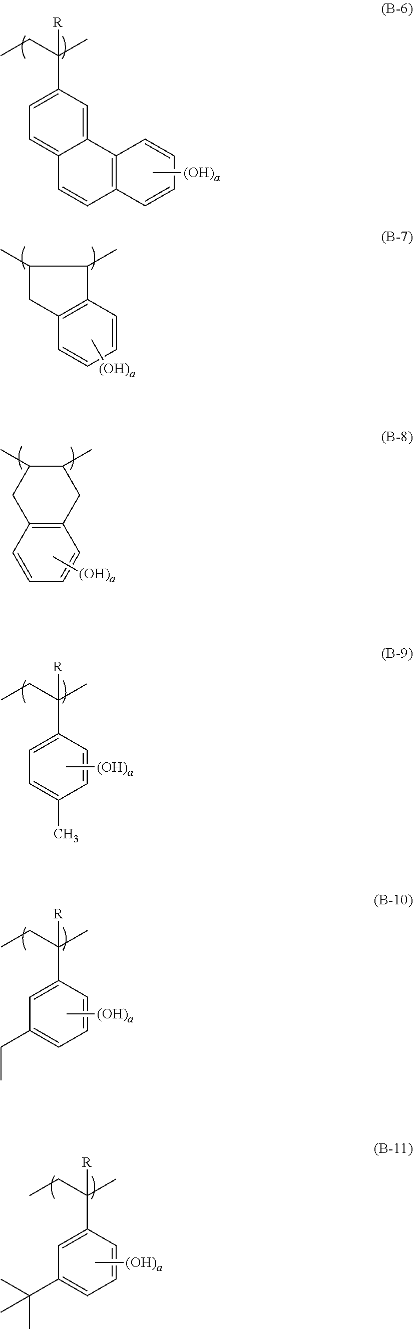

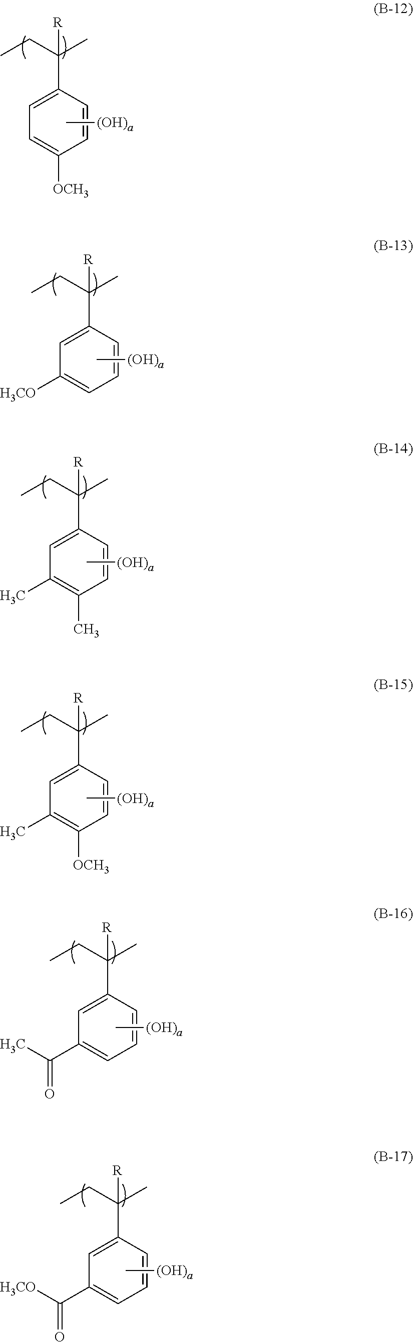

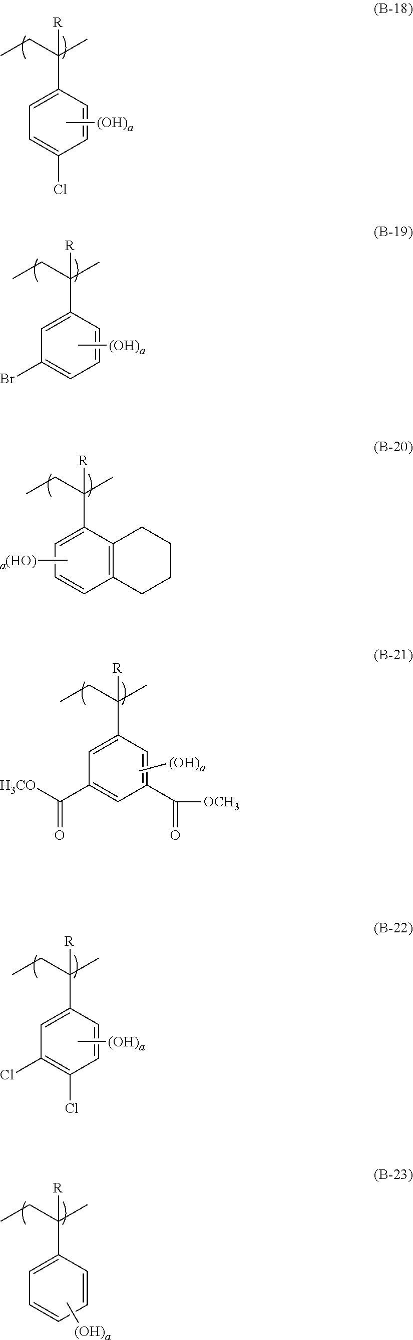

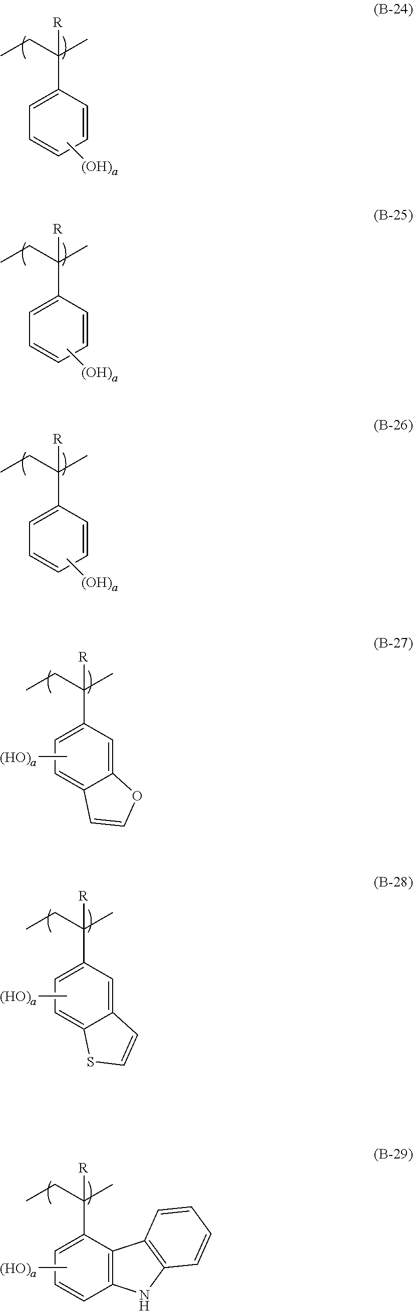

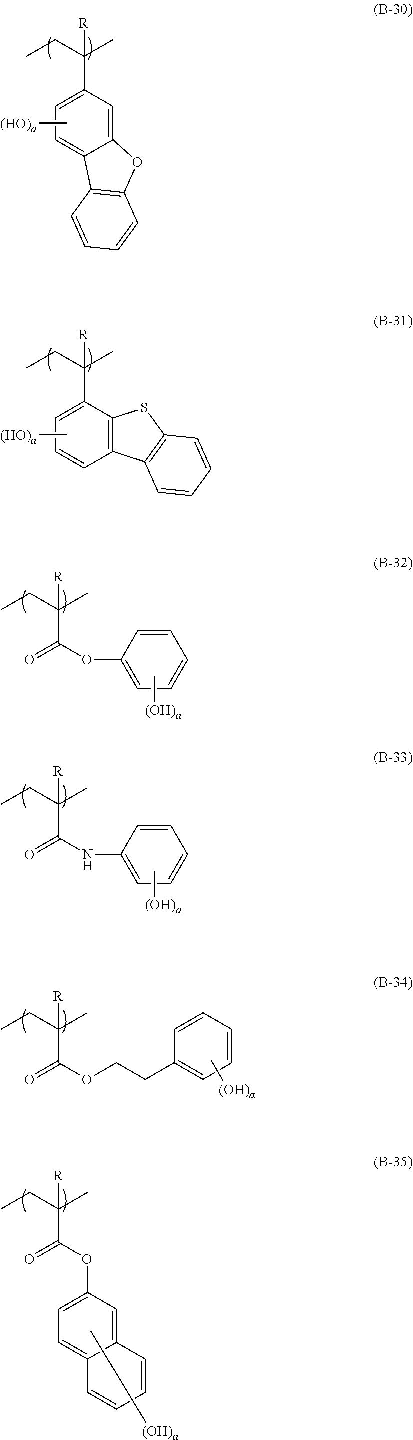

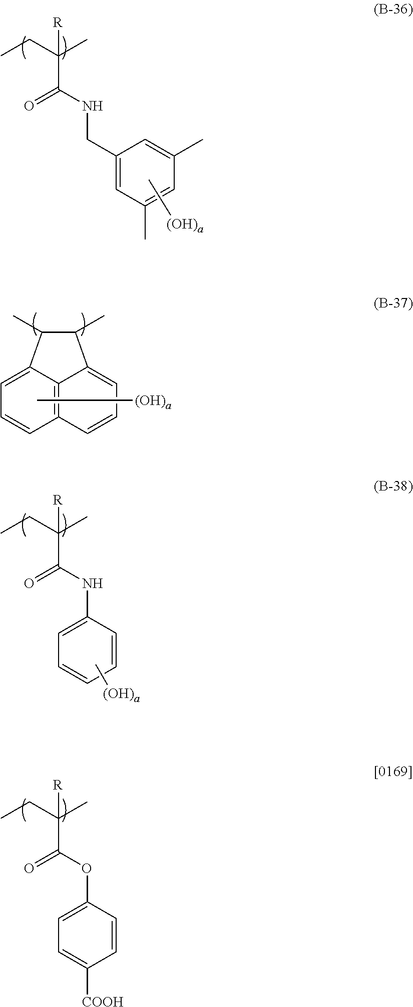

Among the repeating units X1, repeating units specifically shown below are preferable. In the formulae, R represents a hydrogen atom or a methyl group, and a represents 2 or 3.

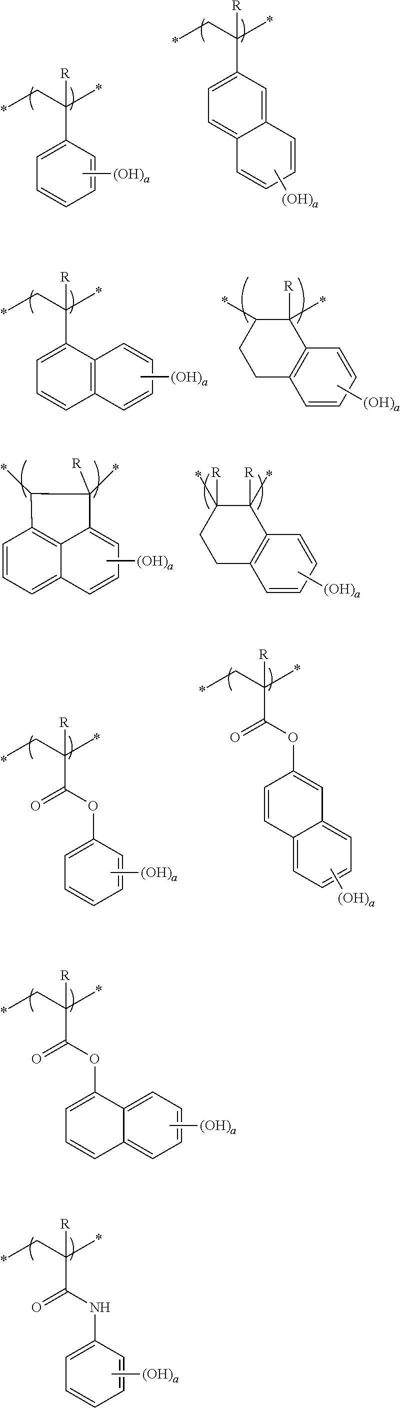

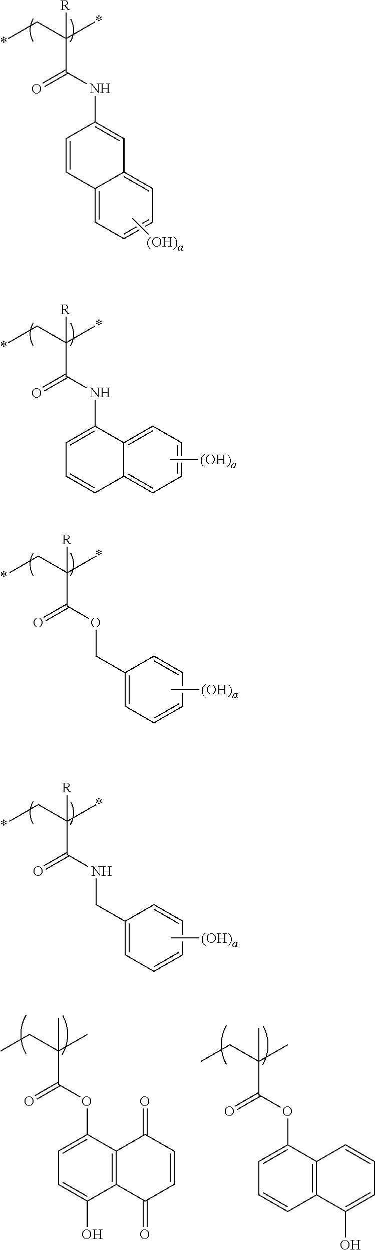

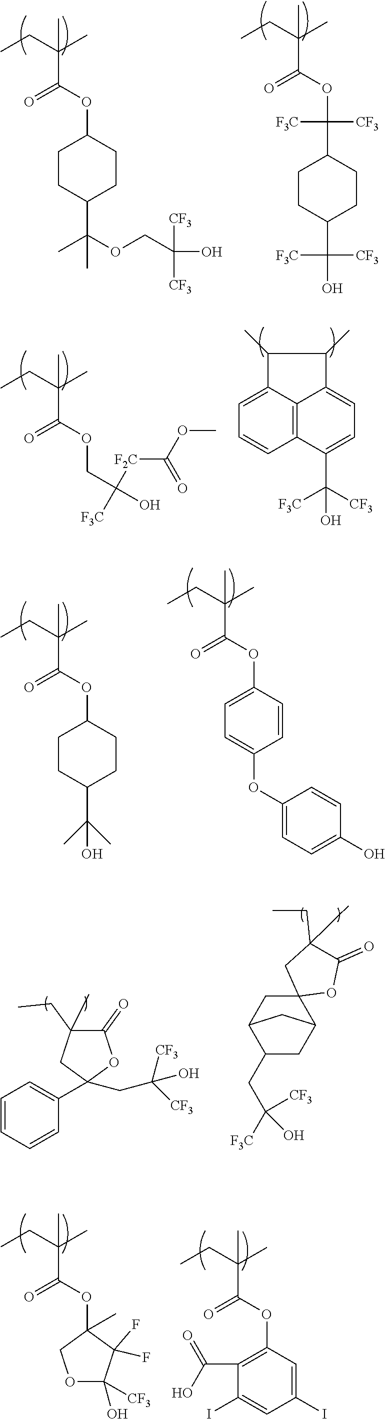

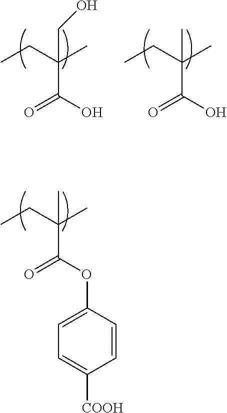

A content of the repeating unit X1 (in a case of including a plurality thereof, the total content thereof) is, for example, 40 to 100 mol %, preferably 50 to 100 mol %, more preferably 60 to 100 mol %, still more preferably 70 to 100 mol %, particularly preferably 80 to 100 mol %, and most preferably 90 to 100 mol % with respect to all repeating units in the specific resin.

(Other Repeating Units)

The specific resin may include other repeating units in addition to the above-described repeating unit X1. Hereinafter, other repeating units will be described.

<<Repeating Unit X2 which Decreases Solubility in Organic Solvent-Based Developer by Action of Acid>>

The specific resin may include a repeating unit X2 which decreases a solubility in the organic solvent-based developer by an action of acid (hereinafter, also referred to as a “repeating unit X2”).

The repeating unit X2 preferably includes a group (hereinafter, also referred to as an “acid-decomposable group”) decomposed by the action of acid to generate a polar group. The acid-decomposable group preferably has a structure in which the polar group is protected by a leaving group which leaves by the action of acid. Due to the above-described configuration, the repeating unit X2 has an increased polarity by the action of acid, an increased solubility in an alkali developer, and a decreased solubility in an organic solvent.

As the above-described polar group, an alkali-soluble group is preferable, and examples thereof include an acidic group, such as a carboxyl group, a phenolic hydroxyl group, a fluorinated alcohol group, a sulfonic acid group, a phosphoric acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group; and an alcoholic hydroxyl group.

Among these, as the polar group, a carboxyl group, a phenolic hydroxyl group, a fluorinated alcohol group (preferably, a hexafluoroisopropanol group), or a sulfonic acid group is preferable.

Examples of the leaving group which leaves by the action of acid include groups represented by Formulae (Y1) to (Y4).

—C(Rx₁)(Rx₂)(Rx₃) Formula (Y1):

—C(═O)OC(Rx₁)(Rx₂)(Rx₃) Formula (Y2):

—C(R₃₆)(R₃₇)(OR₃₈) Formula (Y3):

—C(Rn)(H)(Ar) Formula (Y4):

In Formula (Y1) and Formula (Y2), Rx₁ to Rx₃ each independently represent a (linear or branched) alkyl group, a (monocyclic or polycyclic) cycloalkyl group, an (linear or branched) alkenyl group, or a (monocyclic or polycyclic) aryl group. In a case where all of Rx₁ to Rx₃ are (linear or branched) alkyl groups, it is preferable that at least two of Rx₁, Rx₂, or Rx₃ are methyl groups.

Among these, it is preferable that Rx₁ to Rx₃ each independently represent a linear or branched alkyl group, and it is more preferable that Rx₁ to Rx₃ each independently represent a linear alkyl group.

Two of Rx₁ to Rx₃ may be bonded to each other to form a monocycle or a polycycle.

As the alkyl group of Rx₁ to Rx₃, an alkyl group having 1 to 5 carbon atoms, such as a methyl group, an ethyl group, an n-propyl group, an isopropyl group, an n-butyl group, an isobutyl group, and a t-butyl group is preferable.

As the cycloalkyl group of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the aryl group of Rx₁ to Rx₃, an aryl group having 6 to 10 carbon atoms is preferable, and examples thereof include a phenyl group, a naphthyl group, and an anthryl group.

As the alkenyl group of Rx₁ to Rx₃, a vinyl group is preferable.

A cycloalkyl group is preferable as the ring formed by the bonding of two of Rx₁ to Rx₃. As a cycloalkyl group formed by the bonding of two of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable, and a monocyclic cycloalkyl group having 5 or 6 carbon atoms is more preferable.

In the cycloalkyl group formed by the bonding of two of Rx₁ to Rx₃, for example, one of methylene groups constituting the ring may be substituted with a heteroatom such as an oxygen atom, with a group having a heteroatom, such as a carbonyl group, or with a vinylidene group. In addition, in the cycloalkyl group, one or more of the ethylene groups constituting the cycloalkane ring may be substituted with a vinylene group.

With regard to the group represented by Formula (Y1) or Formula (Y2), for example, an aspect in which Rx₁ is a methyl group or an ethyl group and Rx₂ and Rx₃ are bonded to each other to form the above-described cycloalkyl group is preferable.

In Formula (Y3), R₃₆ to R₃₃ each independently represent a hydrogen atom or a monovalent organic group. R₃₇ and R₃₈ may be bonded to each other to form a ring. Examples of the monovalent organic group include an alkyl group, a cycloalkyl group, an aryl group, an aralkyl group, and an alkenyl group. It is also preferable that R₃₆ is a hydrogen atom.

The alkyl group, the cycloalkyl group, the aryl group, and the aralkyl group may include a heteroatom such as an oxygen atom, and/or a group having a heteroatom, such as a carbonyl group. For example, in the above-described alkyl group, cycloalkyl group, aryl group, and aralkyl group, one or more of methylene groups may be substituted with a heteroatom such as an oxygen atom and/or with a group having a heteroatom, such as a carbonyl group.

In addition, R₃₈ and another substituent included in the main chain of the repeating unit may be bonded to each other to form a ring. A group formed by the mutual bonding of R₃₈ and another substituent on the main chain of the repeating unit is preferably an alkylene group such as a methylene group.

As Formula (Y3), a group represented by Formula (Y3-1) is preferable.

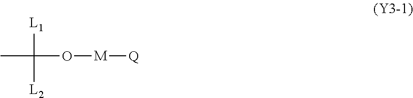

Here, L₁ and L₂ each independently represent a hydrogen atom, an alkyl group, a cycloalkyl group, an aryl group, or a group formed by a combination thereof (for example, a group formed by a combination of an alkyl group and an aryl group).

M represents a single bond or a divalent linking group.

Q represents an alkyl group which may include a heteroatom, a cycloalkyl group which may include a heteroatom, an aryl group which may include a heteroatom, an amino group, an ammonium group, a mercapto group, a cyano group, an aldehyde group, or a group formed by a combination thereof (for example, a group formed by a combination of an alkyl group and a cycloalkyl group).

In the alkyl group and the cycloalkyl group, for example, one of methylene groups may be substituted with a heteroatom such as an oxygen atom or with a group having a heteroatom, such as a carbonyl group.

It is preferable that one of L₁ or L₂ is a hydrogen atom, and the other is an alkyl group, a cycloalkyl group, an aryl group, or a group formed by a combination of an alkylene group and an aryl group.

At least two of Q, M, or L₁ may be bonded to each other to form a ring (preferably a 5- or 6-membered ring).

From the viewpoint of pattern miniaturization, L₂ is preferably a secondary or tertiary alkyl group, and more preferably a tertiary alkyl group. Examples of the secondary alkyl group include an isopropyl group, a cyclohexyl group, and a norbornyl group, and examples of the tertiary alkyl group include a tert-butyl group and an adamantane group. In these aspects, since a glass transition temperature (Tg) and an activation energy are increased, it is possible to suppress fogging in addition to ensuring a film hardness.

In Formula (Y4), Ar represents an aromatic ring group. Rn represents an alkyl group, a cycloalkyl group, or an aryl group. Rn and Ar may be bonded to each other to form a non-aromatic ring. Ar is more preferably an aryl group.

From the viewpoint that the acid decomposability of the repeating unit is excellent, in a case where a non-aromatic ring is directly bonded to a polar group (or a residue thereof) in a leaving group which protects the polar group, it is also preferable that a ring member atom adjacent to the ring member atom directly bonded to the polar group (or a residue thereof) in the non-aromatic ring has no halogen atom such as a fluorine atom as a substituent.

In addition, the leaving group which leaves by the action of acid may be a 2-cyclopentenyl group having a substituent (an alkyl group and the like), such as a 3-methyl-2-cyclopentenyl group, and a cyclohexyl group having a substituent (an alkyl group and the like), such as a 1,1,4,4-tetramethylcyclohexyl group.

As the repeating unit having an acid-decomposable group, a repeating unit represented by Formula (A) is also preferable.

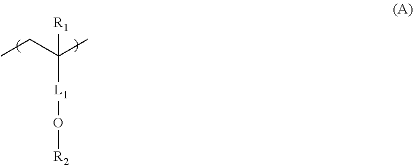

L₁ represents a divalent linking group which may have a fluorine atom or an iodine atom, R₁ represents a hydrogen atom, a fluorine atom, an iodine atom, a fluorine atom, an alkyl group which may have an iodine atom, or an aryl group which may have a fluorine atom or an iodine atom, and R₂ represents a leaving group which leaves by the action of acid and may have a fluorine atom or an iodine atom. However, at least one of L₁, R₁, or R₂ has a fluorine atom or an iodine atom.

L₁ represents a divalent linking group which may have a fluorine atom or an iodine atom. Examples of the divalent linking group which may have a fluorine atom or an iodine atom include —CO—, —O—, —S—, —SO—, —SO₂—, a hydrocarbon group which may have a fluorine atom or an iodine atom (for example, an alkylene group, a cycloalkylene group, an alkenylene group, and an arylene group), and a linking group formed by the linking of a plurality of these groups. Among these, as L₁, —CO— or -arylene group-alkylene group having a fluorine atom or an iodine atom is preferable.

As the arylene group, a phenylene group is preferable.

The alkylene group may be linear or branched. The number of carbon atoms in the alkylene group is not particularly limited, but is preferably 1 to 10 and more preferably 1 to 3.

The total number of fluorine atoms and iodine atoms included in the alkylene group having a fluorine atom or an iodine atom is not particularly limited, but is preferably 2 or more, more preferably 2 to 10, and still more preferably 3 to 6.

R₁ represents a hydrogen atom, a fluorine atom, an iodine atom, an alkyl group which may have a fluorine atom or an iodine atom, or an aryl group which may have a fluorine atom or an iodine atom.

The alkyl group may be linear or branched. The number of carbon atoms in the alkyl group is not particularly limited, but is preferably 1 to 10 and more preferably 1 to 3.

The total number of fluorine atoms and iodine atoms included in the alkyl group having a fluorine atom or an iodine atom is not particularly limited, but is preferably 1 or more, more preferably 1 to 5, and still more preferably 1 to 3.

The above-described alkyl group may include a heteroatom such as an oxygen atom other than a halogen atom.

R₂ represents a leaving group which leaves by the action of acid and may have a fluorine atom or an iodine atom.

Among these, examples of the leaving group include groups represented by Formulae (Z1) to (Z4).

—C(Rx₁₁)(Rx₁₂)(Rx₁₃) Formula (Z1):

—C(═O)OC(Rx₁₁)(Rx₁₂)(Rx₁₃) Formula (Z2):

—C(R₁₃₆)(R₁₃₇)(OR₁₃₈) Formula (Z3):

—C(Rn₁)(H)(Ar₁) Formula (Z4):

In Formulae (Z1) and (Z2), Rx₁₁ to Rx₁₃ each independently represent an (linear or branched) alkyl group which may have a fluorine atom or an iodine atom, a (monocyclic or polycyclic) cycloalkyl group which may have a fluorine atom or an iodine atom, an (linear or branched) alkenyl group which may have a fluorine atom or an iodine atom, or an (monocyclic or polycyclic) aryl group which may have a fluorine atom or an iodine atom. In a case where all of Rx₁₁ to Rx₁₃ are (linear or branched) alkyl groups, it is preferable that at least two of Rx₁₁, Rx₁₂, or Rx₁₃ are methyl groups.

Rx₁₁ to Rx₁₃ are the same as Rx₁ to Rx₃ in (Y1) and (Y2) described above, respectively, except that they may have a fluorine atom or an iodine atom, and have the same definitions and suitable ranges as those of the alkyl group, the cycloalkyl group, the alkenyl group, and the aryl group.

In Formula (Z3), R₁₃₆ to R₁₃₈ each independently represent a hydrogen atom, or a monovalent organic group which may have a fluorine atom or an iodine atom. R₁₃₇ and R₁₃₈ may be bonded to each other to form a ring. Examples of the monovalent organic group which may have a fluorine atom or an iodine atom include an alkyl group which may have a fluorine atom or an iodine atom, a cycloalkyl group which may have a fluorine atom or an iodine atom, an aryl group which may have a fluorine atom or an iodine atom, an aralkyl group which may have a fluorine atom or an iodine atom, and a group formed by a combination thereof (for example, a group formed by a combination of an alkyl group and a cycloalkyl group).

In addition, a heteroatom such as an oxygen atom, in addition to the fluorine atom and the iodine atom, may be included in the alkyl group, the cycloalkyl group, the aryl group, and the aralkyl group. That is, in the above-described alkyl group, cycloalkyl group, aryl group, and aralkyl group, one methylene group may be substituted with a heteroatom such as an oxygen atom, or with a group having a heteroatom, such as a carbonyl group.

In addition, R₁₃₈ and another substituent included in the main chain of the repeating unit may be bonded to each other to form a ring. In this case, a group formed by the mutual bonding of R₁₃₈ and another substituent on the main chain of the repeating unit is preferably an alkylene group such as a methylene group.

As Formula (Z3), a group represented by Formula (Z3-1) is preferable.

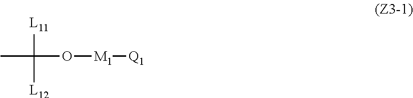

Here, L₁₁ and L₁₂ each independently represent a hydrogen atom; an alkyl group which may have a heteroatom selected from the group consisting of a fluorine atom, an iodine atom, and an oxygen atom; a cycloalkyl group which may have a heteroatom selected from the group consisting of a fluorine atom, an iodine atom, and an oxygen atom; an aryl group which may have a heteroatom selected from the group consisting of a fluorine atom, an iodine atom, and an oxygen atom; or a group formed by a combination thereof (for example, a group formed by a combination of an alkyl group and a cycloalkyl group, each of which may have a heteroatom selected from the group consisting of a fluorine atom, an iodine atom, and an oxygen atom).

M₁ represents a single bond or a divalent linking group.

Q₁ represents an alkyl group which may have a heteroatom selected from the group consisting of a fluorine atom, an iodine atom, and an oxygen atom; a cycloalkyl group which may have a heteroatom selected from the group consisting of a fluorine atom, an iodine atom, and an oxygen atom; an aryl group which may have a heteroatom selected from the group consisting of a fluorine atom, an iodine atom, and an oxygen atom; an amino group; an ammonium group; a mercapto group; a cyano group; an aldehyde group; a group formed by a combination thereof (for example, a group formed by a combination of the alkyl group and the cycloalkyl group, each of which may have a heteroatom selected from the group consisting of a fluorine atom, an iodine atom, and an oxygen atom).

In Formula (Z4), Ar₁ represents an aromatic ring group which may have a fluorine atom or an iodine atom. Rn₁ represents an alkyl group which may have a fluorine atom or an iodine atom, a cycloalkyl group which may have a fluorine atom or an iodine atom, or an aryl group which may have a fluorine atom or an iodine atom. Rn₁ and Ar₁ may be bonded to each other to form a non-aromatic ring.

As the repeating unit X2, a repeating unit represented by General Formula (A1) is also preferable.

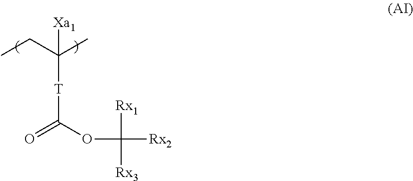

In General Formula (AI),

Xa₁ represents a hydrogen atom, or an alkyl group which may have a substituent.

T represents a single bond or a divalent linking group.

Rx₁ to Rx₃ each independently represent a (linear or branched) alkyl group, a (monocyclic or polycyclic) cycloalkyl group, a (linear or branched) alkenyl group, or a (monocyclic or polycyclic) aryl group. However, in a case where all of Rx₁ to Rx₃ are (linear or branched) alkyl groups, it is preferable that at least two of Rx₁, Rx₂, or Rx₃ are methyl groups.

Two of Rx₁ to Rx₃ may be bonded to each other to form a monocyclic ring or a polycyclic ring (a monocyclic or polycyclic cycloalkyl group and the like).

Examples of the alkyl group which may have a substituent, represented by Xa₁, include a methyl group and a group represented by —CH₂—R₁₁. R₁₁ represents a halogen atom (a fluorine atom or the like), a hydroxyl group, or a monovalent organic group, examples thereof include an alkyl group having 5 or less carbon atoms, which may be substituted with a halogen atom, an acyl group having 5 or less carbon atoms, which may be substituted with a halogen atom, and an alkoxy group having 5 or less carbon atoms, which may be substituted with a halogen atom; and an alkyl group having 3 or less carbon atoms is preferable, and a methyl group is more preferable. Xa₁ is preferably a hydrogen atom, a methyl group, a trifluoromethyl group, or a hydroxymethyl group.

Examples of the divalent linking group of T include an alkylene group, an aromatic ring group, a —COO-Rt- group, and an —O-Rt- group. In the formulae, Rt represents an alkylene group or a cycloalkylene group.

T is preferably a single bond or a —COO-Rt- group. In a case where T represents a —COO-Rt- group, Rt is preferably an alkylene group having 1 to 5 carbon atoms, and more preferably a —CH₂— group, a —(CH₂)₂— group, or a —(CH₂)₃— group.

As the alkyl group of Rx₁ to Rx₃, an alkyl group having 1 to 4 carbon atoms, such as a methyl group, an ethyl group, an n-propyl group, an isopropyl group, an n-butyl group, an isobutyl group, and a t-butyl group is preferable.

As the cycloalkyl group of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the aryl group of Rx₁ to Rx₃, an aryl group having 6 to 10 carbon atoms is preferable, and examples thereof include a phenyl group, a naphthyl group, and an anthryl group.

As the alkenyl group of Rx₁ to Rx₃, a vinyl group is preferable.

As the cycloalkyl group formed by the bonding of two of Rx₁ to Rx₃, a monocyclic cycloalkyl group such as a cyclopentyl group and a cyclohexyl group is preferable, and in addition, a polycyclic cycloalkyl group such as a norbornyl group, a tetracyclodecanyl group, a tetracyclododecanyl group, and an adamantyl group is also preferable. Among these, a monocyclic cycloalkyl group having 5 or 6 carbon atoms is preferable.

In the cycloalkyl group formed by the bonding of two of Rx₁ to Rx₃, for example, one of methylene groups constituting the ring may be substituted with a heteroatom such as an oxygen atom, with a group having a heteroatom, such as a carbonyl group, or with a vinylidene group. In addition, in the cycloalkyl group, one or more of the ethylene groups constituting the cycloalkane ring may be substituted with a vinylene group.

With regard to the repeating unit represented by General Formula (AI), for example, an aspect in which Rx₁ is a methyl group or an ethyl group and Rx₂ and Rx₃ are bonded to each other to form the above-described cycloalkyl group is preferable.

In a case where each of the above-described groups has a substituent, examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms). The substituent preferably has 8 or less carbon atoms.

The repeating unit represented by General Formula (AI) is preferably an acid-decomposable tertiary alkyl (meth)acrylate ester-based repeating unit (a repeating unit in which Xa₁ represents a hydrogen atom or a methyl group and T represents a single bond).

From the viewpoint that the resolution and/or LER performance of the formed pattern is more excellent, it is preferable that the specific resin does not include the repeating unit X2. In a case where the specific resin includes the repeating unit X2, from the viewpoint that the resolution and/or LER performance of the formed pattern is more excellent, a content of the repeating unit X2 is preferably 20 mol % or less and more preferably 10 mol % or less with respect to all repeating units of the resin. The lower limit value thereof is more than 0 mol %.

Specific examples of the repeating unit X2 are shown below, but the present invention is not limited thereto. Further, in the formulae, Xa₁ represents H, F, CH₃, CF₃, or CH₂OH, and Rxa and Rxb each represent a linear or branched alkyl group having 1 to 5 carbon atoms.

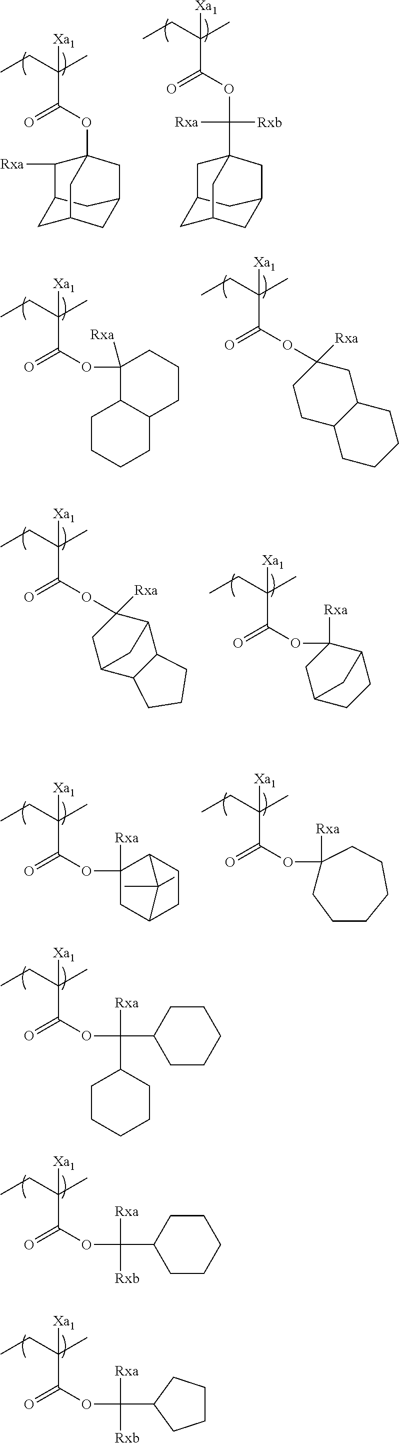

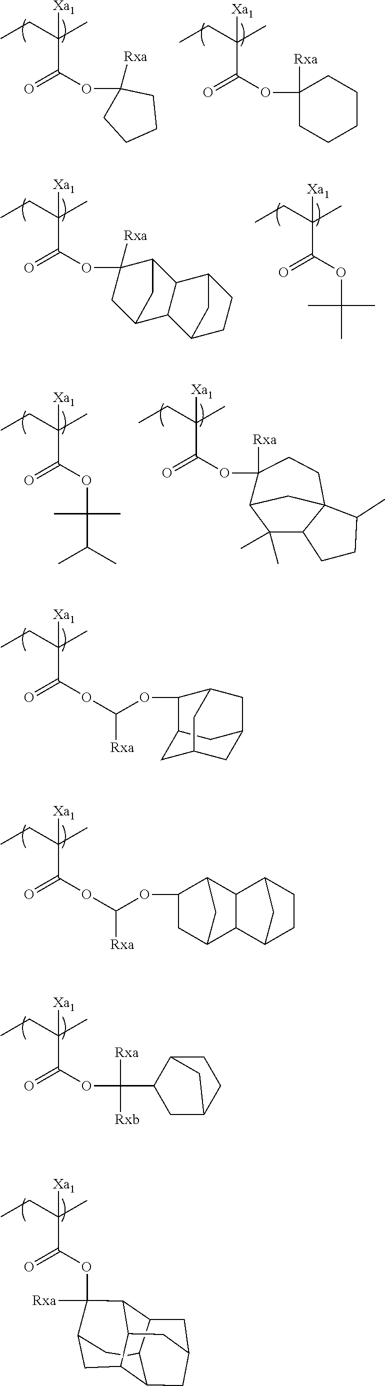

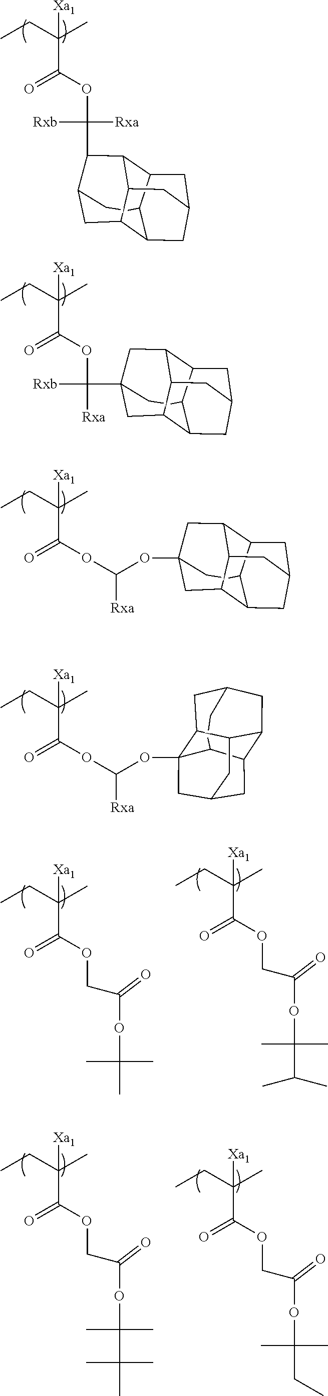

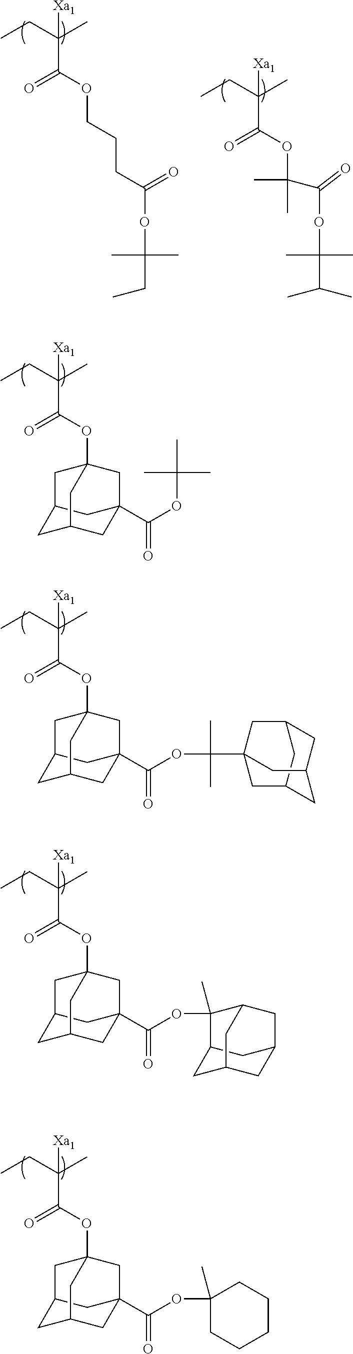

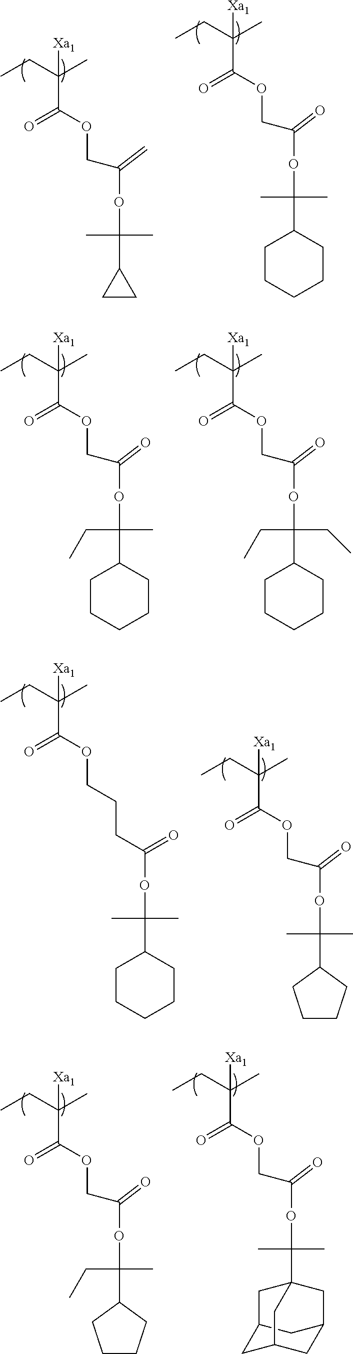

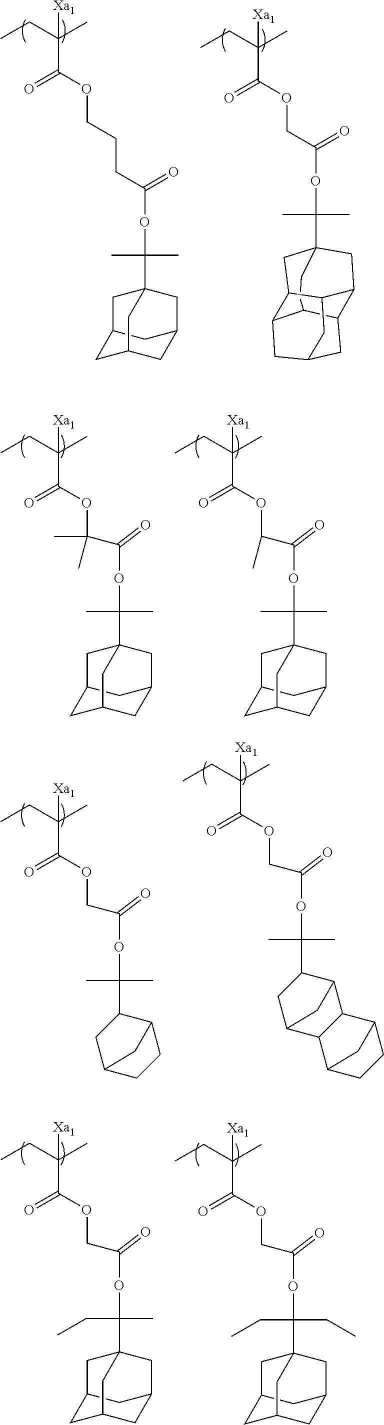

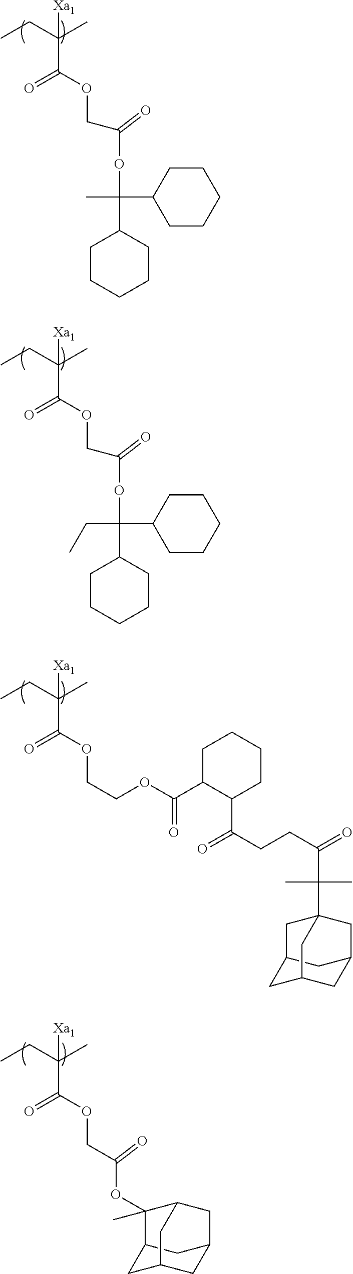

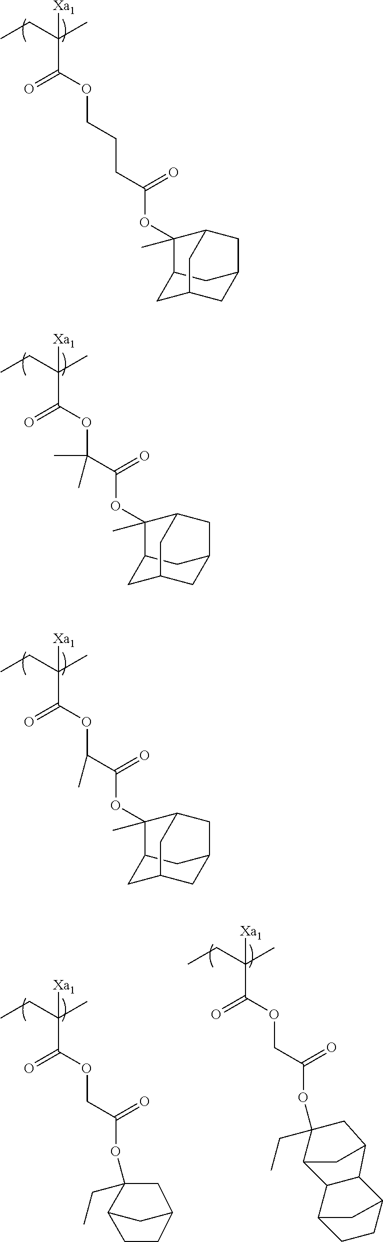

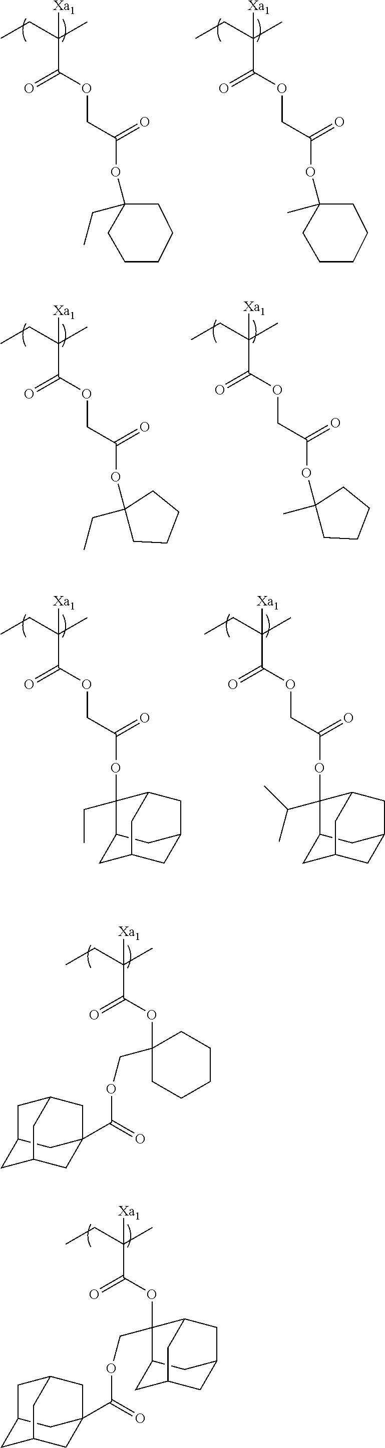

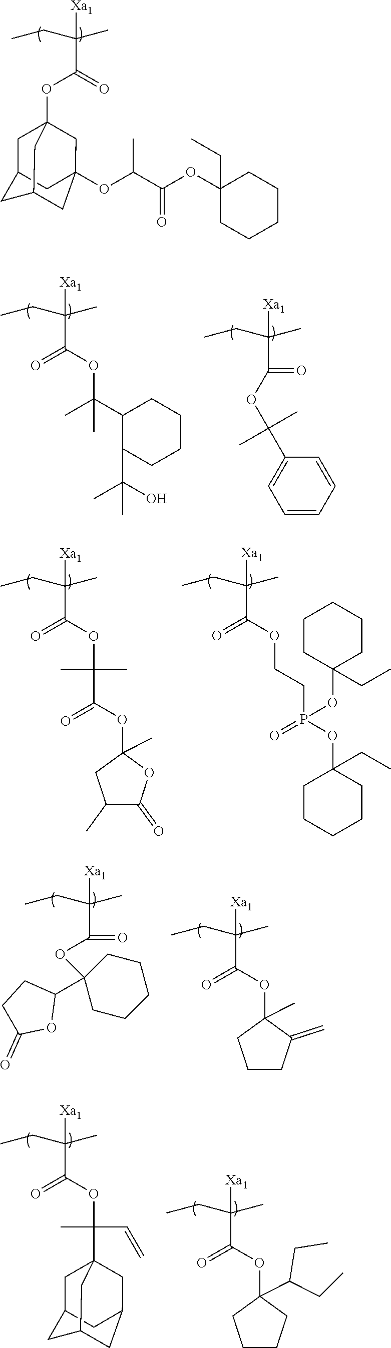

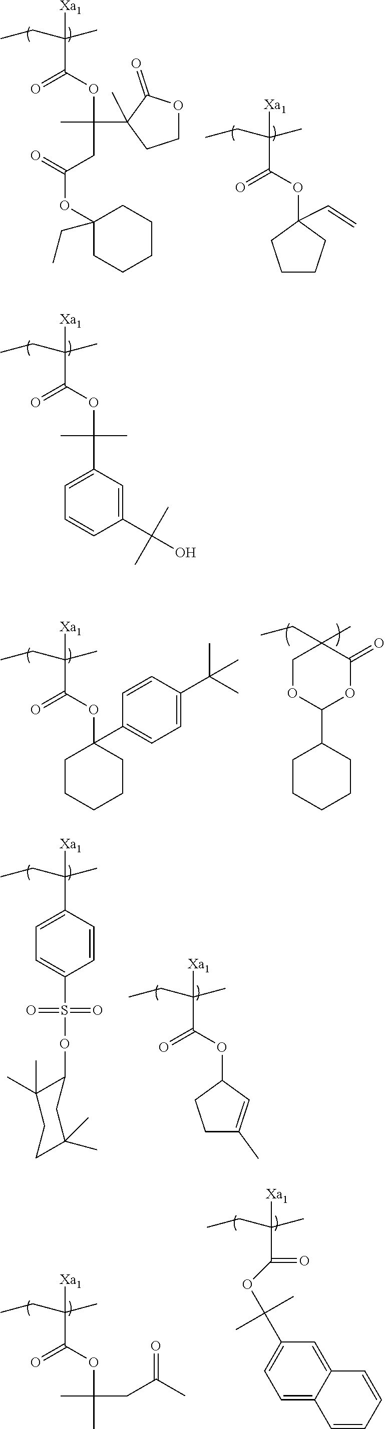

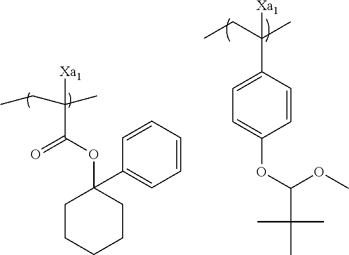

<<Repeating Unit Having Lactone Group, Sultone Group, or Carbonate Group>>

The specific resin may have a repeating unit having at least one selected from the group consisting of a lactone group, a sultone group, and a carbonate group (hereinafter also collectively referred to as a “repeating unit having a lactone group, a sultone group, or a carbonate group”).

It is also preferable that the repeating unit having a lactone group, a sultone group, or a carbonate group has no acid group such as a hexafluoropropanol group.

The lactone group or the sultone group may have a lactone structure or a sultone structure. The lactone structure or the sultone structure is preferably a 5- to 7-membered ring lactone structure or a 5- to 7-membered ring sultone structure. Among these, the structure is more preferably a 5- to 7-membered ring lactone structure with which another ring structure is fused so as to form a bicyclo structure or a spiro structure or a 5- to 7-membered ring sultone structure with which another ring structure is fused so as to form a bicyclo structure or a spiro structure.

The specific resin preferably has a repeating unit having a lactone group or a sultone group, formed by extracting one or more hydrogen atoms from a ring member atom of a lactone structure represented by any of General Formulae (LC1-1) to (LC1-21) or a sultone structure represented by any of General Formulae (SL1-1) to (SL1-3).

In addition, the lactone group or the sultone group may be bonded directly to the main chain. For example, a ring member atom of the lactone group or the sultone group may constitute the main chain of the specific resin.

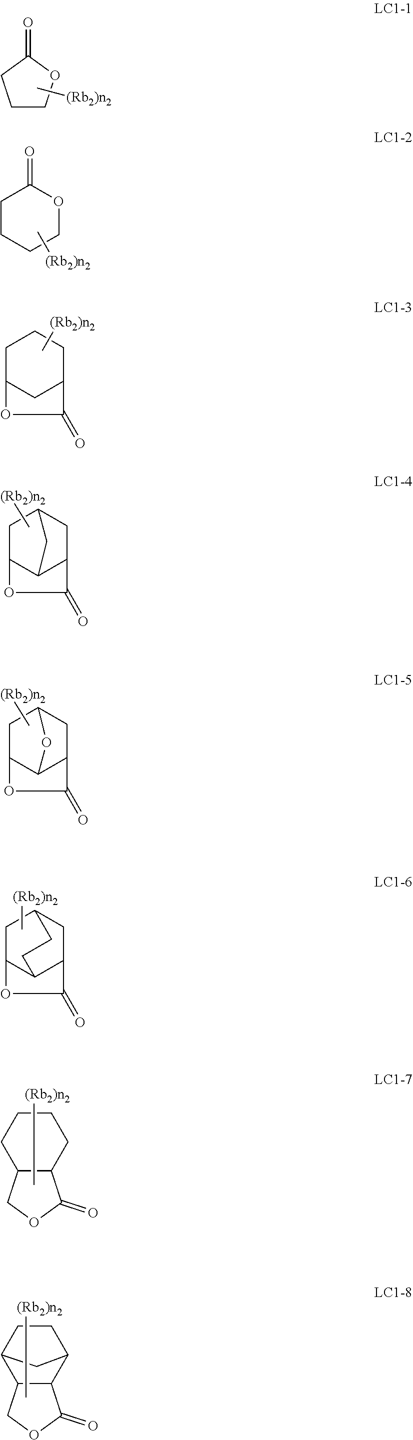

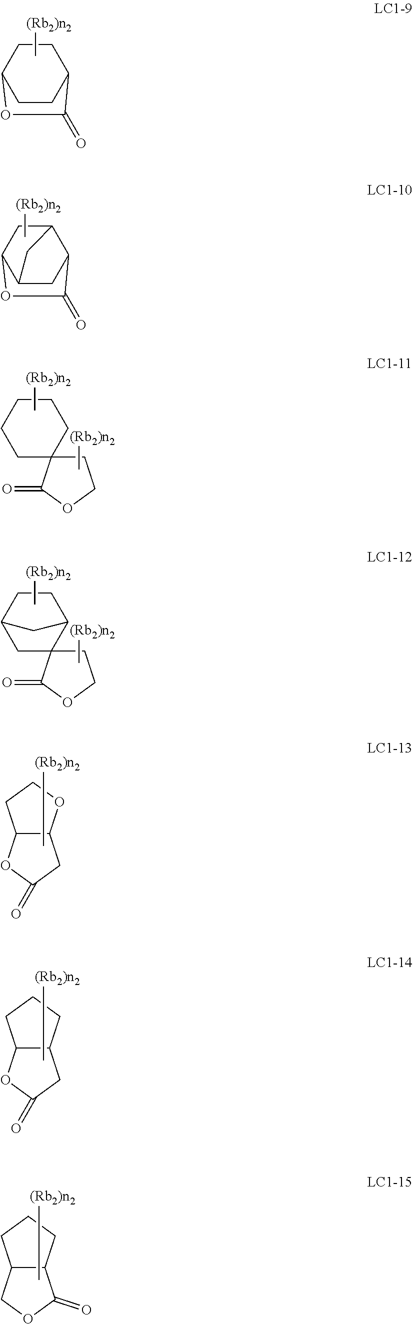

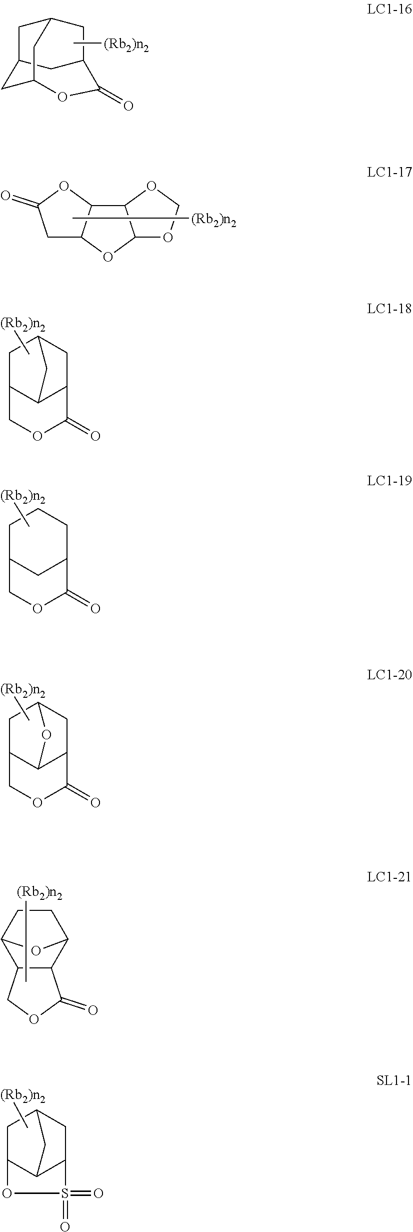

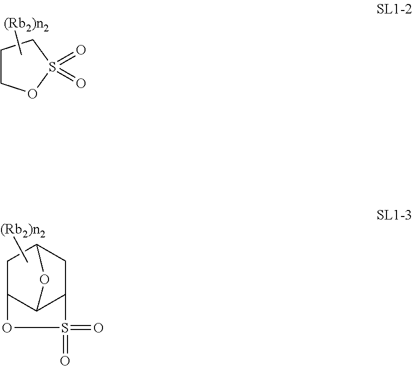

The above-described portion of lactone structure or sultone structure may have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, and an acid-decomposable group. n2 represents an integer of 0 to 4. In a case where n2 is 2 or more, Rb₂'s which are present in a plural number may be different from each other, and Rb₂'s which are present in a plural number may be bonded to each other to form a ring.

Examples of the repeating unit having a group having the lactone structure represented by any of General Formulae (LC1-1) to (LC1-21) or the sultone structure represented by any of General Formulae (SL1-1) to (SL1-3) include a repeating unit represented by General Formula (AI).

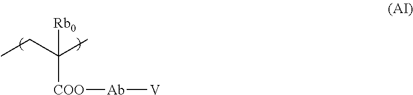

In General Formula (AI), Rb₀ represents a hydrogen atom, a halogen atom, or an alkyl group having 1 to 4 carbon atoms.

Preferred examples of the substituent which may be contained in the alkyl group of Rb₀ include a hydroxyl group and a halogen atom.

Examples of the halogen atom of Rb₀ include a fluorine atom, a chlorine atom, a bromine atom, and an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent group formed by a combination thereof. Among these, a single bond or a linking group represented by -Ab₁—CO₂— is preferable. Ab₁ is a linear or branched alkylene group, or a monocyclic or polycyclic cycloalkylene group, and is preferably a methylene group, an ethylene group, a cyclohexylene group, an adamantylene group, or a norbornylene group.

V represents a group formed by extracting one hydrogen atom from a ring member atom of the lactone structure represented by any of General Formulae (LC1-1) to (LC1-21) or a group formed by extracting one hydrogen atom from a ring member atom of the sultone structure represented by any of General Formulae (SL1-1) to (SL1-3).

In a case where an optical isomer is present in the repeating unit having a lactone group or a sultone group, any of optical isomers may be used. In addition, one optical isomer may be used alone or a mixture of a plurality of the optical isomers may be used. In a case where one kind of optical isomers is mainly used, an optical purity (ee) thereof is preferably 90 or more, and more preferably 95 or more.

As the carbonate group, a cyclic carbonic acid ester group is preferable.

As the repeating unit having a cyclic carbonic acid ester group, a repeating unit represented by General Formula (A-1) is preferable.

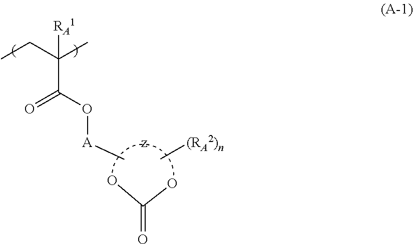

In General Formula (A-1), R_{A}¹ represents a hydrogen atom, a halogen atom, or a monovalent organic group (preferably a methyl group).

n represents an integer of 0 or more.

R_{A}² represents a substituent. In a case where n is 2 or more, R_{A}² which are present in a plural number may be the same or different from each other.

A represents a single bond or a divalent linking group. As the above-described divalent linking group, an alkylene group, a divalent linking group having a monocyclic or polycyclic alicyclic hydrocarbon structure, an ether group, an ester group, a carbonyl group, a carboxyl group, or a divalent group formed by a combination thereof is preferable.

Z represents an atomic group which forms a monocycle or polycycle with a group represented by —O—CO—O— in the formula.

The repeating unit having a lactone group, a sultone group, or a carbonate group will be exemplified below.

(in the formulae, Rx is H, CH₂, CH₂OH, or CF₃)

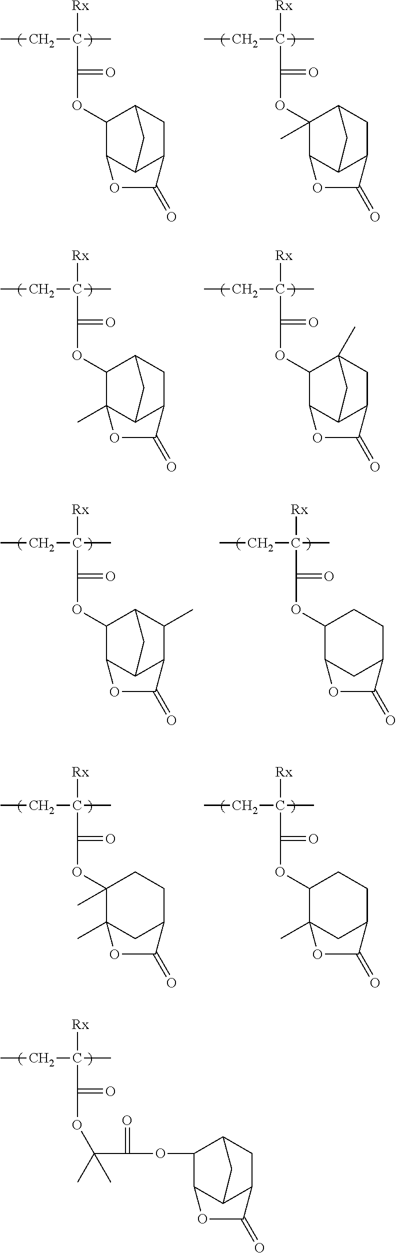

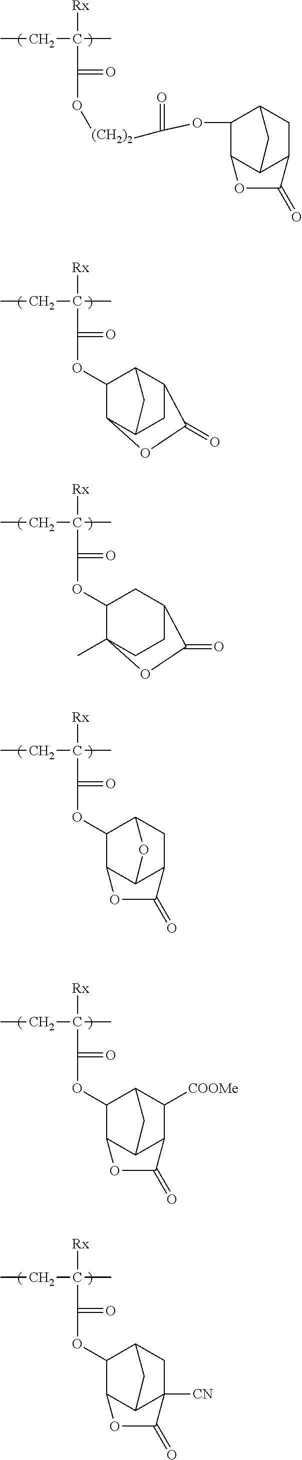

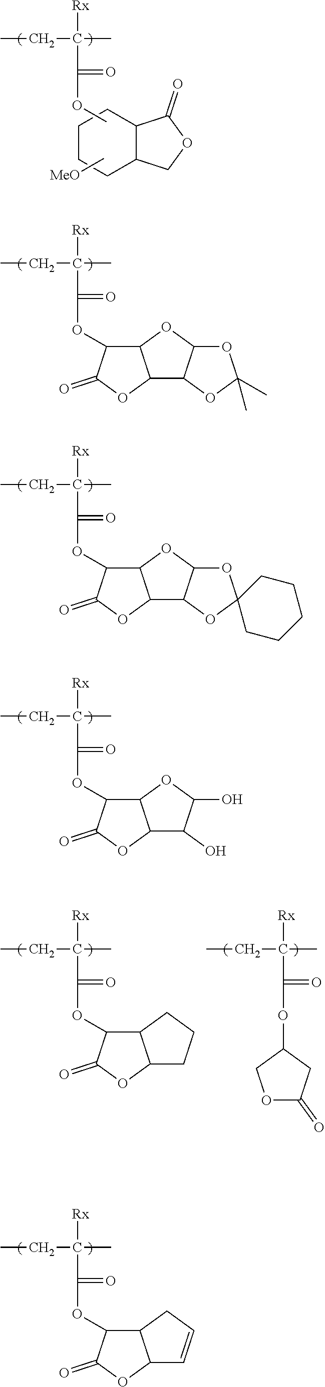

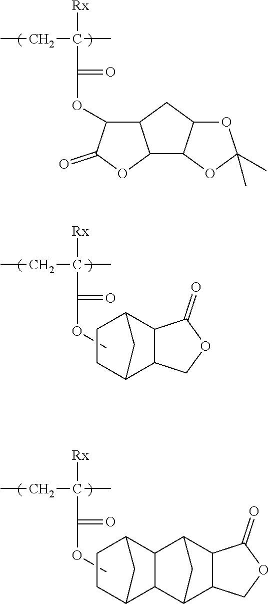

(in the formulae, Rx is H, CH₃, CH₂OH, or CF₃)

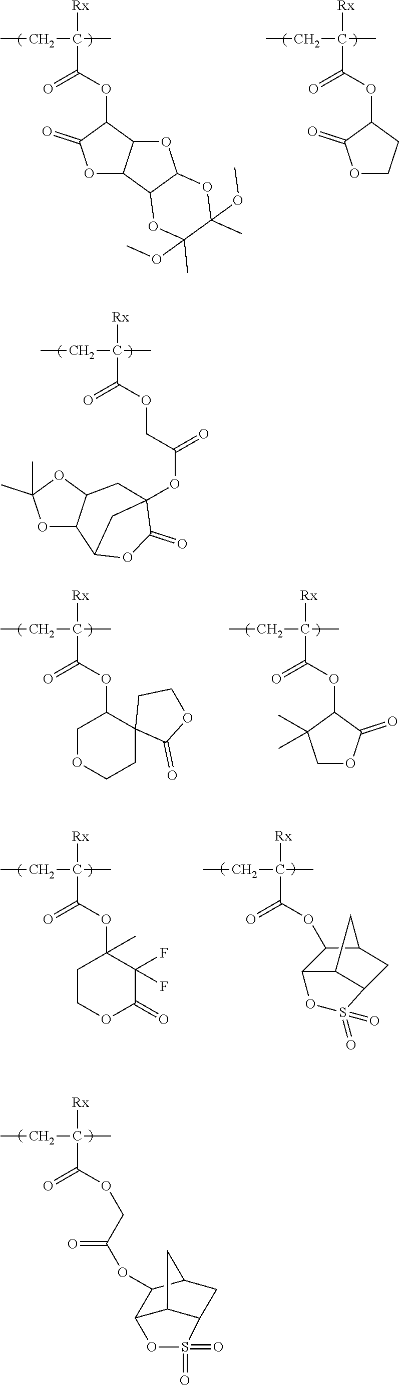

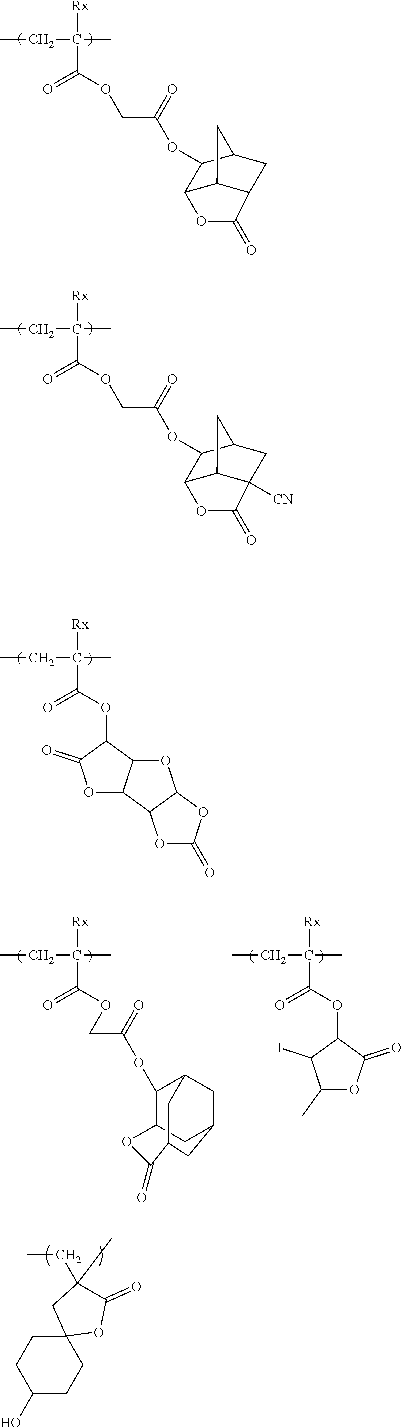

(in the formulae, Rx is H, CH₃, CH₂OH, or CF₃)

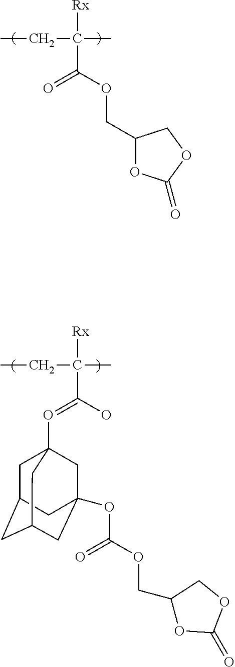

In a case where the specific resin includes a repeating unit having a lactone group, a sultone group, or a carbonate group, a content of the repeating unit having a lactone group, a sultone group, or a carbonate group is preferably 1 to 60 mol %, more preferably 1 to 40 mol %, and still more preferably 5 to 30 mol % with respect to all repeating units in the specific resin.

<<Repeating Unit Represented by General Formula (III)>>

The specific resin preferably has a repeating unit represented by General Formula (III).

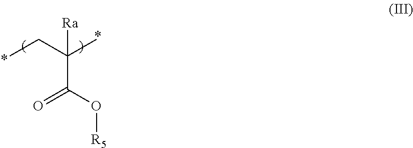

In General Formula (III), R₅ represents a hydrocarbon group having at least one cyclic structure and having neither a hydroxyl group nor a cyano group.

Ra represents a hydrogen atom, an alkyl group, or a —CH₂—O—Ra₂ group. In the formula, Ra₂ represents a hydrogen atom, an alkyl group, or an acyl group.

The cyclic structure included in R₅ includes a monocyclic hydrocarbon group and a polycyclic hydrocarbon group. Examples of the monocyclic hydrocarbon group include a cycloalkyl group having 3 to 12 carbon atoms (more preferably having 3 to 7 carbon atoms) and a cycloalkenyl group having 3 to 12 carbon atoms.

Examples of the polycyclic hydrocarbon group include a ring assembly hydrocarbon group and a crosslinked cyclic hydrocarbon group. Examples of the crosslinked cyclic hydrocarbon ring include a bicyclic hydrocarbon ring, a tricyclic hydrocarbon ring, and a tetracyclic hydrocarbon ring. In addition, as the crosslinked cyclic hydrocarbon ring, a fused ring in which a plurality of 5- to 8-membered cycloalkane rings are fused is also included.

As the crosslinked cyclic hydrocarbon group, a norbornyl group, an adamantyl group, a bicyclooctanyl group, or a tricyclo[5,2,1,0^{2,6}]decanyl group is preferable, and a norbornyl group or an adamantyl group is more preferable.

The alicyclic hydrocarbon group may have a substituent, and examples of the substituent include a halogen atom, an alkyl group, a hydroxyl group protected by a protective group, and an amino group protected by a protective group.

The halogen atom is preferably a bromine atom, a chlorine atom, or a fluorine atom.

As the alkyl group, a methyl group, an ethyl group, an n-butyl group, or a t-butyl group is preferable. The alkyl group may further have a substituent, and examples of the substituent include a halogen atom, an alkyl group, a hydroxyl group protected by a protective group, and an amino group protected by a protective group.

Examples of the protective group include an alkyl group, a cycloalkyl group, an aralkyl group, a substituted methyl group, a substituted ethyl group, an alkoxycarbonyl group, and an aralkyloxycarbonyl group.

As the alkyl group, an alkyl group having 1 to 4 carbon atoms is preferable.

As the substituted methyl group, a methoxymethyl group, a methoxythiomethyl group, a benzyloxymethyl group, a t-butoxymethyl group, or a 2-methoxyethoxymethyl group is preferable.

The substituted ethyl group is preferably a 1-ethoxyethyl group or a 1-methyl-1-methoxyethyl group.

As the acyl group, an aliphatic acyl group having 1 to 6 carbon atoms, such as a formyl group, an acetyl group, a propionyl group, a butyryl group, an isobutyryl group, a valeryl group, and a pivaloyl group, is preferable.

As the alkoxycarbonyl group, an alkoxycarbonyl group having 1 to 4 carbon atoms is preferable.

In a case where the specific resin includes a repeating unit represented by General Formula (III), a content of the repeating unit represented by General Formula (III) is preferably 1 to 40 mol % and more preferably 1 to 20 mol % with respect to all repeating units in the specific resin.

Specific examples of the repeating unit represented by General Formula (III) are shown below, but the present invention is not limited thereto. In the formulae, Ra represents H, CH₃, CH₂OH, or CF₃.

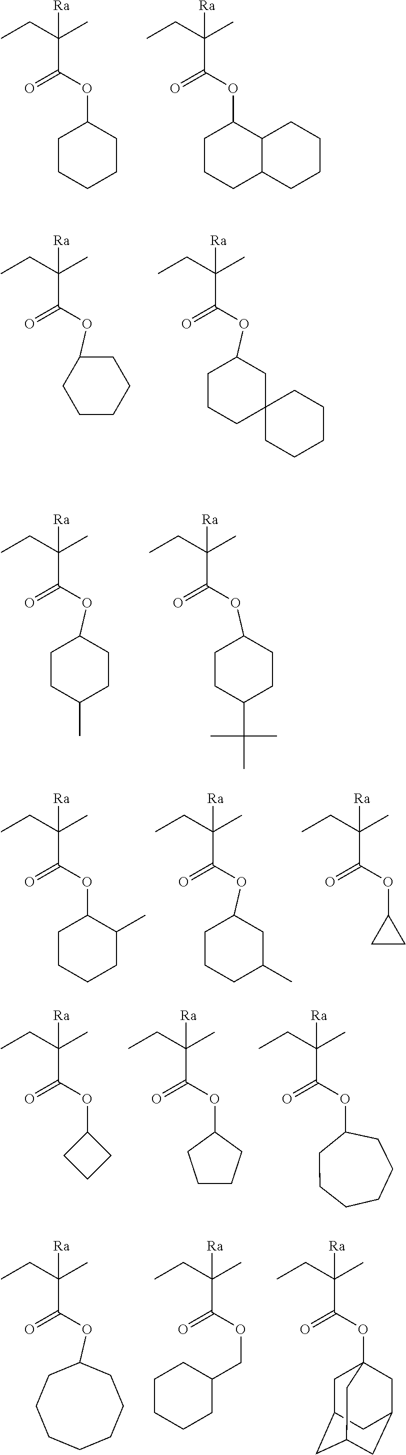

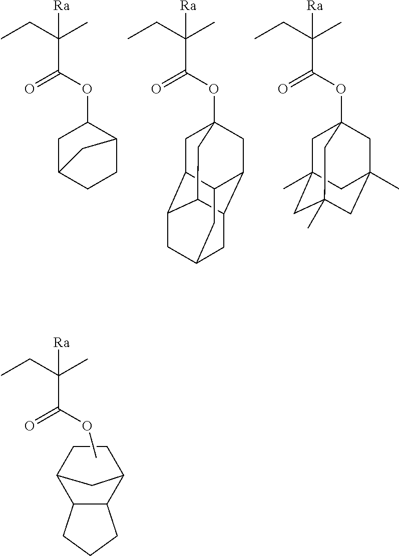

<<Other Repeating Units>>

Further, the specific resin may have a repeating unit other than the above-described repeating units. Examples of the other repeating units include various repeating units for the purpose of adjusting dry etching resistance, suitability for a standard developer, adhesiveness to a substrate, a resist profile, resolving power, heat resistance, sensitivity, and the like. From the viewpoint that the resolution and/or LER performance of the formed pattern is more excellent, it is preferable that the specific resin does not substantially have a structure which includes a repeating unit including an ion pair. The term “substantially” as used herein means that, with respect to all repeating units of the specific resin, a content of the repeating unit including an ion pair is 5 mol % or less, preferably 3 mol % or less, more preferably 1 mol % or less, and still more preferably 0 mol %.

As the other repeating units, repeating units described in paragraphs [0088] to [0093] of WO2017/002737A are also preferable.

Specific examples of the specific resin also include resins described in paragraphs

to [0101] of WO2017/002737A, but the present invention is not limited thereto.

The specific resin can be synthesized in accordance with an ordinary method (for example, a radical polymerization).

A weight-average molecular weight of the specific resin as a value expressed in terms of polystyrene by a GPC method is preferably 1,000 to 200,000, more preferably 3,000 to 20,000, and still more preferably 5,000 to 15,000. By setting the weight-average molecular weight of the specific resin to 1,000 to 200,000, deterioration of heat resistance and dry etching resistance can be further suppressed. In addition, deterioration of developability and deterioration of film-forming properties due to high viscosity can also be further suppressed.

A dispersity (molecular weight distribution) of the specific resin is usually 1.0 to 5.0, preferably 1.0 to 3.0, more preferably 1.2 to 3.0, and still more preferably 1.2 to 2.0. As the dispersity is smaller, resolution and resist shape are more excellent, and a side wall of a resist pattern is smoother and roughness is also more excellent.

In the specific resist composition, a content of the specific resin (in a case of including a plurality thereof, the total amount thereof) is preferably 50.0% to 99.9% by mass, more preferably 60.0% to 99.0% by mass, still more preferably 60.0% to 95.0% by mass, and particularly preferably 70.0% to 95.0% by mass with respect to the total solid content of the composition.

In addition, the specific resin may be used alone or in combination of two or more kinds thereof.

<Solvent>

The specific resist composition includes a solvent.

The solvent preferably includes at least one solvent of (M1) propylene glycol monoalkyl ether carboxylate or (M2) at least one selected from the group consisting of propylene glycol monoalkyl ether, lactic acid ester, acetic acid ester, alkoxypropionic acid ester, chain ketone, cyclic ketone, lactone, and alkylene carbonate. The solvent may further include a component other than the components (M1) and (M2).

The present inventors have found that, by using such a solvent and the above-described resin in combination, a pattern having a small number of development defects can be formed while improving coating property of the composition. A reason for this is not always clear, but the present inventors have considered that, since these solvents have a good balance of solubility, boiling point, and viscosity of the above-described resin, unevenness of a film thickness of a composition film, generation of precipitates during spin coating, and the like can be suppressed.

As the component (M1), at least one selected from the group consisting of propylene glycol monomethyl ether acetate (PGMEA), propylene glycol monomethyl ether propionate, and propylene glycol monoethyl ether acetate is preferable, and propylene glycol monomethyl ether acetate (PGMEA) is more preferable.

The component (M2) is preferably the following solvent.

The propylene glycol monoalkyl ether is preferably propylene glycol monomethyl ether (PGME) or propylene glycol monoethyl ether (PGEE).

The lactic acid ester is preferably ethyl lactate, butyl lactate, or propyl lactate.

The acetic acid ester is preferably methyl acetate, ethyl acetate, butyl acetate, isobutyl acetate, propyl acetate, isoamyl acetate, methyl formate, ethyl formate, butyl formate, propyl formate, or 3-methoxybutyl acetate.

In addition, butyl butyrate is also preferable.

The alkoxypropionic acid ester is preferably methyl 3-methoxypropionate (MMP) or ethyl 3-ethoxypropionate (EEP).

The chain ketone is preferably 1-octanone, 2-octanone, 1-nonanone, 2-nonanone, acetone, 2-heptanone, 4-heptanone, 1-hexanone, 2-hexanone, diisobutyl ketone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, or methyl amyl ketone.

The cyclic ketone is preferably methylcyclohexanone, isophorone, cyclopentanone, or cyclohexanone.

The lactone is preferably γ-butyrolactone.

The alkylene carbonate is preferably propylene carbonate.

The component (M2) is more preferably propylene glycol monomethyl ether (PGME), ethyl lactate, ethyl 3-ethoxypropionate, methyl amyl ketone, cyclohexanone, butyl acetate, pentyl acetate, γ-butyrolactone, or propylene carbonate.

In addition to the above-described components, it is preferable to use an ester-based solvent having 7 or more carbon atoms (preferably 7 to 14 carbon atoms, more preferably 7 to 12 carbon atoms, and still more preferably 7 to 10 carbon atoms) and 2 or less heteroatoms.

Examples of the ester-based solvent having 7 or more carbon atoms and 2 or less heteroatoms include amyl acetate, 2-methylbutyl acetate, 1-methylbutyl acetate, hexyl acetate, pentyl propionate, hexyl propionate, butyl propionate, isobutyl isobutyrate, heptyl propionate, and butyl butanoate, and isoamyl acetate is preferable.

The component (M2) is preferably a solvent having a flash point (hereinafter, also referred to as fp) of 37° C. or higher. Such a component (M2) is preferably propylene glycol monomethyl ether (fp: 47° C.), ethyl lactate (fp: 53° C.), ethyl 3-ethoxypropionate (fp: 49° C.), methyl amyl ketone (fp: 42° C.), cyclohexanone (fp: 44° C.), pentyl acetate (fp: 45° C.), methyl 2-hydroxyisobutyrate (fp: 45° C.), γ-butyrolactone (fp: 101° C.), or propylene carbonate (fp: 132° C.). Among these, propylene glycol monoethyl ether, ethyl lactate, pentyl acetate, or cyclohexanone is more preferable, and propylene glycol monoethyl ether or ethyl lactate is still more preferable.

The “flash point” herein means a value described in a reagent catalog of Tokyo Chemical Industry Co., Ltd. or Sigma-Aldrich Co. LLC.

It is preferable that the solvent includes the component (M1). The solvent is more preferably composed of substantially only the component (M1) or is a mixed solvent of the component (M1) and other components. In the latter case, it is still more preferable that the solvent includes both the component (M1) and the component (M2).

A mass ratio (M1/M2) of the component (M1) to the component (M2) is preferably “100/0” to “0/10”, more preferably “100/0” to “15/85”, still more preferably “100/0” to “40/60”, and particularly preferably “100/0” to “60/40”.

That is, in a case where the solvent includes both the component (M1) and the component (M2), the mass ratio of the component (M1) to the component (M2) is preferably 15/85 or more, more preferably 40/60 or more, and still more preferably 60/40 or more. In a case where such a configuration is adopted, the number of development defects is reduced.

In a case where both of the component (M1) and the component (M2) are included in the solvent, the mass ratio of the component (M1) to the component (M2) is set to, for example, 99/1 or less.

As described above, the solvent may further include a component other than the components (M1) and (M2). In this case, a content of the component other than the components (M1) and (M2) is preferably 5% to 30% by mass with respect to the total amount of the solvent.

A content of the solvent in the specific resist composition is preferably set such that the concentration of solid contents is 0.5% to 20.0% by mass, more preferably set such that the concentration of solid contents is 0.5% to 10.0% by mass, and still more preferably set such that the concentration of solid contents is 0.5% to 5.0% by mass. With this content, the coating property of the specific resist composition can be further improved.

The solid content means all components excluding the solvent.

<Other Additives>

The specific resist composition may include other additives in addition to the specific resin, the specific photodegradable ion compound, and the solvent.

(Acid Diffusion Control Agent)

The specific resist composition may further include an acid diffusion control agent. The acid diffusion control agent acts as a quencher that traps an acidic decomposition product which can be produced by the decomposition of the specific photodegradable ion compound by exposure and that functions to control the diffusion phenomenon of the acidic decomposition product in the resist film.

The acid diffusion control agent may be, for example, a basic compound.

The basic compound is preferably a compound having a structure represented by General Formula (A) to General Formula (E).

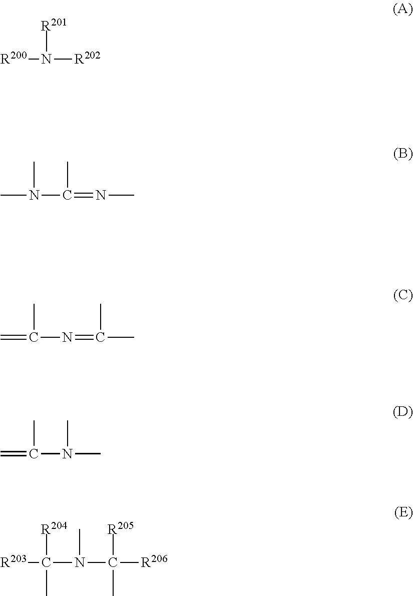

In General Formula (A) and General Formula (E), R²⁰⁰, R²⁰¹, and R²⁰² may be the same or different from each other, and each represent a hydrogen atom, an alkyl group (preferably having 1 to 20 carbon atoms), a cycloalkyl group (preferably having 3 to 20 carbon atoms), or an aryl group (preferably having 6 to 20 carbon atoms), in which R²⁰¹ and R²⁰² may be bonded to each other to form a ring.

With regard to the above-described alkyl group, an alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

R²⁰³, R²⁰⁴, R²⁰⁵, and R²⁰⁶ may be the same or different from each other, and each represent an alkyl group having 1 to 20 carbon atoms.

It is more preferable that the alkyl groups in General Formula (A) and General Formula (E) are unsubstituted.

As the basic compound, guanidine, aminopyrrolidine, pyrazole, pyrazoline, piperazine, aminomorpholine, aminoalkylmorpholine (in which an alkyl group moiety may be linear or branched, and may be partly substituted with an ether group and/or an ester group; a total number of all atoms other than hydrogen atoms in the alkyl group moiety is preferably 1 to 17), or piperidine is preferable. Among these, a compound having an imidazole structure, a diazabicyclo structure, an onium hydroxide structure, an onium carboxylate structure, a trialkylamine structure, an aniline structure, or a pyridine structure; an alkylamine derivative having a hydroxyl group and/or an ether bond; an aniline derivative having a hydroxyl group and/or an ether bond; or the like is more preferable.

Examples of the compound having an imidazole structure include imidazole, 2,4,5-triphenylimidazole, and benzimidazole. Examples of the compound having a diazabicyclo structure include 1,4-diazabicyclo[2,2,2]octane, 1,5-diazabicyclo[4,3,0]non-5-ene, and 1,8-diazabicyclo[5,4,0]undec-7-ene. Examples of the compound having an onium hydroxide structure include triarylsulfonium hydroxide, phenacylsulfonium hydroxide, and sulfonium hydroxide having a 2-oxoalkyl group. Specific examples thereof include triphenylsulfonium hydroxide, tris(t-butylphenyl)sulfonium hydroxide, bis(t-butylphenyl)iodonium hydroxide, phenacylthiophenium hydroxide, and 2-oxopropylthiophenium hydroxide. The compound having an onium carboxylate structure is formed by carboxylation of an anionic moiety of a compound having an onium hydroxide structure, and examples thereof include acetate, adamantane-1-carboxylate, and perfluoroalkyl carboxylate. Examples of the compound having a trialkylamine structure include tri(n-butyl)amine and tri(n-octyl)amine. Examples of the aniline compound include 2,6-diisopropylaniline, N,N-dimethylaniline, N,N-dibutylaniline, and N,N-dihexylaniline. Examples of the alkylamine derivative having a hydroxyl group and/or an ether bond include ethanolamine, diethanolamine, triethanolamine, tris(methoxyethoxyethyl)amine, and “(HO—C₂H₄—O—C₂H₄)₂N(—C₃H₆O—CH₃)”. Examples of the aniline derivative having a hydroxyl group and/or an ether bond include N,N-bis(hydroxyethyl)aniline.

Preferred examples of the basic compound include an amine compound having a phenoxy group and an ammonium salt compound having a phenoxy group.

As the amine compound, for example, a primary, secondary, or tertiary amine compound can be used, and an amine compound in which at least one alkyl group is bonded to a nitrogen atom is preferable. The amine compound is more preferably a tertiary amine compound. As long as at least one alkyl group (preferably having 1 to 20 carbon atoms) is bonded to the nitrogen atom, the amine compound may have a cycloalkyl group (preferably having 3 to 20 carbon atoms) or an aryl group (preferably having 6 to 12 carbon atoms) bonded to the nitrogen atom in addition to the alkyl group.

In addition, the amine compound preferably has an oxyalkylene group. The number of oxyalkylene groups is preferably 1 or more, more preferably 3 to 9, and still more preferably 4 to 6, within the molecule. Among these, as the oxyalkylene group, an oxyethylene group (—CH₂CH₂O—) or an oxypropylene group (—CH(CH₃)CH₂O— or —CH₂CH₂CH₂O—) is preferable, and an oxyethylene group is more preferable.

Examples of the ammonium salt compound include primary, secondary, tertiary, and quaternary ammonium salt compounds, and an ammonium salt compound in which at least one alkyl group is bonded to a nitrogen atom is preferable. As long as at least one alkyl group (preferably having 1 to 20 carbon atoms) is bonded to the nitrogen atom, the ammonium salt compound may have a cycloalkyl group (preferably having 3 to 20 carbon atoms) or an aryl group (preferably having 6 to 12 carbon atoms) bonded to the nitrogen atom in addition to the alkyl group.

It is preferable that the ammonium salt compound has an oxyalkylene group. The number of oxyalkylene groups is preferably 1 or more, more preferably 3 to 9, and still more preferably 4 to 6, within the molecule. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

Examples of the anion of the ammonium salt compound include a halogen atom, a sulfonate, a borate, and a phosphate, and among these, a halogen atom or a sulfonate is preferable. The halogen atom is preferably a chlorine atom, a bromine atom, or an iodine atom. The sulfonate is preferably an organic sulfonate having 1 to 20 carbon atoms. Examples of the organic sulfonate include an alkyl sulfonate and an aryl sulfonate, which have 1 to 20 carbon atoms. The alkyl group of the alkyl sulfonate may have a substituent, and examples of the substituent include a fluorine atom, a chlorine atom, a bromine atom, an alkoxy group, an acyl group, and an aromatic ring group. Examples of the alkyl sulfonate include methanesulfonate, ethanesulfonate, butanesulfonate, hexanesulfonate, octanesulfonate, benzyl sulfonate, trifluoromethanesulfonate, pentafluoroethanesulfonate, and nonafluorobutanesulfonate. Examples of an aryl group of the aryl sulfonate include a benzene ring group, a naphthalene ring group, and an anthracene ring group. The substituent which can be included in the benzene ring group, naphthalene ring group, and anthracene ring group is preferably a linear or branched alkyl group having 1 to 6 carbon atoms or a cycloalkyl group having 3 to 6 carbon atoms. Examples of the linear or branched alkyl group and the cycloalkyl group include a methyl group, an ethyl group, an n-propyl group, an isopropyl group, an n-butyl group, an i-butyl group, a t-butyl group, an n-hexyl group, and a cyclohexyl group. Examples of other substituents include an alkoxy group having 1 to 6 carbon atoms, a halogen atom, a cyano group, a nitro group, an acyl group, and an acyloxy group.

The amine compound having a phenoxy group and the ammonium salt compound having a phenoxy group are each a compound having a phenoxy group at the terminal on the opposite side to the nitrogen atom of the alkyl group which is included in the amine compound or the ammonium salt compound.

Examples of a substituent of the phenoxy group include an alkyl group, an alkoxy group, a halogen atom, a cyano group, a nitro group, a carboxylic acid group, a carboxylic acid ester group, a sulfonic acid ester group, an aryl group, an aralkyl group, an acyloxy group, and an aryloxy group. A substitution position of the substituent may be any of 2- to 6-positions. The number of substituents may be any of 1 to 5.

The compound preferably has at least one oxyalkylene group between the phenoxy group and the nitrogen atom. The number of oxyalkylene groups is preferably 1 or more, more preferably 3 to 9, and still more preferably 4 to 6, within the molecule. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

The amine compound having a phenoxy group can be obtained by heating a mixture of a primary or secondary amine having a phenoxy group and a haloalkyl ether to perform a reaction, then adding an aqueous solution of a strong base (for example, sodium hydroxide, potassium hydroxide, tetraalkylammonium, and the like) to a reaction system, and extracting the reaction product with an organic solvent (for example, ethyl acetate, chloroform, and the like). Alternatively, the amine compound having a phenoxy group can also be obtained by heating a mixture of a primary or secondary amine and a haloalkyl ether having a phenoxy group at the terminal to perform a reaction, then adding an aqueous solution of the strong base to a reaction system, and extracting the reaction product with an organic solvent.

The specific resist composition may include, as an acid diffusion control agent, a compound (hereinafter, also referred to as a “compound (PA)”) that has a proton-accepting functional group and generates a compound which is decomposed by an irradiation with actinic ray or radiation to exhibit deterioration in proton-accepting properties, no proton-accepting properties, or a change from the proton-accepting properties to acidic properties.

The proton-accepting functional group refers to a functional group having a group or electron capable of electrostatically interacting with a proton, and for example, means a functional group with a macrocyclic structure, such as a cyclic polyether, or a functional group having a nitrogen atom having an unshared electron pair not contributing to π-conjugation. For example, the nitrogen atom having the unshared electron pair, which does not contribute to the π-conjugation, is a nitrogen atom having a partial structure represented by the following general formula.

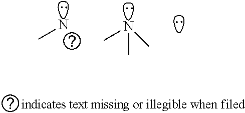

unshared electron pair

Preferred examples of the partial structure of the proton-accepting functional group include a crown ether structure, an azacrown ether structure, primary to tertiary amine structures, a pyridine structure, an imidazole structure, and a pyrazine structure.

The compound (PA) is decomposed by irradiation with actinic ray or radiation to generate a compound exhibiting deterioration in proton-accepting properties, no proton-accepting properties, or a change from the proton-accepting properties to acidic properties. Here, an expression of generating a compound which exhibits deterioration in proton-accepting properties, no proton-accepting properties, or a change from the proton-accepting properties to acidic properties is a change of proton-accepting properties due to the proton being added to the proton-accepting functional group. Specifically, the expression means a decrease in an equilibrium constant at chemical equilibrium in a case where a proton adduct is generated from the compound (PA) having the proton-accepting functional group and the proton.

With regard to the compound (PA), for example, reference can be made to those described in paragraphs [0421] to [0428] of JP2014-41328A or paragraphs [0108] to [0116] of JP2014-134686A, the contents of which are incorporated herein by reference.

A low-molecular-weight compound having a nitrogen atom and a group which is eliminated by the action of acid can also be used as the acid diffusion control agent. The above-described low-molecular-weight compound is preferably an amine derivative having, on the nitrogen atom, a group which is eliminated by the action of acid.

The group which is eliminated by the action of acid is preferably an acetal group, a carbonate group, a carbamate group, a tertiary ester group, a tertiary hydroxyl group, or a hemiaminal ether group, and more preferably a carbamate group or a hemiaminal ether group.

A molecular weight of the low-molecular-weight compound is preferably 100 to 1000, more preferably 100 to 700, and still more preferably 100 to 500.

The low-molecular-weight compound may have a carbamate group having a protective group on the nitrogen atom.

Onium salts represented by General Formulae (d1-1) to (d1-4) can also be used.

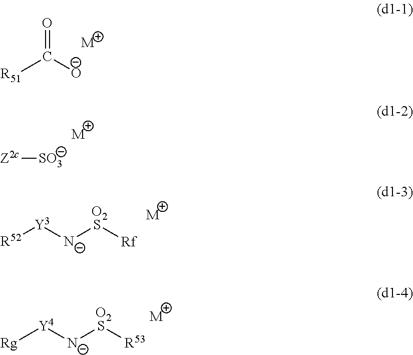

In Formula (d1-1), R⁵¹ represents a hydrocarbon group (for example, an aryl group such as a phenyl group) which may have a substituent (for example, a hydroxyl group).

In Formula (d1-2), Z^{2c} represents a hydrocarbon group having 1 to 30 carbon atoms, which may have a substituent (provided that a carbon atom adjacent to S is not substituted with a fluorine atom).

The above-described divalent hydrocarbon group in Z^{2c} may be linear or branched, may have a cyclic structure. In addition, carbon atoms in the above-described hydrocarbon group (preferably, carbon atoms which are ring member atoms in a case where the above-described hydrocarbon group has a cyclic structure) may be a carbonyl carbon (—CO—). Examples of the hydrocarbon group include a group having a norbornyl group which may have a substituent. Carbon atoms forming the above-described norbornyl group may be a carbonyl carbon.

In Formula (d1-3), R⁵² represents an organic group (preferably, a hydrocarbon group having a fluorine atom), Y³ represents a linear, branched, or cyclic alkylene group, an arylene group, or a carbonyl group, and Rf represents a hydrocarbon group.

In Formula (d1-4), Rg represents a hydrocarbon group, Y⁴ represents a linear, branched, or cyclic alkylene group, an arylene group, or a carbonyl group, and R⁵³ represents an organic group (preferably, a hydrocarbon group having a fluorine atom).

In Formulae (d1-1) to (d1-4), M⁺ represents an organic cation including an ammonium cation, a sulfonium cation, or an iodonium cation. Specific examples of M⁺ include the cation (ZaI) and the cation (ZaII) represented as M_{E1}⁺ in General Formula (EX1) described above.

As the acid diffusion control agent, for example, the contents described in paragraphs

to [0159] of JP2018-155788A can also be incorporated.

Examples of the acid diffusion control agent include compounds (amine compounds, amide group-containing compounds, urea compounds, nitrogen-containing heterocyclic compounds, and the like) described in paragraphs [0140] to [0144] of JP2013-11833A.

Specific examples of the acid diffusion control agent are shown below, but the present invention is not limited thereto.

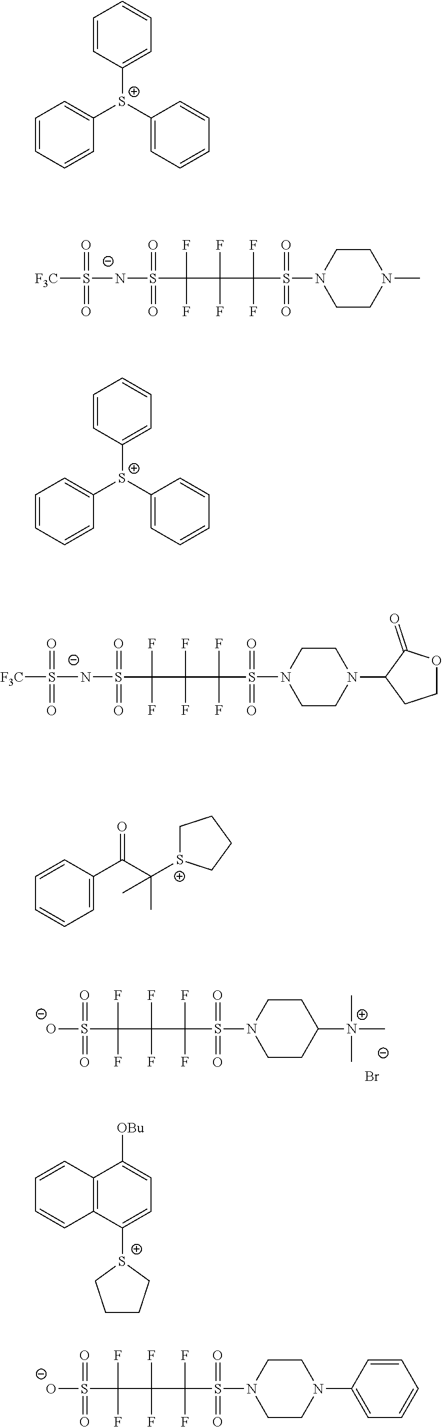

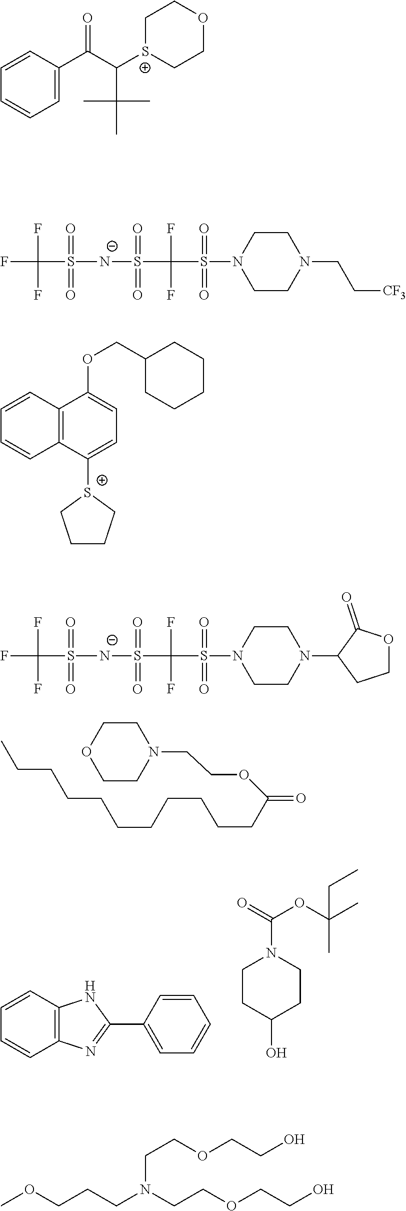

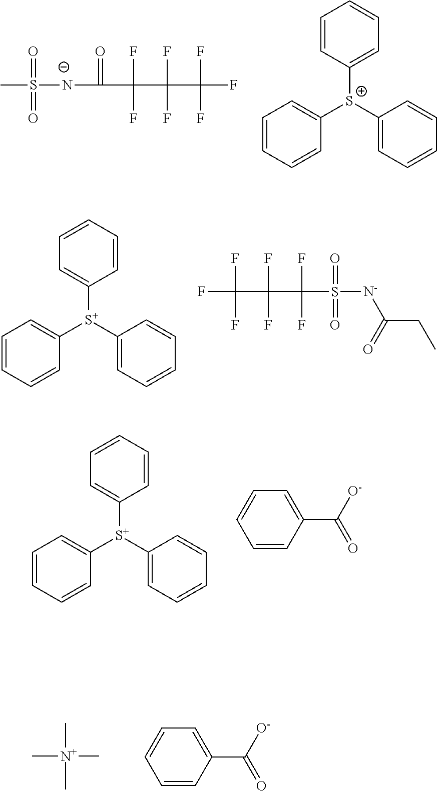

In a case where the specific resist composition includes an acid diffusion control agent, a content of the acid diffusion control agent used is preferably 0.0% to 15% by mass and more preferably 0.01% to 8.0% by mass with respect to the total solid content of the composition.

The acid diffusion control agent may be used alone or in combination of two or more kinds thereof.

(Surfactant)

The specific resist composition may include a surfactant. In a case where the surfactant is included, it is possible to form a pattern having more excellent adhesiveness and fewer development defects.

The surfactant is preferably a fluorine-based and/or silicon-based surfactant.

Examples of the fluorine-based and/or silicon-based surfactant include the surfactants described in paragraph [0276] of the specification of US2008/0248425A. In addition, EFTOP EF301 or EF303 (manufactured by Shin-Akita Chemical Co., Ltd.); FLUORAD FC430, 431, and 4430 (manufactured by Sumitomo 3M inc.); MEGAFACE F171, F173, F176, F189, F113, F110, F177, F120, and R08 (manufactured by DIC Corporation); SURFLON S-382, SC101, 102, 103, 104, 105, or 106 (manufactured by Asahi Glass Co., Ltd.); TROYSOL S-366 (manufactured by Troy Corporation); GF-300 or GF-150 (manufactured by Toagosei Co., Ltd.); SURFLON S-393 (manufactured by AGC Seimi Chemical Co., Ltd.); EFTOP EF121, EF122A, EF122B, RF122C, EF125M, EF135M, EF351, EF352, EF801, EF802, or EF601 (manufactured by JEMCO Inc.); PF636, PF656, PF6320, and PF6520 (manufactured by OMNOVA Solutions Inc.); KH-20 (manufactured by Asahi Kasei Corporation); or FTX-204G, 208G, 218G, 230G, 204D, 208D, 212D, 218D, and 222D (manufactured by NEOS COMPANY LIMITED) may be used. A polysiloxane polymer KP-341 (manufactured by Shin-Etsu Chemical Co., Ltd.) can also be used as the silicon-based surfactant.

Moreover, in addition to the known surfactants as described above, the surfactant may be synthesized using a fluoroaliphatic compound produced by a telomerization method (also referred to as a telomer method) or an oligomerization method (also referred to as an oligomer method). Specifically, a polymer including a fluoroaliphatic group derived from the fluoroaliphatic compound may be used as the surfactant. The fluoroaliphatic compound can be synthesized, for example, by the method described in JP2002-90991A.

In addition, a surfactant other than the fluorine-based and/or the silicon-based surfactants described in paragraph [0280] of the specification of US2008/0248425A may be used.

The surfactant may be used alone or in combination of two or more kinds thereof.

In a case where the specific resist composition includes a surfactant, a content of the surfactant is preferably 0.0001% to 2% by mass, and more preferably 0.0005% to 1% by mass with respect to the total solid content of the composition.

(Other Additives)

The specific resist composition may further include a dissolution inhibiting compound, a dye, a plasticizer, a photosensitizer, a light absorbing agent, and/or a compound promoting a solubility in a developer (for example, a phenol compound having a molecular weight of 1000 or less or an alicyclic or aliphatic compound including a carboxylic acid group).

The specific resist composition may further include a dissolution inhibiting compound. Here, the “dissolution inhibiting compound” is intended to be a compound having a molecular weight of 3000 or less, in which solubility in an organic developer decreases by decomposition due to the action of acid.

[Method for Manufacturing Electronic Device]

In addition, the present invention further relates to a method for manufacturing an electronic device, including the above-described pattern forming method. The electronic device manufactured by the method for manufacturing an electronic device according to the embodiment of the present invention can be suitably mounted on electric or electronic apparatus (home electronics, office automation (OA) related equipment, media-related equipment, optical equipment, telecommunication equipment, and the like).

[Actinic Ray-Sensitive or Radiation-Sensitive Resin Composition]

In addition, the present invention relates to an actinic ray-sensitive or radiation-sensitive resin composition.

The actinic ray-sensitive or radiation-sensitive resin composition according to the embodiment of the present invention is the same as the specific resist composition used in the above-described pattern forming method, and the suitable aspects thereof are also the same.

In the resist film formed of the actinic ray-sensitive or radiation-sensitive resin composition according to the embodiment of the present invention, a solubility in the organic solvent-based developer is increased by an irradiation with an actinic ray or a radiation.

### EXAMPLES

Hereinafter, the present invention will be described in more detail with reference to Examples. The materials, the amounts of materials used, the proportions, the treatment details, the treatment procedure, and the like shown in Examples below may be appropriately modified as long as the modifications do not depart from the spirit of the present invention. Therefore, the scope of the present invention should not be construed as being limited to Examples shown below.

[Preparation of Actinic Ray-Sensitive or Radiation-Sensitive Resin Composition]

[Various Components]

<Resin>

Structures of resins (A-1 to A-9) shown in Table 1 are shown below.

The weight-average molecular weight (Mw) and the dispersity (Mw/Mn) of the resins were measured by GPC (carrier: tetrahydrofuran (THF)) (an amount expressed in terms of polystyrene). In addition, the compositional ratio (ratio in % by mole) of the resin was measured by means of ¹³C-nuclear magnetic resonance (NMR).

As the resins (A-1 to A-9), resins synthesized by a known procedure were used.

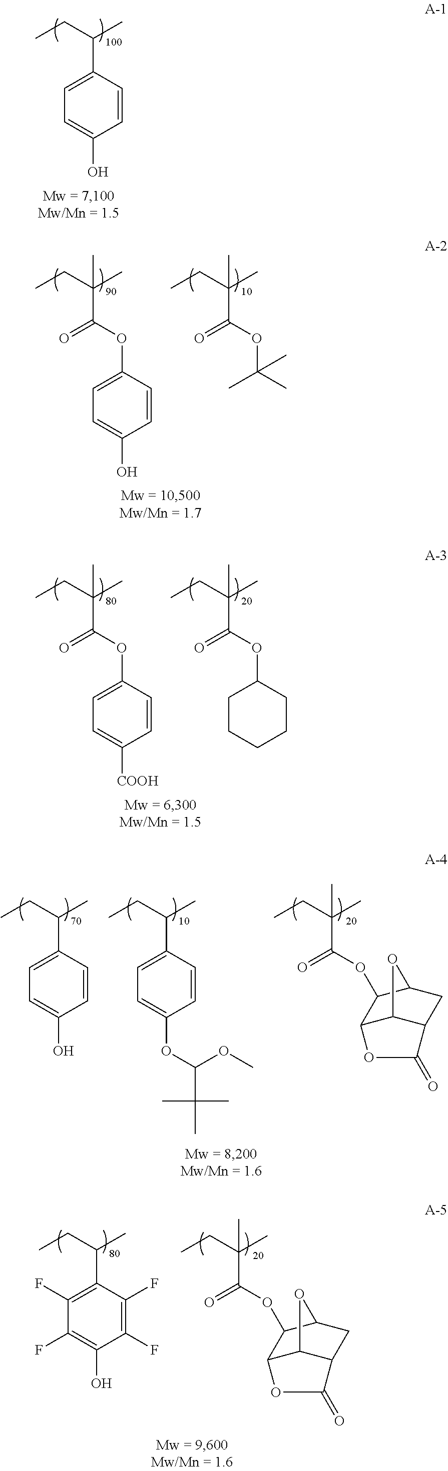

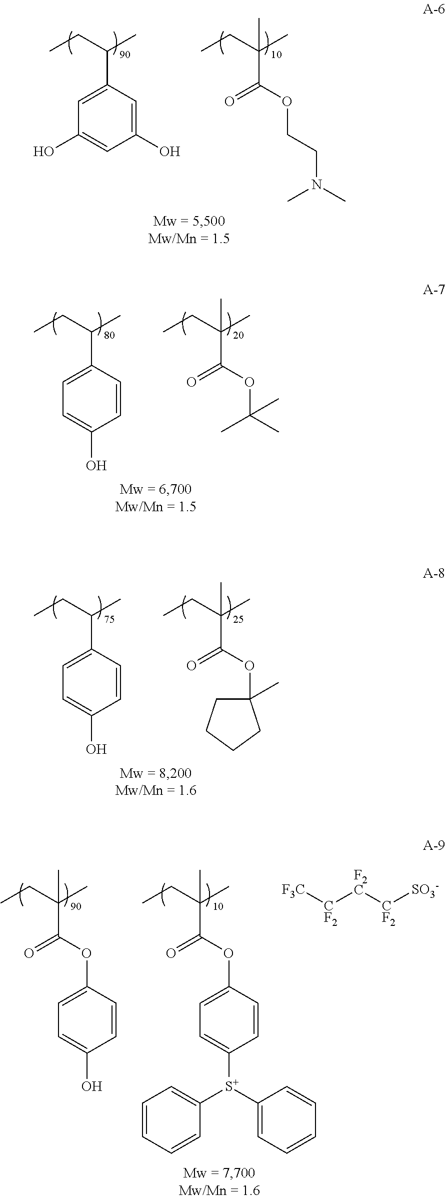

<Compound (Photodegradable Ion Compound) Including Two or More Ion Pairs which are Decomposed by Irradiation with Actinic Ray or Radiation and Having Molecular Weight of 5,000 or Less>

Structures of photodegradable ion compounds (B-1 to B-7) shown in Table 1 are shown below.

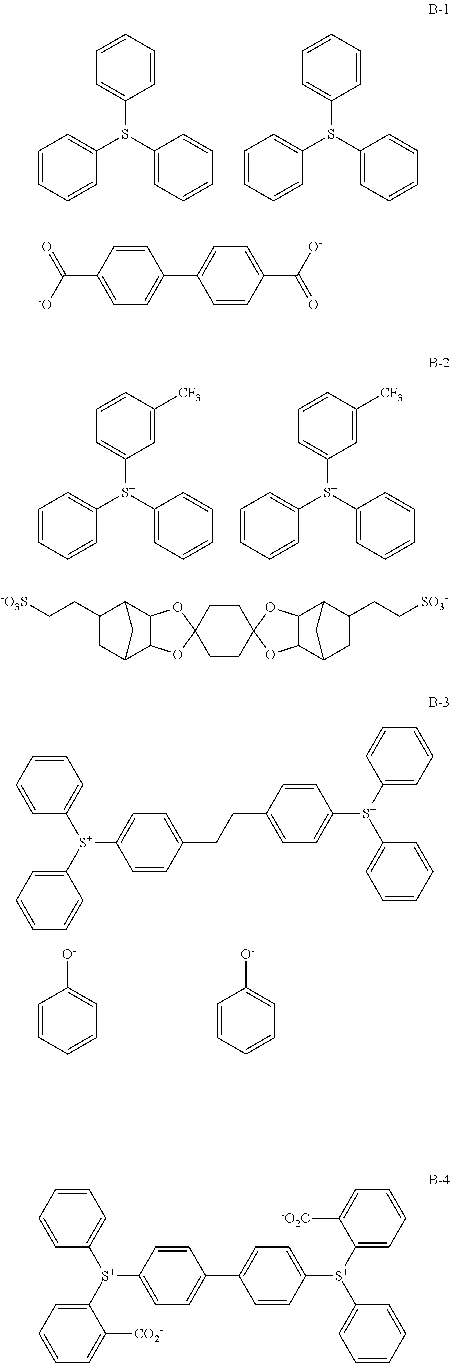

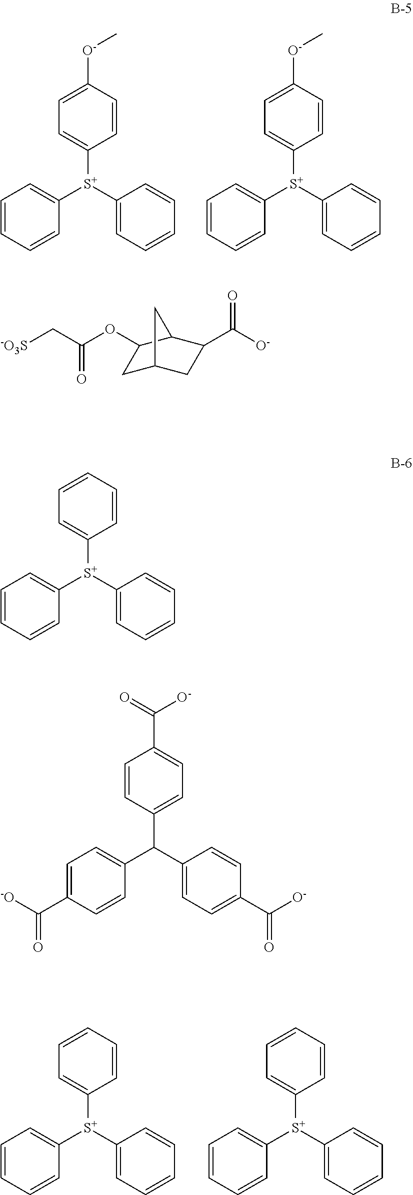

As the photodegradable ion compound B-7 shown in Table 1, a resin having Mw=4,500 and Mw/Mn=1.6, which was synthesized by the same procedure as the above-described resin A-9, was used. That is, the photodegradable ion compound B-7 corresponds to a resin having a weight-average molecular weight and a dispersity different from those of the resin A-9.

<Additive>

Structures of additives (D-1 to D-4) shown in Table 1 are shown below.

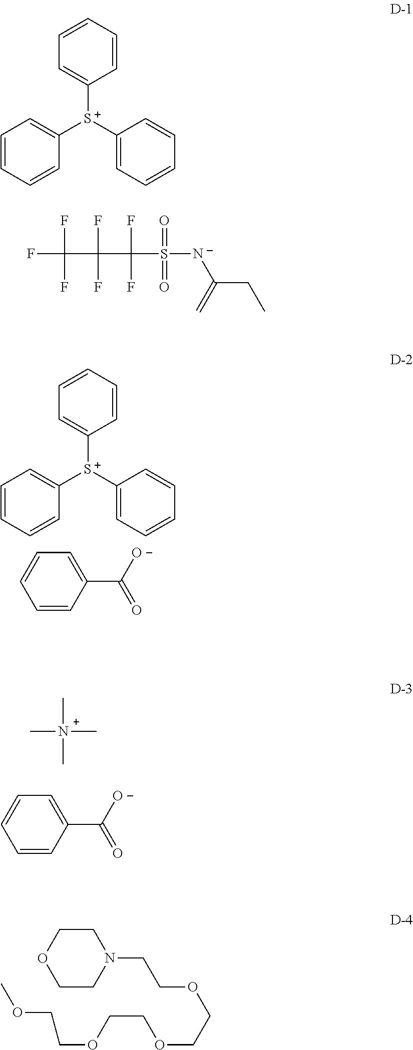

<Surfactant>

A surfactant (W-1) shown in Table 1 is shown below.

W-1: MEGAFACE F176 (manufactured by DIC Corporation; fluorine-based surfactant)

<Solvent>

Solvents (C-1 to C-5) shown in Table 1 are shown below.

C-1: Propylene glycol monomethyl ether acetate (PGMEA)

C-2: Propylene glycol monomethyl ether (PGME)

C-3: Ethyl lactate

C-4: γ-Butyrolactone

C-5: Cyclohexanone

<Developer and Rinsing Liquid>

Developers and rinsing liquids (E-1 to E-4) shown in Table 2 are shown below.

E-1: Butyl acetate

E-2: 2-Heptanone

E-3: Isobutyl acetate

E-4: 4-Methyl-2-pentanol (MIBC)

<Underlayer Film>

Underlayer films (UL-1 and UL-2) shown in Table 2 are shown below.

UL-1: AL412 (manufactured by Brewer Science Ltd.)

UL-2: SHB-A940 (manufactured by Shin-Etsu Chemical Co., Ltd.)

[Preparation of Actinic Ray-Sensitive or Radiation-Sensitive Resin Composition]

Various components were mixed based on the composition shown in Table 1, the obtained mixed liquid was filtered through a polyethylene filter having a pore size of 0.03 μm to prepare an actinic ray-sensitive or radiation-sensitive resin composition (hereinafter also referred to as a “resist composition”). In the resist composition, the solid content means all the components excluding the solvent. The obtained resist compositions were used in Examples and Comparative Examples.

Table 1 is shown below.

In Table 1, numerical values in the columns of “Content of resin (% by mass)”, “Content of photodegradable ion compound (% by mass)”, “Content of additive (% by mass)”, and “Content of surfactant (% by mass)” each indicate a content with respect to the total solid content in the composition.

TABLE 1

| | | | | Photodegradable ion | | | | | | |
|---|---|---|---|---|---|---|---|---|---|---|
| | | Resin | | compound | | Additive | | Surfactant | | |
| Resist | Concentration of solid | | Content (% | | Content (% | | Content (% | | Content (% | |
| composition | contents (% by mass) | Type | by mass) | Type | by mass) | Type | by mass) | Type | by mass) | Solvent |
| R-1 | 1.4 | A-1 | 75.0 | B-1 | 25.0 | — | — | — | — | C-1/C-2 = |
| | | | | | | | | | | 60/40 |
| R-2 | 1.6 | A-2 | 80.0 | B-1 | 20.0 | — | — | — | — | C-1/C-2/C-3 = |
| | | | | | | | | | | 30/30/40 |
| R-3 | 1.2 | A-3 | 85.0 | B-1 | 15.0 | — | — | — | — | C-1/C-2/C-3 = |
| | | | | | | | | | | 30/30/40 |
| R-4 | 1.3 | A-4 | 88.0 | B-1 | 12.0 | — | — | — | — | C-1/C-2/C-3 = |
| | | | | | | | | | | 30/30/40 |
| R-5 | 1.6 | A-5 | 79.7 | B-1 | 15.0 | D-2 | 5.0 | W-1 | 0.3 | C-1/C-2/C-3 = |
| | | | | | | | | | | 30/30/40 |
| R-6 | 1.4 | A-6 | 80.0 | B-1 | 20.0 | — | — | — | — | C-1/C-2/C-4 = |
| | | | | | | | | | | 60/30/10 |
| R-7 | 1.4 | A-1 | 76.0 | B-2 | 16.0 | D-1 | 8.0 | — | — | C-1/C-2/C-4 = |
| | | | | | | | | | | 60/30/10 |
| R-8 | 1.4 | A-1 | 80.0 | B-3 | 15.0 | D-3 | 5.0 | — | — | C-1/C-2/C-4 = |
| | | | | | | | | | | 60/30/10 |
| R-9 | 1.6 | A-1 | 86.0 | B-4 | 14.0 | — | — | — | — | C-1/C-5 = |
| | | | | | | | | | | 70/30 |
| R-10 | 1.5 | A-1 | 74.0 | B-5 | 26.0 | — | — | — | — | C-3/C-5 = |
| | | | | | | | | | | 70/30 |
| R-11 | 1.4 | A-1 | 80.0 | B-6 | 20.0 | — | — | — | — | C-3/C-5 = |
| | | | | | | | | | | 70/30 |
| R-12 | 1.6 | A-5 | 83.0 | B-2 | 14.0 | D-4 | 3.0 | — | — | C-1/C-2/C-3 = |
| | | | | | | | | | | 30/30/40 |
| R-13 | 1.6 | A-5 | 80.0 | B-3 | 20.0 | — | — | — | — | C-1/C-2/C-3 = |
| | | | | | | | | | | 30/30/40 |
| R-14 | 1.4 | A-6 | 79.5 | B-4 | 20.0 | — | — | W-1 | 0.5 | C-1/C-2/C-3 = |
| | | | | | | | | | | 30/30/40 |
| R-15 | 1.3 | A-6 | 82.0 | B-5 | 18.0 | — | — | — | — | C-1/C-2/C-3 = |
| | | | | | | | | | | 30/30/40 |
| R-16 | 1.9 | A-6 | 92.0 | B-6 | 8.0 | — | — | — | — | C-1/C-2 = |
| | | | | | | | | | | 60/40 |
| R-17 | 1.6 | A-7 | 80.0 | B-1 | 20.0 | — | — | — | — | C-1/C-2/C-3 = |
| | | | | | | | | | | 30/30/40 |
| R-18 | 1.3 | A-8 | 80.0 | B-1 | 20.0 | — | — | — | — | C-1/C-2/C-3 = |
| | | | | | | | | | | 30/30/40 |
| R-19 | 1.3 | A-8 | 80.0 | B-7 | 20.0 | — | — | — | — | C-1/C-2/C-3 = |
| | | | | | | | | | | 30/30/40 |
| CR-1 | 1.5 | A-1 | 70.0 | — | — | D-2 | 30.0 | — | — | C-1/C-2/C- 3 = |
| | | | | | | | | | | 30/30/40 |
| CR-2 | 1.4 | A-2 | 75.0 | — | — | D-1 | 25.0 | — | — | C-1/C-2 = |
| | | | | | | | | | | 60/40 |
| CR-3 | 1.5 | A-9 | 100.0 | — | — | — | — | — | — | C-1/C-2/C-3 = |
| | | | | | | | | | | 30/30/40 |

[Pattern Formation and Evaluation]

[EUV Exposure and Organic Solvent Development]

The resist composition shown in Table 2 was applied to a silicon wafer (12 inches) on which the underlayer film shown in Table 2 had been formed to form a coating film. Next, the obtained coating film was heated under the bake conditions described in “Resist coating conditions” in Table 2. By the above-described procedure, a silicon wafer which had a resist film having a film thickness (nm) described in “Resist coating conditions” in Table 2 was obtained.

The silicon wafer having the obtained resist film was subjected to a pattern irradiation using an EUV exposure device (manufactured by Exitech Ltd., Micro Exposure Tool, NA 0.3, Quadrupol, outer sigma 0.68, inner sigma 0.36). As a reticle, a mask having a line size=14 nm and a line:space=1:1 was used.

Thereafter, after baking under the conditions described in “PEB-development conditions” in Table 2 below, developer was performed for 30 seconds with the developer described in “PEB development conditions” in Table 2 below. However, for Examples 12 and 13, after the development treatment, rinsing was further performed by paddling with the rinsing liquid described in “PEB development conditions” in Table 2 below. Next, the silicon wafer having the resist film subjected to the above-described treatment was rotated at a rotation speed of 4000 rpm for 30 seconds, and further baked at 90° C. for 60 seconds. By the above-described procedure, a line-and-space pattern having a pitch of 28 nm and a line width of 14 nm (space width of 14 nm) was obtained. The results are summarized in Table 2.

<Evaluation>

The obtained patterns were evaluated as shown below.

(Evaluation 1: Sensitivity)

While changing an exposure amount, the line width of the line-and-space pattern was measured, and an exposure amount at which the line width reached 14 nm was determined and defined as a sensitivity (mJ/cm²). A smaller value thereof indicates a resist having a higher sensitivity and better performance.

(Evaluation 2: LER)

While the line-and-space resist pattern resolved at the optimal exposure amount in the evaluation of the sensitivity was observed from a top of the pattern with a length measuring scanning electron microscope (SEM (CG-4100 manufactured by Hitachi High Technologies Corporation)), a distance from the center of the pattern to an edge was measured at any points and a measurement deviation thereof was evaluated as 3σ. As the value is smaller, the performance is better.

(Evaluation 3: Resolution (Pattern Collapse Performance))

The line width of the line-and-space pattern was measured while changing the exposure amount. At this time, a minimum line width in which the pattern was resolved without a collapse over 10 m square was defined as a collapse line width. A smaller value thereof indicates that a margin of pattern collapse is wider and the performance is better.

Table 2 is shown below.

In the column of “PEB development conditions” of Table 2, “-” in the column of “PEB” indicates that PEB was not performed. In addition, “-” in the column of “Rinsing liquid” indicates that the rinsing treatment was not performed.

TABLE 2

| | Resist coating conditions | | | | | | | | | |
|---|---|---|---|---|---|---|---|---|---|---|
| | | | Film | | PEB * development conditions | | | Evaluation result | | |
| | Resist | | thickness | | | | Rinsing | Sensitivity | LER | Collapse |
| | composition | Underlying film | (nm) | bake | PEB | Developer | liquid | (mJ/cm²) | (nm) | (nm) |
| Example 1 | R-1 | UL-1 | 30 | 120° C./60 | 80° C./60 | E-1 | — | 25 | 2.1 | 12 |
| | | | | seconds | seconds | | | | | |
| Example 2 | R-2 | UL-1 | 35 | 120° C./60 | 90° C./60 | E-1 | — | 26 | 2.5 | 10 |
| | | | | seconds | seconds | | | | | |
| Example 3 | R-3 | UL-1 | 25 | 100° C./90 | — | E-1 | — | 19 | 2.6 | 11 |
| | | | | seconds | | | | | | |
| Example 4 | R-4 | UL-1 | 30 | 90° C./60 | — | E-1 | — | 20 | 2.2 | 10 |
| | | | | seconds | | | | | | |
| Example 5 | R-5 | UL-2 | 35 | 100° C./60 | 100° C./50 | E-1 | — | 21 | 2.7 | 11 |
| | | | | seconds | seconds | | | | | |
| Example 6 | R-6 | UL-2 | 30 | 120° C./45 | — | E-1 | — | 20 | 2.2 | 11 |
| | | | | seconds | | | | | | |
| Example 7 | R-7 | UL-1 | 35 | 120° C./60 | — | E-2 | — | 20 | 2.2 | 12 |
| | | | | seconds | | | | | | |
| Example 8 | R-8 | UL-1 | 30 | 100° C./60 | — | E-2 | — | 30 | 2.3 | 10 |
| | | | | seconds | | | | | | |
| Example 9 | R-9 | UL-1 | 35 | 90° C./60 | — | E-3 | — | 34 | 2.1 | 11 |
| | | | | seconds | | | | | | |
| Example 10 | R-10 | UL-1 | 35 | 100° C./60 | 80° C./60 | E-3 | — | 32 | 2.0 | 12 |
| | | | | seconds | seconds | | | | | |
| Example 11 | R-11 | UL-1 | 30 | 100° C./60 | 80° C./60 | E-1 | — | 35 | 1.9 | 10 |
| | | | | seconds | seconds | | | | | |
| Example 12 | R-12 | UL-2 | 35 | 120° C./60 | 80° C./60 | E-1 | E-4 | 34 | 1.6 | 12 |
| | | | | seconds | seconds | | | | | |
| Example 13 | R-13 | UL-2 | 30 | 100° C./50 | 100° C./50 | E-1 | E-4 | 36 | 2.2 | 12 |
| | | | | seconds | seconds | | | | | |
| Example 14 | R-14 | UL-1 | 30 | 90° C./60 | 80° C./60 | E-1 | — | 20 | 1.9 | 10 |
| | | | | seconds | seconds | | | | | |
| Example 15 | R-15 | UL-1 | 25 | 90° C./60 | 80° C./60 | E-1 | — | 25 | 1.7 | 11 |
| | | | | seconds | seconds | | | | | |
| Example 16 | R-16 | UL-1 | 40 | 100° C./60 | — | E-1 | — | 32 | 1.6 | 11 |
| | | | | seconds | | | | | | |
| Example 17 | R-17 | UL-1 | 30 | 120° C./60 | 90° C./60 | E-1 | — | 30 | 2.4 | 11 |
| | | | | seconds | seconds | | | | | |
| Example 18 | R-18 | UL-1 | 25 | 120° C./60 | 90° C./60 | E-1 | — | 40 | 2.9 | 12 |
| | | | | seconds | seconds | | | | | |
| Example 19 | R-19 | UL-1 | 25 | 120° C./60 | 90° C./60 | E-1 | — | 50 | 3.1 | 12 |
| | | | | seconds | seconds | | | | | |
| Comparative | CR-1 | UL-1 | 35 | 120° C./60 | — | E-1 | — | 55 | 3.5 | 13 |
| Example 1 | | | | seconds | | | | | | |
| Comparative | CR-2 | UL-2 | 30 | 100° C./60 | 100° C./50 | E-1 | — | 60 | 4.2 | 14 |
| Example 2 | | | | seconds | seconds | | | | | |
| Comparative | CR-3 | UL-1 | 30 | 90° C./60 | 100° C./50 | E-1 | — | 65 | 5.0 | 13 |
| Example 3 | | | | seconds | seconds | | | | | |

From the results in Table 2 above, with the pattern forming methods and resist compositions of Examples, it was confirmed that the sensitivity, LER performance, and resolution performance were excellent.

In addition, from the comparison of Example 2, Example 4, Example 17, Example 18, and Example 19, it was found that, in a case where the specific resin included the repeating unit X2 and the content of the repeating unit X2 was 20 mol % or less (preferably, 10 mol % or less) with respect to all repeating units of the specific resin, the LER of the formed pattern was more excellent.

In addition, from the comparison of Example 18 and Example 19, it was found that, in a case where the photodegradable ion compound was a non-polymer-type specific photodegradable ion compound (preferably, a case of being the compounds represented by General Formulae (EX1) to (EX3)), the LER of the formed pattern was more excellent.

### EXPLANATION OF REFERENCES

1: substrate
2: resist film
3: mask
2a: region (exposed portion) with high solubility in organic solvent-based developer
2b: region (non-exposed portion) with low solubility or insolubility in organic solvent-based developer

What is claimed is:

1. A pattern forming method comprising:
a resist film forming step of forming a resist film on a substrate using an actinic ray-sensitive or radiation-sensitive resin composition;
an exposing step of exposing the resist film; and
a developing step of positively developing the exposed resist film using an organic solvent-based developer,
wherein the actinic ray-sensitive or radiation-sensitive resin composition includes a resin having a polar group, a compound including two or more ion pairs which are decomposed by an irradiation with an actinic ray or a radiation and having a molecular weight of 5,000 or less, and a solvent.

2. The pattern forming method according to claim 1,
wherein the resin includes a repeating unit X1 having a polar group.

3. The pattern forming method according to claim 2,
wherein the repeating unit X1 includes a repeating unit including a phenolic hydroxyl group.

4. The pattern forming method according to claim 1,
wherein the resin does not include a repeating unit X2 which decreases a solubility in the organic solvent-based developer by an action of acid, or
in a case where the resin includes the repeating unit X2, a content of the repeating unit X2 is 20 mol % or less with respect to all repeating units of the resin.

5. The pattern forming method according to claim 1,
wherein the resin does not include a repeating unit X2 which decreases a solubility in the organic solvent-based developer by an action of acid, or
in a case where the resin includes the repeating unit X2, a content of the repeating unit X2 is 10 mol % or less with respect to all repeating units of the resin.

6. A method for manufacturing an electronic device, comprising:
the pattern forming method according to claim 1.

7. An actinic ray-sensitive or radiation-sensitive resin composition comprising:
a resin having a polar group;
a compound including two or more ion pairs which are decomposed by an irradiation with an actinic ray or a radiation and having a molecular weight of 5,000 or less; and
a solvent,
wherein, in a case where a resist film formed of the actinic ray-sensitive or radiation-sensitive resin composition is irradiated with an actinic ray or a radiation, a solubility in an organic solvent-based developer is increased.

8. The actinic ray-sensitive or radiation-sensitive resin composition according to claim 7,
wherein the resin includes a repeating unit X1 having a polar group.

9. The actinic ray-sensitive or radiation-sensitive resin composition according to claim 8,
wherein the repeating unit X1 includes a repeating unit including a phenolic hydroxyl group.

10. The actinic ray-sensitive or radiation-sensitive resin composition according to claim 7,
wherein the resin does not include a repeating unit X2 which decreases a solubility in the organic solvent-based developer by an action of acid, or
in a case where the resin includes the repeating unit X2, a content of the repeating unit X2 is 20 mol % or less with respect to all repeating units of the resin.

11. The actinic ray-sensitive or radiation-sensitive resin composition according to claim 7,
wherein the resin does not include a repeating unit X2 which decreases a solubility in the organic solvent-based developer by an action of acid, or
in a case where the resin includes the repeating unit X2, a content of the repeating unit X2 is 10 mol % or less with respect to all repeating units of the resin.

12. A resist film formed of the actinic ray-sensitive or radiation-sensitive resin composition according to claim 7.

13. The pattern forming method according to claim 2,
wherein the resin does not include a repeating unit X2 which decreases a solubility in the organic solvent-based developer by an action of acid, or
in a case where the resin includes the repeating unit X2, a content of the repeating unit X2 is 20 mol % or less with respect to all repeating units of the resin.

14. The pattern forming method according to claim 2,
wherein the resin does not include a repeating unit X2 which decreases a solubility in the organic solvent-based developer by an action of acid, or
in a case where the resin includes the repeating unit X2, a content of the repeating unit X2 is 10 mol % or less with respect to all repeating units of the resin.

15. A method for manufacturing an electronic device, comprising:
the pattern forming method according to claim 2.

16. The actinic ray-sensitive or radiation-sensitive resin composition according to claim 8,
wherein the resin does not include a repeating unit X2 which decreases a solubility in the organic solvent-based developer by an action of acid, or
in a case where the resin includes the repeating unit X2, a content of the repeating unit X2 is 20 mol % or less with respect to all repeating units of the resin.

17. The actinic ray-sensitive or radiation-sensitive resin composition according to claim 8,
wherein the resin does not include a repeating unit X2 which decreases a solubility in the organic solvent-based developer by an action of acid, or
in a case where the resin includes the repeating unit X2, a content of the repeating unit X2 is 10 mol % or less with respect to all repeating units of the resin.

18. A resist film formed of the actinic ray-sensitive or radiation-sensitive resin composition according to claim 8.

19. The pattern forming method according to claim 3,
wherein the resin does not include a repeating unit X2 which decreases a solubility in the organic solvent-based developer by an action of acid, or
in a case where the resin includes the repeating unit X2, a content of the repeating unit X2 is 10 mol % or less with respect to all repeating units of the resin.

20. A method for manufacturing an electronic device, comprising:
the pattern forming method according to claim 3.
